(19) United States
(12) Patent Application Publication
(10) Pub. No.: US 2026/0231389 A1
(43) Pub. Date: Aug. 6, 2026

(54) SEMICONDUCTOR DEVICE AND MEMORY DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Tsutomu MURAKAWA, Isehara (JP); Hitoshi KUNITAKE, Machida (JP); Hidekazu MIYAIRI, Hadano (JP); Motomu KURATA, Isehara (JP); Yuki OKAMOTO, Ebina (JP); Shoki MIYATA, Atsugi (JP)

(21) Appl. No.: 19/150,250

(22) PCT Filed: Feb. 16, 2024
(86) PCT No.: PCT/IB2024/051467

§ 371 Date: Jul. 23, 2025

(30) Foreign Application Priority Data
Feb. 24, 2023 (JP) 2023-026836
Mar. 2, 2023 (JP) 2023-031698

(51) Int. Cl. H10B 12/00

(52) U.S. Cl. CPC H10B 12/00

(57) ABSTRACT

A semiconductor device with a reduced number of steps is provided. The semiconductor device includes a first transistor and a second transistor in a memory cell. As each of the two transistors, a vertical transistor including a channel formation region on a side surface of an opening portion formed in an insulating layer and having a small occupied area is used. Some unevenness due to the components of the first transistor is allowed, and the second transistor is placed obliquely above the first transistor not to cause a defect due to the unevenness, whereby the number of steps in a planarization process or the like is reduced.

### TECHNICAL FIELD

One embodiment of the present invention relates to a transistor, a semiconductor device, a memory device, and an electronic device. Another embodiment of the present invention relates to a method for manufacturing a memory device or a semiconductor device. Another embodiment of the present invention relates to a semiconductor wafer and a module.

Note that in this specification and the like, a semiconductor device refers to a general device that can function by utilizing semiconductor characteristics. A semiconductor element such as a transistor, a semiconductor circuit, an arithmetic device, and a memory device are each an embodiment of a semiconductor device. It can be sometimes said that a display device (e.g., a liquid crystal display device and a light-emitting display device), a projection device, a lighting device, an electro-optical device, a power storage device, a memory device, a semiconductor circuit, an image capturing device, an electronic device, and the like include a semiconductor device.

One embodiment of the present invention is not limited to the above technical field. One embodiment of the invention disclosed in this specification and the like relates to an object, a method, or a manufacturing method. One embodiment of the present invention relates to a process, a machine, manufacture, or a composition of matter.

### BACKGROUND ART

A silicon-based semiconductor material is widely known as a semiconductor thin film usable for the transistor and further, an oxide semiconductor has been attracting attention as another material. It is known that the current flowing through a transistor including an oxide semiconductor in the non-conducting state (off state) is extremely low.

For example, Patent Document 1 discloses a memory device that can retain stored contents for a long time by utilizing a characteristic of a low leakage current of the transistor including an oxide semiconductor.

In recent years, demand for an integrated circuit with higher density has risen with reductions in size and weight of electronic devices. For example, Patent Document 2 and Non-Patent Document 1 disclose a technique to achieve an integrated circuit with higher density by making a plurality of memory cells overlap with each other by stacking a first transistor including an oxide semiconductor film and a second transistor including an oxide semiconductor film.

Furthermore, by employing vertical transistors, an integrated circuit with higher density can be achieved. For example, Patent Document 3 discloses a vertical transistor in which a side surface of an oxide semiconductor is covered with a gate electrode with a gate insulator therebetween.

### REFERENCES

### Patent Documents

[Patent Document 1] Japanese Published Patent Application No. 2011-151383
[Patent Document 2] PCT International Publication No. 2021/053473
[Patent Document 3] Japanese Published Patent Application No. 2013-211537

### Non-Patent Document

[Non-Patent Document 1] M. Oota et. al, “3D-Stacked CAAC-In—Ga—Zn Oxide FETs with Gate Length of 72 nm”, IEDM Tech. Dig., 2019, pp. 50-53

### SUMMARY OF THE INVENTION

### Problems to be Solved by the Invention

The memory cell disclosed in Patent Document 1 includes a write transistor and a read transistor. The read transistor feeds a current in accordance with the data potential retained in a gate, so that the potential of a bit line (a read line) is changed.

In the memory cell, unlike in a DRAM cell, there is no need to provide a capacitor with a large volume, which enables formation of a memory device (memory) with a high integration degree. By appropriately arranging components included in the memory cell two-dimensionally or three-dimensionally, the integration degree can be further increased, so that a memory device (memory) with a high storage capacity can be formed.

In the case where transistors included in memory cells are arranged three-dimensionally, a planarization process for reducing unevenness due to components of the transistors is employed. Since the number of steps in the planarization process is increased in proportion to the number of layers, the number of layers is preferably reduced as much as possible.

Furthermore, miniaturization and an increase in integration degree of memory cells shorten the distance between wirings, which enhances the influence of parasitic capacitance. The retained data potential is varied by capacitive coupling due to parasitic capacitance to lower the reliability of data reading in some cases.

In view of the above, an object of one embodiment of the present invention is to provide a semiconductor device with a reduced number of steps. Another object is to provide a semiconductor device having high reliability of data reading. Another object is to provide a semiconductor device with low parasitic capacitance. Another object is to provide a semiconductor device that can be highly integrated. Another object is to provide a semiconductor device having favorable electrical characteristics. Another object is to provide a semiconductor device with high reliability. Another object is to provide a semiconductor device with low power consumption. Another object is to provide a novel semiconductor device. Another object is to provide a novel semiconductor device or the like.

Note that the description of these objects does not preclude the existence of other objects. One embodiment of the present invention does not necessarily achieve all these objects. Note that other objects will be apparent from the description of the specification, the drawings, the claims, and the like, and other objects can be derived from the description of the specification, the drawings, the claims, and the like.

### Means for Solving the Problems

One embodiment of the present invention is a semiconductor device, in which a first layer includes an arithmetic processing device and a sense amplifier, a second layer includes a memory device, the second layer is provided over the first layer, the sense amplifier has a function of reading data from the memory device, the memory device includes a plurality of memory cells, the memory cell includes a first transistor and a second transistor, the first transistor and the second transistor are electrically connected to each other through a conductor, the first transistor includes a channel formation region in a first semiconductor provided along a side surface of a first opening portion included in a first insulator, the second transistor includes a channel formation region in a second semiconductor provided along a side surface of a second opening portion included in a second insulator, the second insulator is provided over the first insulator, and the second opening portion is provided obliquely above the first opening portion.

The conductor can include a region functioning as a gate electrode of the first transistor and a region functioning as a source electrode or a drain electrode of the second transistor.

The second opening portion is preferably provided in a position not overlapping with the first opening portion in a top view.

Another embodiment of the present invention is a semiconductor device, in which a first layer includes an arithmetic processing device and a sense amplifier, a second layer includes a memory device, the second layer is provided over the first layer, the sense amplifier has a function of reading data from the memory device, the memory device includes a plurality of memory cells, the memory cell includes a first transistor and a second transistor, the first transistor includes a first conductor, a first semiconductor, a first insulator, a second conductor, and a third conductor, the first semiconductor includes a region formed on a side surface of a first opening portion that penetrates a second insulator provided over the first conductor and the second conductor, the first insulator includes a region that is in contact with the first semiconductor and covers the first opening portion, the third conductor includes a region that is in contact with the first insulator and covers the first opening portion, the second transistor includes the third conductor, a second semiconductor, a third insulator, a fourth conductor, and a fifth conductor, the second semiconductor includes a region formed on a side surface of a second opening portion that penetrates a fourth insulator provided over the third conductor and the fourth conductor, the third insulator includes a region that is in contact with the second semiconductor and covers the second opening portion, the fifth conductor includes a region that is in contact with the third insulator and covers the second opening portion, and the second opening portion is provided obliquely above the first opening portion.

The first conductor can include a region functioning as one of a source electrode and a drain electrode of the first transistor. The second conductor can include a region functioning as the other of the source electrode and the drain electrode of the first transistor. The third conductor can include a region functioning as a gate electrode of the first transistor and a region functioning as one of a source electrode and a drain electrode of the second transistor. The fourth conductor can include a region functioning as the other of the source electrode and the drain electrode of the second transistor. The fifth conductor can include a region functioning as a gate electrode of the second transistor.

The second opening portion is preferably provided in a position not overlapping with the first opening portion in a top view.

The third conductor may be provided such that the whole third conductor overlaps with the second conductor in a top view.

The third conductor in a top view may have an elliptical shape or an oval shape. The first conductor, the second conductor, the fourth conductor, and the fifth conductor may each have a belt-like shape in a top view. The third conductor may be provided such that a direction of a major axis of the third conductor in a top view is not the same as and is not orthogonal to a longitudinal direction of each of the first conductor, the second conductor, the fourth conductor, and the fifth conductor in a top view.

Each of the first semiconductor and the second semiconductor is preferably an oxide semiconductor. The oxide semiconductor preferably includes any one or more selected from In, Ga, and Zn.

### Effect of the Invention

According to one embodiment of the present invention, a semiconductor device with a reduced number of steps can be provided. A semiconductor device having high reliability of data reading can be provided. A semiconductor device with low parasitic capacitance can be provided. A semiconductor device that can be highly integrated can be provided. A semiconductor device having favorable electrical characteristics can be provided. A semiconductor device with high reliability can be provided. A semiconductor device with low power consumption can be provided. A novel semiconductor device can be provided. A novel semiconductor device or the like can be provided.

Note that the description of these effects does not preclude the existence of other effects. Note that one embodiment of the present invention does not need to have all of these effects. Other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1 is a diagram illustrating a memory cell.

FIG. 2A and FIG. 2B are circuit diagrams illustrating a memory cell.

FIG. 3 is a timing chart showing operation of a memory cell.

FIG. 4A is a cross-sectional view illustrating a memory cell. FIG. 4B and FIG. 4C are cross-sectional views each illustrating a defect of the memory cell.

FIG. 5A is a diagram illustrating a memory cell array. FIG. 5B is a layout diagram of the memory cell array.

FIG. 6A and FIG. 6B are side views each illustrating the positional relation of wirings. FIG. 6C to FIG. 6F are top views each illustrating the positional relation of the wirings.

FIG. 7A is a cross-sectional view illustrating a memory cell. FIG. 7B is a diagram illustrating a memory cell array.

FIG. 8A is a diagram illustrating a memory cell array. FIG. 8B is a layout diagram of the memory cell array.

FIG. 9A and FIG. 9B are side views each illustrating the positional relation of wirings. FIG. 9C to FIG. 9F are top views each illustrating the positional relation of the wirings.

FIG. 10 is a diagram illustrating a three-dimensional arrangement of a memory cell array.

FIG. 11A and FIG. 11B are diagrams illustrating a transistor.

FIG. 12A and FIG. 12B are diagrams illustrating a structure example of a memory device.

FIG. 13A to FIG. 13G are diagrams each illustrating an example of a circuit configuration of a memory cell.

FIG. 14 is a block diagram illustrating a CPU.

FIG. 15A and FIG. 15B are diagrams illustrating a semiconductor device.

FIG. 16A and FIG. 16B are diagrams each illustrating a semiconductor device.

FIG. 17A and FIG. 17B are diagrams each showing a hierarchy of a variety of memory devices.

FIG. 18 is a block diagram illustrating a structure example of an electronic computer.

FIG. 19A and FIG. 19B are schematic diagrams each illustrating a structure example of the electronic computer.

FIG. 20A to FIG. 20D are schematic diagrams each illustrating a structure example of the electronic computer.

FIG. 21 is a circuit diagram illustrating a structure example of a semiconductor device.

FIG. 22 is a timing chart showing an operation example of a semiconductor device.

FIG. 23A to FIG. 23D are schematic diagrams each illustrating an operation example of a semiconductor device.

FIG. 24 is a timing chart showing an operation example of a semiconductor device.

FIG. 25A to FIG. 25G are schematic diagrams each illustrating an operation example of a semiconductor device.

FIG. 26A and FIG. 26B are diagrams each illustrating an example of an electronic component.

FIG. 27A and FIG. 27B are diagrams each illustrating an example of an electronic device. FIG. 27C to FIG. 27E are diagrams each illustrating an example of a large computer.

FIG. 28 is a diagram illustrating an example of space equipment.

FIG. 29 is a diagram illustrating an example of a storage system that can be used in a data center.

### MODE FOR CARRYING OUT THE INVENTION

Embodiments will be described below with reference to the drawings. Note that the embodiments can be implemented with many different modes, and it is readily understood by those skilled in the art that modes and details thereof can be changed in various ways without departing from the spirit and scope thereof. Thus, the present invention should not be construed as being limited to the description of the embodiments below.

Furthermore, in the drawings, the same reference numerals are used in common for the same portions or portions having similar functions in different drawings, and repeated description thereof is omitted in some cases. The same hatching pattern is applied to portions having similar functions, and the portions are not especially denoted by reference numerals in some cases.

In this specification and the like, an oxynitride is a material that contains more oxygen than nitrogen in its composition. Examples of the oxynitride include silicon oxynitride, aluminum oxynitride, and hafnium oxynitride. Moreover, a nitride oxide is a material that contains more nitrogen than oxygen in its composition. Examples of the nitride oxide include silicon nitride oxide, aluminum nitride oxide, and hafnium nitride oxide.

In this specification and the like, the term “insulator” can be replaced with an insulating film or an insulating layer. Furthermore, the term “conductor” can be replaced with a conductive film or a conductive layer. Moreover, the term “semiconductor” can be replaced with a semiconductor film or a semiconductor layer.

In this specification and the like, “parallel” indicates a state where two straight lines are placed at an angle greater than or equal to −10° and less than or equal to 10°. Accordingly, the case where the angle is greater than or equal to −5° and less than or equal to 5° is also included. Furthermore, “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Accordingly, the case where the angle is greater than or equal to 85° and less than or equal to 95° is also included. Furthermore, “substantially perpendicular” indicates a state where two straight lines are placed at an angle greater than or equal to 60° and less than or equal to 120°. The term “orthogonal” indicates that two straight lines intersect or are connected to each other at an angle greater than or equal to 80° and less than or equal to 100°. Thus, the case where the angle is greater than or equal to 85° and less than or equal to 95° is also included. The terms “approximately orthogonal” and “substantially orthogonal” indicate that two straight lines intersect or are connected to each other at an angle greater than or equal to 60° and less than or equal to 120°.

In the drawings and the like in this specification, arrows indicating the X direction, the Y direction, and the Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. More specifically, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

Moreover, in this specification and the like, terms for describing arrangement, such as “over” and “under”, are used for convenience for describing the positional relation between components with reference to drawings. The positional relation between components is changed as appropriate in accordance with the direction in which the components are described. Thus, without limitation to terms described in this specification, the description can be changed appropriately depending on the situation.

### Embodiment 1

In this embodiment, a semiconductor device, such as a memory device, of one embodiment of the present invention will be described. A memory cell included in the memory device of one embodiment of the present invention includes two transistors.

As the two transistors, vertical transistors each of which includes a channel formation region along a side surface of an opening portion provided in an insulator are used. The vertical transistor has an advantage in that it can easily have a short channel length and a long channel width and thus can easily increase the on-state current. The area occupied by the vertical transistor can be small in a top view. Accordingly, the use of the vertical transistor in a memory cell enables formation of a memory device that can operate at high speed and has a high integration degree.

The two transistors can have the same structure; when the transistors are stacked vertically, the cell density can be the highest. However, in the case where transistors are stacked, unevenness due to the components of the transistors serves as an instability factor of the manufacturing process. Accordingly, planarization steps, such as a challenging step of filling a via and steps of forming and polishing a thick insulating layer, are performed, for example. These steps are performed many times in accordance with the number of stacked layers, which is one factor of increasing the number of steps in total. Therefore, in one embodiment of the present invention, some unevenness due to components of the lower transistor is allowed, and the upper transistor is placed at a position where the unevenness does not cause a defect, whereby the number of steps is reduced.

A plurality of wirings are connected to the memory cell, and parasitic capacitance is generated between a data retention portion of the memory cell and each of the wirings. Capacitive coupling due to the parasitic capacitance may vary the potential of the data retention portion along with change in wiring potential, which might impair the reliability of data reading. In the memory device of one embodiment of the present invention, the electrostatic capacitance of the parasitic capacitance can be reduced with an appropriate arrangement of the wirings, and thus the reliability of data reading can be improved. In addition, the electrostatic capacitance of parasitic capacitance generated between the wirings can be reduced, bringing an increase in operation speed and a reduction in power consumption of the memory device.

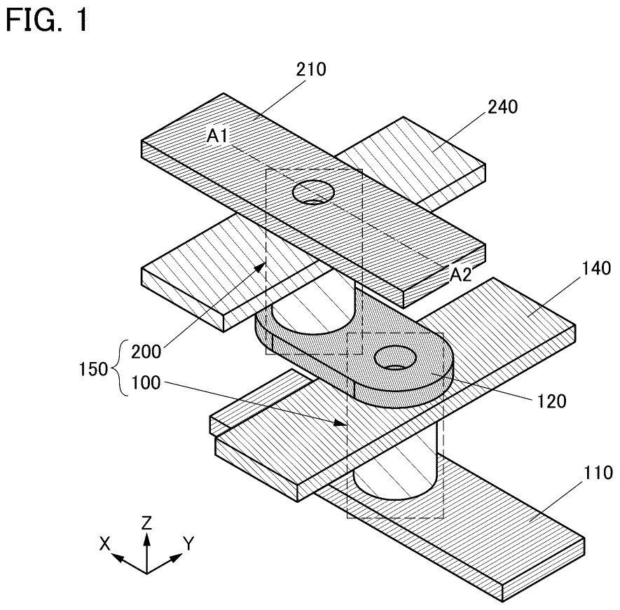

FIG. 1 is a perspective view illustrating part of the memory device of one embodiment of the present invention and illustrates a memory cell 150 (a transistor 100 and a transistor 200) and wirings. Note that the wiring can also include one region of a component of a transistor, such as an electrode. Furthermore, a wiring, an electrode, and the like can also be referred to as a conductor.

The transistor 100 and the transistor 200 are vertical transistors and the transistor 200 is provided obliquely above the transistor 100. The memory cell 150 is electrically connected to a wiring 110, a wiring 140, a wiring 240, and a wiring 210. Note that for clarity, an insulator such as an interlayer film is not illustrated in FIG. 1.

The transistor 100 includes the wiring 110, the wiring 140, and a conductor 120 as its components. The transistor 200 includes the conductor 120, the wiring 240, and the wiring 210 as its components.

The wiring 110 includes a region functioning as one of a source electrode and a drain electrode of the transistor 100. The wiring 140 includes a region functioning as the other of the source electrode and the drain electrode of the transistor 100.

The conductor 120 includes a region functioning as a gate electrode of the transistor 100 and a region functioning as one of a source electrode and a drain electrode of the transistor 200. In other words, the conductor 120 includes a region shared by the gate electrode of the transistor 100 and the one of the source electrode and the drain electrode of the transistor 200.

The wiring 240 includes a region functioning as the other of the source electrode and the drain electrode of the transistor 200.

The wiring 210 includes a region functioning as a gate electrode of the transistor 200. Note that a structure in which the conductor functioning as a gate electrode is provided and the wiring 210 is provided to have electrical connection with the conductor can be employed. The structures and connection modes of the transistors are described in detail later.

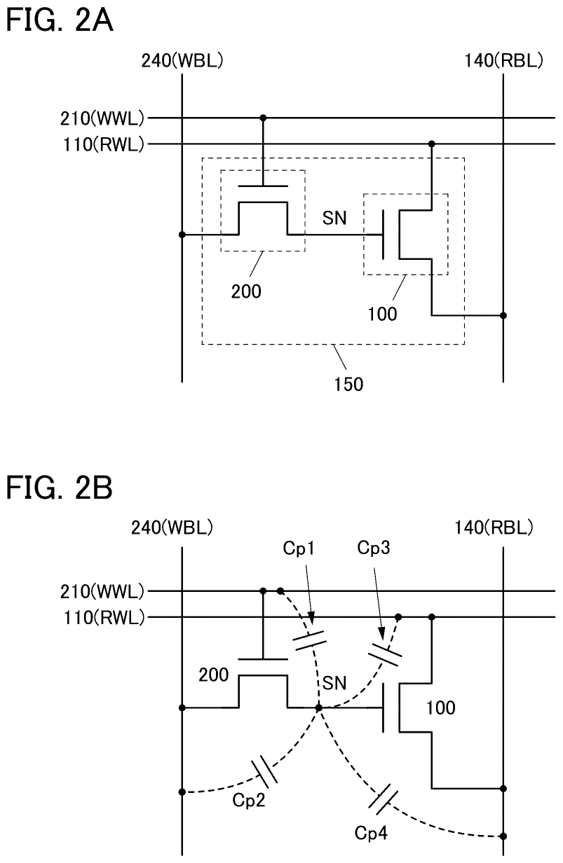

FIG. 2A is a diagram illustrating an example of a circuit diagram of the memory cell 150. The transistor 100 has a function of reading data. The transistor 200 has a function of writing data.

One of a source and a drain of the transistor 200 is electrically connected to a gate of the transistor 100. The conductor 120 serves this connection structure in FIG. 1. The conductor 120 can also be referred to as a component of a node SN that retains a data potential in the memory cell 150 illustrated in FIG. 2A.

The wiring 210 connected to the gate of the transistor 200 is a wiring that supplies a write word signal to the memory cell 150 and also referred to as a write word line (WWL). The write word signal is a signal that controls the timing of data writing to the memory cell 150.

The wiring 240 connected to the other of the source and the drain of the transistor 200 is a wiring that supplies a potential corresponding to a data signal (data) to the memory cell 150 and also referred to as a write bit line (WBL). The data signal is a signal written to the memory cell 150 and represented by two values which are a high-level (also referred to as “1” or V_{H}) and a low-level (also referred to as “0” or V_{L}).

The wiring 110 connected to the one of the source and the drain of the transistor 100 is a wiring that supplies a read word signal to the memory cell 150 and also referred to as a read word line (RWL). The read word signal is a signal that controls the timing of data reading from the memory cell 150.

The wiring 140 connected to the other of the source and the drain of the transistor 100 is a wiring for reading a potential corresponding to a data signal (data) retained in the memory cell 150 and also referred to as a read bit line (RBL). A current flows through the transistor 100 in accordance with the data (“1” or “0”) written to the memory cell 150, so that the potential of the precharged wiring 140 is changed. The potential is input to a sense amplifier or the like, whereby data can be read.

Here, parasitic capacitance generated between the node SN and each wiring is described. As illustrated in FIG. 1, when the focus is placed on the conductor 120, which is the component of the node SN, an insulator that is not illustrated is provided between the conductor 120 and each wiring, which means that a plurality of parasitic capacitances are formed.

Here, for simple description, parasitic capacitance generated between the node SN and one wiring is collectively described as one parasitic capacitance. As illustrated in FIG. 2B, parasitic capacitance Cp1 is generated between the node SN and the wiring 210. Parasitic capacitance Cp2 is generated between the node SN and the wiring 240. Parasitic capacitance Cp3 is generated between the node SN and the wiring 110. Parasitic capacitance Cp4 is generated between the node SN and the wiring 140. Note that a component of the transistor 100 or the transistor 200 are also included in the components of the parasitic capacitances.

Since the node SN is floating, when the potentials of wirings vary, the potential of the node SN also varies by capacitive coupling by the influence of any one or more of the parasitic capacitances Cp1 to Cp4. The range of potential variation of the node SN depends on the amounts of potential variation of wirings and the electrostatic capacitances of parasitic capacitances; however, when the potential variation of the node SN is too large, the transistor 100 does not operate normally and thus data cannot be read accurately in some cases.

In one embodiment of the present invention, with an appropriate arrangement of wirings and a memory cell, a change in the potential of the node SN due to parasitic capacitance can be made small and the accuracy of data reading can be increased.

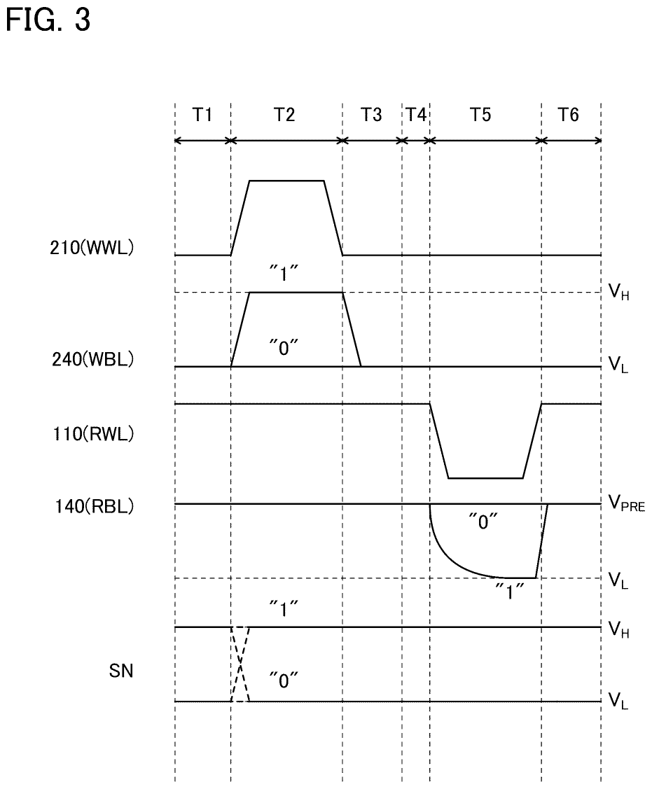

Next, the operation of the memory cell 150 will be described with reference to FIG. 3. Here, an ideal operation where the influence of parasitic capacitances is eliminated is described. FIG. 3 is a timing chart for showing an operation example of the memory cell 150 illustrated in FIG. 2A.

In FIG. 3, the potentials supplied to the wiring 210 (WWL), the wiring 240 (WBL), and the wiring 110 (RWL), the potential read to the wiring 140 (RBL), and the potential of the node SN are illustrated. Note that in FIG. 3, the wiring 240 (WBL) is set to the low level (VL) in the standby state.

Period T1 is a standby period. Period T2 is a write period. Period T3 is a standby period. Periods T4 and T5 are read periods. Period T6 is a standby period. Note that FIG. 3 illustrates data “1” or “0” written to the memory cell 150 (the node SN) through the wiring 240 (WBL). The data written to the memory cell 150 is data “1” when the wiring 240 is set to the high level and is data “0” when the wiring 240 is set to the low level.

FIG. 3 illustrates data “1” or “0” read from the memory cell 150 through the wiring 140 (RBL). The wiring 140 (RBL) is precharged to a high-level potential (e.g., a high power supply potential such as VDD) in the read period, and data is read to an external read circuit connected to the wiring 140 (RBL) in accordance with a change in the precharged potential.

When the data retained in the memory cell 150 (the node SN) is data “1”, a large amount of current flows through the transistor 100, whereby the potential of the wiring 140 (RBL) is lowered. When the data retained in the memory cell 150 (the node SN) is data “0”, a small amount of current flows through the transistor 100, whereby a variation in the potential of the wiring 140 (RBL) is small. That is, when the data retained in the memory cell 150 (the node SN) is data “1”, the potential of the wiring 140 (RBL) turns to the low level. When the data retained in the memory cell 150 (the node SN) is data “0”, the potential of the wiring 140 (RBL) turns to the high level (the precharged potential).

In Period T1, the wiring 210 (WWL) is at the low level, the wiring 240 (WBL) is at the low level (V_{L}), the wiring 110 (RWL) is at the high level, and the wiring 140 (RBL) is at the high level. At this time, the transistor 200 is in the non-conducting state. A current does not flow through the transistor 100 since the potentials of the terminals serving as the source and the drain are equal to each other. Note that the potential of the gate of the transistor 100 (the node SN) is the potential V_{H} or V_{L} written in the previous write period.

In Period T2, the wiring 210 (WWL) is at the high level, the wiring 240 (WBL) is the signal corresponding to data (VH or VL), the wiring 110 (RWL) is at the high level, and the wiring 140 (RBL) is at the high level. At this time, the transistor 200 is in the conducting state, and the potential of the gate of the transistor 100 (the node SN) becomes a potential corresponding to the data. A current does not flow through the transistor 100 regardless of the potential of the gate since the potentials of the terminals serving as the source and the drain are equal to each other.

In Period T3, the wiring 210 (WWL) is at the low level, the wiring 240 (WBL) is at the low level (VL), the wiring 110 (RWL) is at the high level, and the wiring 140 (RBL) is at the high level. At this time, the transistor 100 and the transistor 200 are both in the non-conducting state. In Period T3, the potential written to the gate of the transistor 100 (the node SN) is retained. A current does not flow through the transistor 100 regardless of the potential of the gate since the potentials of the terminals serving as the source and the drain are equal to each other.

In Period T4, the wiring 210 (WWL) is at the low level, the wiring 240 (WBL) is at the low level (V_{L}), and the wiring 110 (RWL) is at the high level. The wiring 140 (RBL) is precharged to the high level (also referred to as a precharge potential V_{PRE}). At this time, the transistor 200 is in the non-conducting state. The precharged voltage V_{PRE} is, for example, VDD and is equal to the high level of the wiring 140 (RBL). A current does not flow through the transistor 100 regardless of the potential of the gate (the node SN) since the potentials of the terminals serving as the source and the drain are equal to each other. In other words, the potential of the wiring 140 does not change.

In Period T5, the wiring 210 (WWL) is at the low level, the wiring 240 (WBL) is at the low level (V_{L}), and the wiring 110 (RWL) is at the low level. At this time, the transistor 200 is in the non-conducting state. In Period T5, the wiring 140 (RBL) is brought into an electrically floating state. That is, the potential varies in accordance with the current flowing through the transistor 100 in the memory cell 150.

In the period T5, a potential difference occurs between the terminals serving as the source and the drain of the transistor 100, and a current flows through the transistor 100 in accordance with the potential of the gate (the node SN). In the case where data “1” is retained in the memory cell 150, a large current flows through the transistor 100 and the potential of the wiring 140 (RBL) is lowered to the low level. By this change in the potential of the wiring 140 (RBL), a sense amplifier connected to the wiring 140 (RBL) can be activated and the data in the selected memory cell 150 can be read to the outside.

In the case where data “0” is retained in the memory cell 150, a small current flows through the transistor 100 and the potential of the wiring 140 (RBL) changes little from the high-level potential (the precharged potential).

In the memory cell 150 in a non-selected row in the period T5, the wiring 110 (RWL) is at the high level and a current does not flow through the transistor 100 regardless of the potential of the gate since the potentials of the terminals serving as the source and the drain are equal.

In Period T6, the wiring 210 (WWL) is at the low level, the wiring 240 (WBL) is at the low level (V_{L}), the wiring 110 (RWL) is at the high level, and the wiring 140 (RBL) is at the high level. At this time, the transistor 200 is in the non-conducting state. A current does not flow through the transistor 100 regardless of the potential of the gate since the potentials of the terminals serving as the source and the drain are equal.

Through the above operations, data can be read from the memory cell 150 in the selected row. In practice, the parasitic capacitances affect and decrease the data reading reliability in some cases.

### Structure Example of Memory Cell

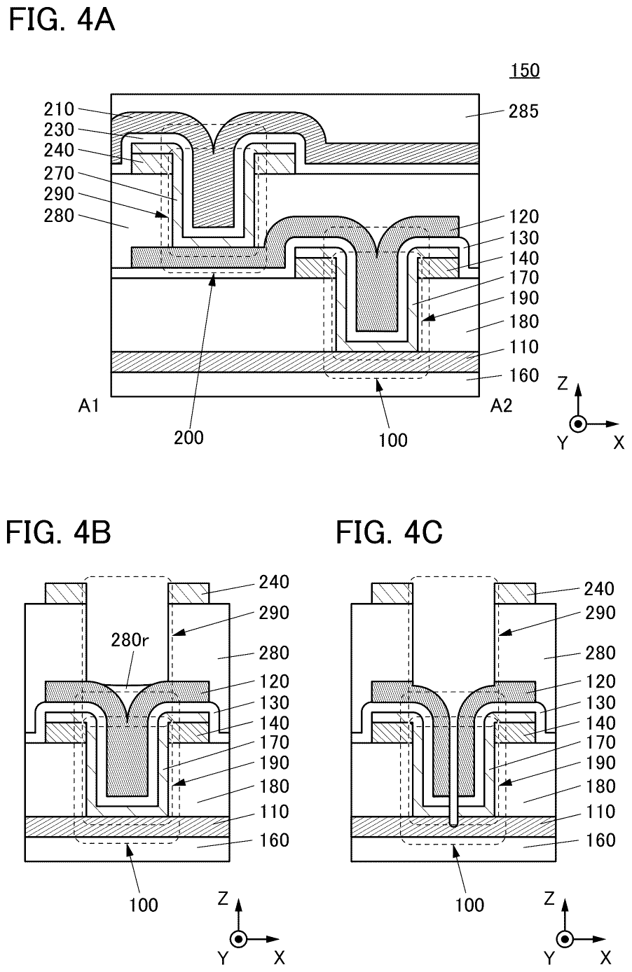

Next, a structure example of the memory cell 150 is described. FIG. 4A is a diagram illustrating a cross section taken along A1-A2 in FIG. 1.

The memory cell 150 includes an insulator 160 over a substrate (not illustrated), the transistor 100 over the insulator 160, and the transistor 200 obliquely above the transistor 100. Between the transistors and between the wirings, an insulator 180, an insulator 280, an insulator 285, and the like functioning as interlayer films can be provided.

The transistor 100 includes the oxide semiconductor 170, an insulator 130, and the conductor 120. The oxide semiconductor 170 functions as a semiconductor layer, the insulator 130 functions as a gate insulator, and the conductor 120 functions as the gate electrode. The wiring 110 includes a region that functions as the one of the source electrode and the drain electrode of the transistor 100. The wiring 140 includes a region that functions as the other of the source electrode and the drain electrode of the transistor 100.

The insulator 180 and the wiring 140 are provided over the insulator 160 and the wiring 110. An opening portion 190 penetrating through the insulator 180 and the wiring 140 and reaching the wiring 110 is provided. The opening portion 190 has a pillar shape with a substantially circular top surface. With such a structure, miniaturization and an increase in integration degree of memory cells can be achieved. Note that the side surface of the opening portion 190 is preferably perpendicular to the top surface of the wiring 110.

At least part of the oxide semiconductor 170 is placed in the opening portion 190. Note that the oxide semiconductor 170 includes a region in contact with the top surface of the wiring 110, a region in contact with the side surface of the wiring 140, and a region in contact with the side surface of the insulator 180 in the opening portion 190.

The insulator 130 is placed so as to at least partly cover the opening portion 190. The conductor 120 is placed such that at least part of the conductor 120 is positioned in the opening portion 190. The conductor 120 is preferably provided so as to be embedded in the opening portion 190.

In order to reduce the parasitic capacitance, the conductor 120 preferably has a small area overlapping with each wiring. That is, the area of the conductor 120 in the top view is preferably as small as possible. The conductor 120 also has a function of a wiring electrically connecting the transistor 100 and the transistor 200; thus, the top view is preferably a rectangular shape. Further preferably, the top view is an elliptical shape or an oval shape (see FIG. 1) that can have a smaller area than a rectangular shape.

The transistor 200 includes an oxide semiconductor 270, an insulator 230, and the wiring 210. The oxide semiconductor 270 functions as a semiconductor layer, the insulator 230 functions as a gate insulator, and the wiring 210 functions as the gate electrode. The conductor 120 includes a region that functions as the one of the source electrode and the drain electrode of the transistor 200. The wiring 240 includes a region that functions as the other of the source electrode and the drain electrode of the transistor 200.

The insulator 280 and the wiring 240 are provided over the insulator 130 and the conductor 120. An opening portion 290 penetrating through the insulator 280 and the wiring 240 and reaching the conductor 120 is provided. The opening portion 290 has a pillar shape with a substantially circular top surface. With such a structure, the memory cell can be miniaturized and highly integrated. Note that the side surface of the opening portion 290 is preferably perpendicular to the top surface of the conductor 120.

At least part of the oxide semiconductor 270 is placed in the opening portion 290. The oxide semiconductor 270 includes a region in contact with the top surface of the conductor 120, a region in contact with the side surface of the wiring 240, and a region in contact with the side surface of the insulator 280 in the opening portion 290.

The insulator 230 is placed so as to at least partly cover the opening portion 290. The wiring 210 is placed such that at least part of the wiring 210 is positioned in the opening portion 290. The wiring 210 is preferably provided so as to be embedded in the opening portion 290. Note that a conductor may be provided to fill the opening portion 290, and the wiring 210 may be formed over the conductor.

It is preferable that the diameter of the opening portion 190 and the diameter of the opening portion 290 be substantially the same, and the transistor 100 and the transistor 200 have substantially the same structure. For example, when the electrodes (wirings) included in the two transistors are formed to have the minimum feature size (F), the memory cells 150 can be arranged densely and the memory capacity of the memory device can be increased. In other words, the memory device can be highly integrated.

Furthermore, the one of the source electrode and the drain electrode of the transistor 200 and the gate electrode of the transistor 100 share the same region; in other words, the transistor 200 and the transistor 100 are directly connected without a wiring or the like therebetween. Accordingly, electric resistance between the transistors can be minimum and data writing or the like can be performed quickly.

As illustrated in FIG. 1 and FIG. 4A, the transistor 200 is provided obliquely above the transistor 100. That is, the opening portion 290 is provided obliquely above the opening portion 190. As described above, when two transistors are placed to overlap with each other vertically, the cell area can be the smallest. Meanwhile, time is taken to eliminate unevenness due to components of the transistors.

In a structure where the opening portion 290 is provided directly over the opening portion 190, defects might be induced when eliminating unevenness is not performed. FIG. 4B and FIG. 4C are diagrams illustrating a step of providing the opening portion 290 directly over the opening portion 190. For example, as illustrated in FIG. 4B, an upper portion of the conductor 120 is depressed owing to the shape of the opening portion 190 in the transistor 100, and an etching residue 280r of the insulator 280 is generated in the depressed portion in the formation of the opening portion 290 in some cases. This etching residue 280r induces a contact defect between the conductor 120 and the oxide semiconductor 270 provided in a later step.

As illustrated in FIG. 4C, in the case where the insulator 280 is overetched or the opening portion 190 is not sufficiently filled with the conductor 120, the etching proceeds deeply to induce a contact defect and disconnection in some cases. For this reason, in the case where the opening portion 290 is provided directly over the opening portion 190, it is preferable to avoid the unevenness by heavily performing planarization steps or challenging filling steps that do not cause a depressed portion in the upper portion of the conductor 120.

In view of the above, in one embodiment of the present invention, as illustrated in FIG. 4A, the conductor 120 is extended in one direction and the opening portion 290 is formed over a region where the conductor 120 is flat in order to eliminate the influence of the depressed portion generated in the conductor 120. Such a structure can eliminate defects due to the unevenness without increasing the number of steps. In this structure, the depressed portion generated in the conductor 120 does not affect the next step; thus, a planarization step or the like can be omitted.

As described above, the influence of parasitic capacitance on the conductor 120 is preferably eliminated as much as possible. Since the electrostatic capacitance C=ε×S/d (ε: dielectric constant, S: electrode area, and d: dielectric thickness), reducing the area of the conductor 120 overlapping with a wiring in the vicinity of the conductor 120 can reduce parasitic capacitance.

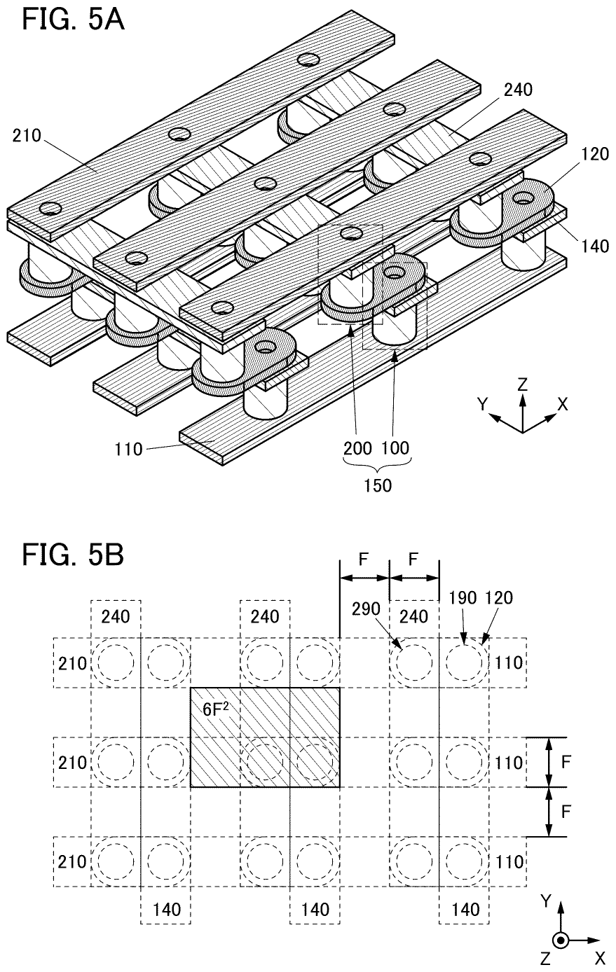

A wiring that is closest to the conductor 120 is the wiring 140, followed by the wiring 240. As described above, the conductor 120 preferably has an elliptical shape or an oval shape in the top view. The wiring 140 and the wiring 240 each have a belt-like shape in the top view. Thus, as illustrated in the layout diagrams of FIG. 1, FIG. 4A, and FIG. 5B that is used for description later, the conductor 120 is placed such that the direction of the major axis of the conductor 120 intersects perpendicularly with the longitudinal directions of the wiring 140 and the wiring 240. With such a structure, the area of the conductor 120 overlapping with the wiring 140 and the area of the conductor 120 overlapping with the wiring 240 can be reduced, so that the parasitic capacitance Cp2 and the parasitic capacitance Cp4 (see FIG. 2B) can be reduced.

The wirings closest to the conductor 120, following the wiring 140 and the wiring 240, are the wiring 110 and the wiring 210. These wirings each also have a belt-like shape in the top view, and when the direction of the major axis of the conductor 120 intersects perpendicularly with the longitudinal directions of the wiring 110 and the wiring 210, the parasitic capacitance Cp1 and the parasitic capacitance Cp3 (see FIG. 2B) formed between the conductor 120 and the wiring 110 and between the conductor 120 and the wiring 210 can be reduced.

However, this structure significantly increases the parasitic capacitance formed between the wiring 110 and the wiring 140 and the parasitic capacitance formed between the wiring 210 and the wiring 240, which leads to a delay in operation and an increase in power consumption. Thus, as illustrated in FIG. 1, FIG. 4A, and FIG. 5B, the longitudinal directions of the wiring 110 and the wiring 210 are preferably orthogonal to the wiring 140 and the wiring 240.

FIG. 5A is a perspective view illustrating an example of a memory cell array in which a plurality of the memory cells 150 described above are arranged two-dimensionally, and FIG. 5B is a layout diagram of the memory cell array seen from above. When the widths of the wiring 110, the wiring 210, the wiring 140, and the wiring 240 and the width of the conductor 120 in the short axis direction are the minimum feature size (F), the area per memory cell 150 can be 6 F².

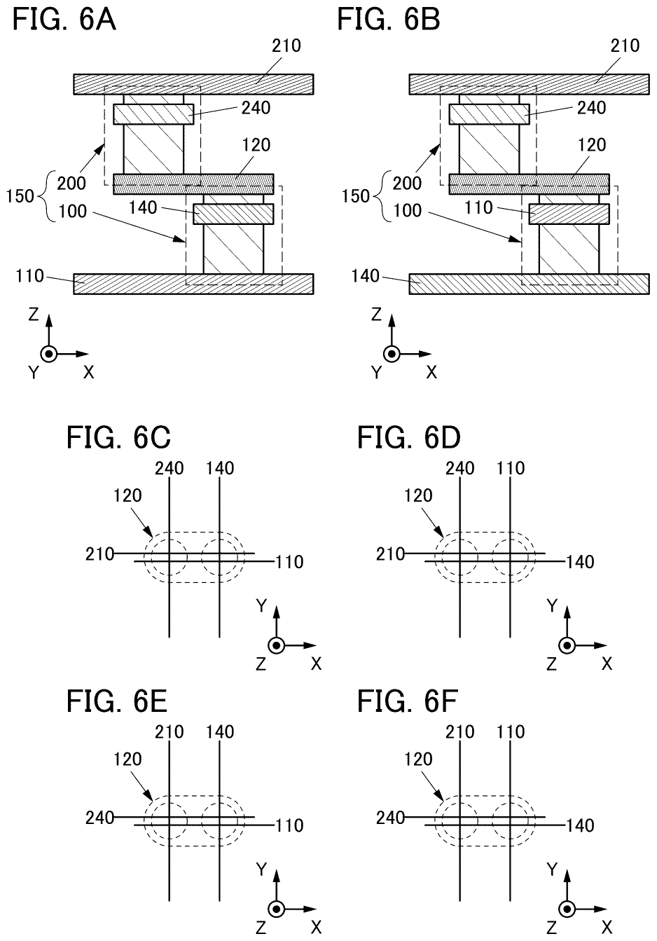

Note that in the above description of the memory cell 150, as illustrated in the side view of the memory cell 150 in FIG. 6A, the wiring provided in the lower portion of the transistor 100 is referred to as the wiring 110, and the wiring positioned close to the conductor 120 is referred to as the wiring 140; however, one embodiment of the present invention is not limited thereto. For example, as illustrated in FIG. 6B, the wiring provided in the lower portion of the transistor 100 may be referred to as the wiring 140, and the wiring positioned close to the conductor 120 may be referred to as the wiring 110.

In the case where the positional relation between the wirings in the height direction in FIG. 6A or FIG. 6B is maintained, the longitudinal direction of each wiring may be the same as or orthogonal to the direction of the major axis of the conductor 120. Note that in order to reduce electrostatic capacitance between the wirings, the wiring 110 and the wiring 140 are preferably orthogonal to each other and the wiring 210 and the wiring 240 are preferably orthogonal to each other.

For example, as illustrated in FIG. 6C, the direction of the major axis of the conductor 120 and the longitudinal directions of the wiring 110 and the wiring 210 can be the same, and the longitudinal directions of the wiring 140 and the wiring 240 can be orthogonal to each other. Alternatively, as illustrated in FIG. 6D, the direction of the major axis of the conductor 120 and the longitudinal directions of the wiring 140 and the wiring 210 can be the same, and the longitudinal directions of the wiring 110 and the wiring 240 can be orthogonal to each other. Alternatively, as illustrated in FIG. 6E, the direction of the major axis of the conductor 120 and the longitudinal directions of the wiring 110 and the wiring 240 can be the same, and the longitudinal directions of the wiring 140 and the wiring 210 can be orthogonal to each other. Alternatively, as illustrated in FIG. 6F, the direction of the major axis of the conductor 120 and the longitudinal directions of the wiring 140 and the wiring 240 can be the same, and the longitudinal directions of the wiring 110 and the wiring 210 can be orthogonal to each other.

Note that in FIG. 6C to FIG. 6F, for clarity, two wirings provided in the same direction as the direction of the major axis of the conductor 120 are separately illustrated; however, in practice, the two wirings are placed to include a region where they overlap with each other.

Although unevenness due to the opening portion 190 is regarded as a problem in the above, unevenness due to the wiring 140 and unevenness due to the oxide semiconductor 170 are also a problem. FIG. 4A illustrates an example in which the opening portion 290 is formed over a region where the conductor 120 is flat by avoiding not only the unevenness due to the opening portion 190 but also the unevenness due to the wiring 140 and the oxide semiconductor 170. Here, it can be said that the opening portion 190 and the opening portion 290 can be further close to each other and the cell density can be increased if the unevenness due to the wiring 140 and the oxide semiconductor 170 is not formed.

To prevent unevenness due to the wiring 140 and the oxide semiconductor 170 from being formed, the conductor 120 and the wiring 140 are placed such that the direction of the major axis of the conductor 120 is the same as the longitudinal direction of the wiring 140. Note that the oxide semiconductor 170 is provided to overlap with the wiring 140. The parasitic capacitance Cp4 (see FIG. 2) formed between the conductor 120 and the wiring 140 is allowed (without hindering the reading reliability).

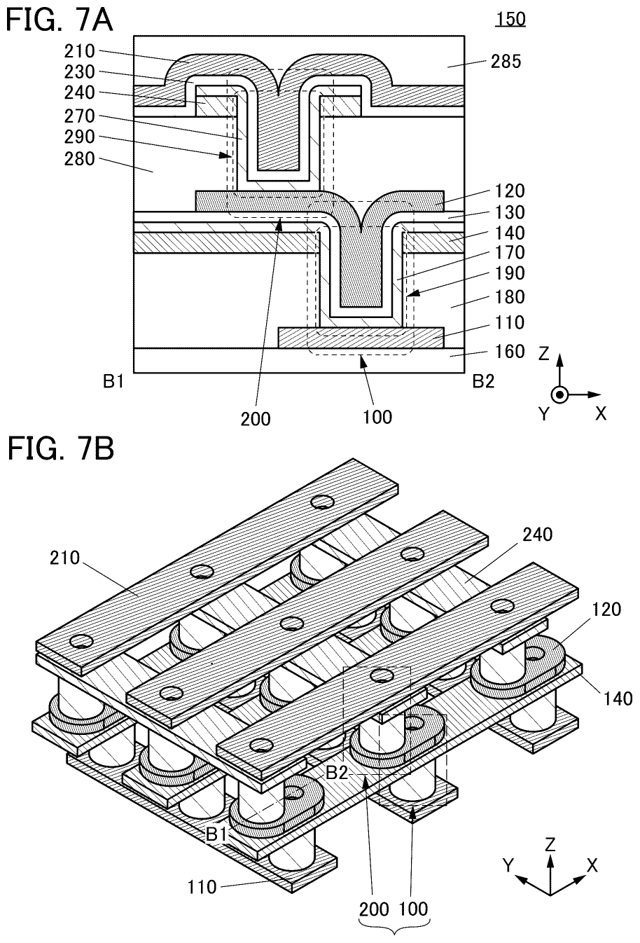

FIG. 7A is a cross-sectional view illustrating the case where the direction of the major axis of the conductor 120 and the longitudinal direction of the wiring 140 are the same. With the arrangement that makes the direction of the major axis of the conductor 120 and the longitudinal direction of the wiring 140 the same, that is, with the structure in which the whole conductor 120 overlaps with the wiring 140, unevenness due to the wiring 140 as illustrated in FIG. 4A is not formed. With such a structure, the opening portion 190 and the opening portion 290 can be close to each other within a range where the depressed portion of the conductor 120 due to the opening portion 190 does not have an adversely influence.

Note that when the depressed portion of the conductor 120 and the opening portion 290 overlap with each other, the opening portion 290 does not have a uniform depth and a portion where the channel length changes is formed in the transistor 200. Accordingly, the reliability and electric characteristics of the transistor 200 might be degraded. Thus, the depressed portion of the conductor 120 and the opening portion 290 are preferably apart from each other. Since the depressed portion of the conductor 120 is caused by the opening portion 190, it can be said that the opening portion 190 and the opening portion 290 are preferably apart from each other so as not to overlap with each other in the top view.

FIG. 7B is a perspective view illustrating an example of a memory cell array in which the memory cells 150 illustrated in FIG. 7A are arranged two-dimensionally. FIG. 7A corresponds to a cross section taken along line B1-B2 in FIG. 7B. In this structure, the distance between the opening portion 190 and the opening portion 290 in the top view can be shorter than that in the structure illustrated in FIG. 5A and FIG. 5B; thus, the cell area can be smaller than 6 F². Since the area of the conductor 120 can be smaller than that in the structure illustrated in FIG. 5A and FIG. 5B, the electrostatic capacitance of parasitic capacitance generated between the conductor 120 and each wiring can be reduced.

Note that a structure may be employed in which the direction of the major axis of the conductor 120 is not the same as the longitudinal directions of the wiring 110, the wiring 210, the wiring 140, and the wiring 240 and is not orthogonal to the longitudinal directions of the wirings.

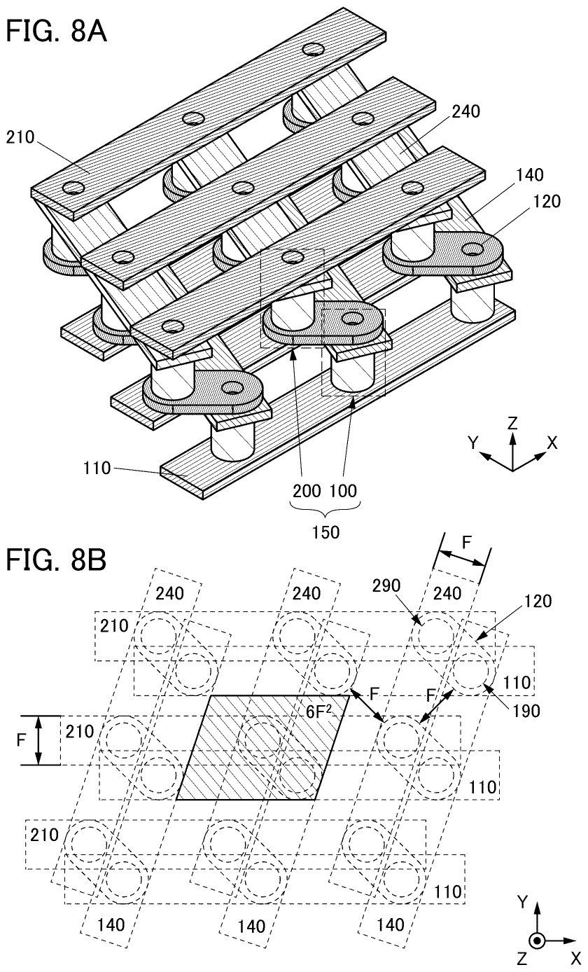

FIG. 8A is a perspective view illustrating a memory cell array when the conductor 120 is inclined with respect to the longitudinal direction of the wiring 110, and FIG. 8B is a layout diagram seen from above. When the widths of the wiring 110, the wiring 210, the wiring 140, and the wiring 240 and the width of the conductor 120 in the short axis direction are the minimum feature size (F), the area per memory cell 150 can be 6 F².

In the structure illustrated in FIG. 5A and FIG. 5B, since the direction of the major axis of the conductor 120 is the same as and overlaps with the longitudinal directions of the wiring 110 and the wiring 210, the parasitic capacitances Cp1 and Cp3 (see FIG. 2B) are relatively large. Furthermore, since the wiring 110 and the wiring 210 are provided to overlap with each other, the electrostatic capacitance of parasitic capacitance generated between these wirings also increases.

Meanwhile, in the structure illustrated in FIG. 8A and FIG. 8B, since the direction of the major axis of the conductor 120 is different from the longitudinal directions of the all wirings, the area where the conductor 120 overlaps with the wiring 110 and the area where the conductor 120 overlaps with the wiring 210 are small; thus, the electrostatic capacitance of the parasitic capacitances Cp1 and Cp3 can be smaller than that in the structure illustrated in FIG. 5A and FIG. 5B. Furthermore, since the area where the wiring 110 and the wiring 210 overlap with each other is also small, the electrostatic capacitance of parasitic capacitance generated between these wirings can be small; thus, the operation speed can be improved and the power consumption can be reduced.

Although FIG. 8A and FIG. 8B illustrate the structure in which the direction of the conductor 120 is inclined at an angle of 45° with respect to the longitudinal direction of the wiring 110, the angle is not limited. Depending on the angle, the areas where the conductor 120 overlaps with the wirings and the areas where the wirings overlap with each other become different, and the electrostatic capacitance of each of the parasitic capacitances illustrated in FIG. 2B and the electrostatic capacitance between the wirings change. Accordingly, the angle may be determined as appropriate in consideration of the influence of the parasitic capacitances and the parasitic capacitance between wirings illustrated in FIG. 2B.

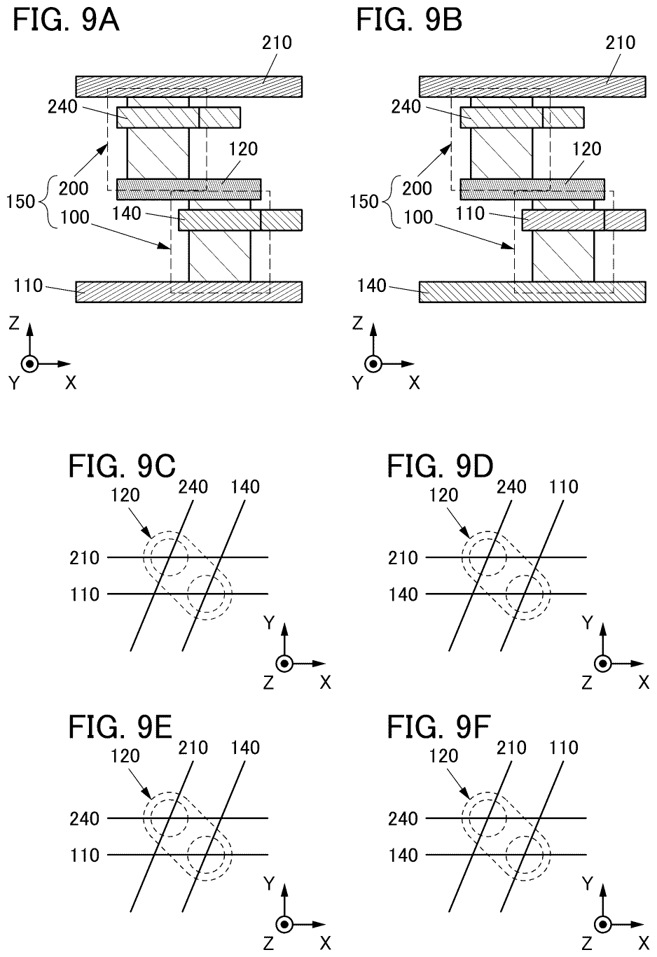

Note that in the structure illustrated in FIG. 8A and FIG. 8B, as illustrated in the side view of the memory cell 150 in FIG. 9A, the wiring provided in the lower portion of the transistor 100 is referred to as the wiring 110, and the wiring positioned close to the conductor 120 is referred to as the wiring 140; however, one embodiment of the present invention is not limited thereto. For example, as illustrated in FIG. 9B, the wiring provided in the lower portion of the transistor 100 may be referred to as the wiring 140, and the wiring positioned close to the conductor 120 may be referred to as the wiring 110.

In the case where the positional relation between the wirings in the height direction in FIG. 9A or FIG. 9B is maintained, the longitudinal direction of each wiring is not limited. The direction of each wiring in the longitudinal direction is determined in consideration of the influence of the parasitic capacitances and the parasitic capacitance between wirings illustrated in FIG. 2.

For example, as illustrated in FIG. 9C, the wiring 110 and the wiring 210 arranged in parallel can intersect with the wiring 140 and the wiring 240 arranged in parallel. Alternatively, as illustrated in FIG. 9D, the wiring 140 and the wiring 210 arranged in parallel can intersect with the wiring 110 and the wiring 240 arranged in parallel. Alternatively, as illustrated in FIG. 9E, the wiring 110 and the wiring 240 arranged in parallel can intersect with the wiring 140 and the wiring 210 arranged in parallel. Alternatively, as illustrated in FIG. 9F, the wiring 140 and the wiring 240 arranged in parallel can intersect with the wiring 110 and the wiring 210 arranged in parallel.

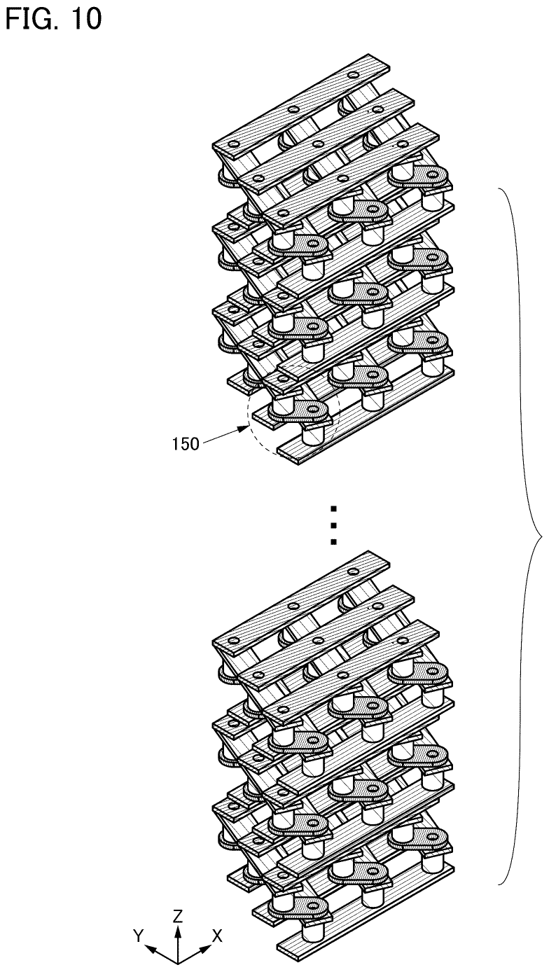

Note that memory cell arrays in which the memory cells 150 are two-dimensionally arranged are three-dimensionally arranged as illustrated in FIG. 10 to increase the memory capacity. The memory cell array can include n layers stacked (n is an integer greater than or equal to 2) as needed, and can include 100 or more layers, for example. Since the wirings overlap with each other in the height direction, electrical connection through a via is easy and a signal potential can be supplied at a time. When a plurality of reading lines (e.g., the wirings 140) are electrically connected to each other through the via, the same reading circuit can be used.

### Transistors 100 and 200

Next, the details of the transistors 100 and 200 are described. Although the transistor 100 and the transistor 200 are different in the connection mode of the wirings and the like as described above, the transistor 100 and the transistor 200 can be regarded as having basically the same structure in terms of operation, and thus the transistor 200 is described here.

As illustrated in FIG. 4A and the like, the transistor 200 can have a structure including the conductor 120; the wiring 240 over the insulator 280; the oxide semiconductor 270 provided in contact with the top surface of the conductor 120, which is exposed in the opening portion 290, the side surface of the insulator 280 in the opening portion 290, the side surface of the wiring 240 in the opening portion 290, and at least part of the top surface of the wiring 240; the insulator 230 provided in contact with the top surface of the oxide semiconductor 270; and the wiring 210 provided in contact with the top surface of the insulator 230.

At least part of the components of the transistor 200 is placed in the opening portion 290. Here, the bottom portion of the opening portion 290 is also the top surface of the conductor 120, and the side surface of the opening portion 290 is also the side surface of the insulator 280 and the side surface of the wiring 240.

The opening portion 290 has a pillar shape with a substantially circular top surface. With this structure, the memory device can be miniaturized or highly integrated. Note that the side surface of the opening portion 290 is preferably perpendicular to the top surface of the wiring 110.

For miniaturization or high integration of the memory device, the top surface shape of the opening portion 290 where the transistor 200 is formed and the top surface shape of the opening portion 190 where the transistor 100 is formed are preferably the same.

Portions of the oxide semiconductor 270, the insulator 230, and the wiring 210 that are placed in the opening portion 290 reflect the shape of the opening portion 290. Thus, the oxide semiconductor 270 is provided so as to cover the bottom portion and the side surface of the opening portion 290, the insulator 230 is provided to cover the oxide semiconductor 270, and the wiring 210 is provided so as to be embedded in the depressed portion of the insulator 230, which reflects the shape of the opening portion 290.

Although an example where the opening portion 290 is substantially circular in the top view is described in this embodiment, the present invention is not limited thereto. For example, the opening portion 290 may have an elliptical shape, a polygonal shape such as a square shape, or a polygonal shape such as a square shape with rounded corners in the top view. In that case, the maximum width of the opening portion 290 is preferably calculated as appropriate in accordance with the shape of the opening portion 290 in the top view. The maximum width of the wiring 210 is preferably calculated as appropriate in accordance with the shape of the wiring 210 in the top view.

For example, in the case where the opening portion 290 is square in the top view, the maximum width of the opening portion 290 may be the length of a diagonal line of the square. Alternatively, for example, in the case where the opening portion 290 has an elliptical shape, a polygonal shape, or a polygonal shape with rounded corners in the top view, the maximum width of the opening portion 290 may be the diameter of the smallest circle (the minimum bounding circle) including the shape in the top view of the opening portion 290. The description of the shape of the opening portion 290 can also be applied to the opening portion 190.

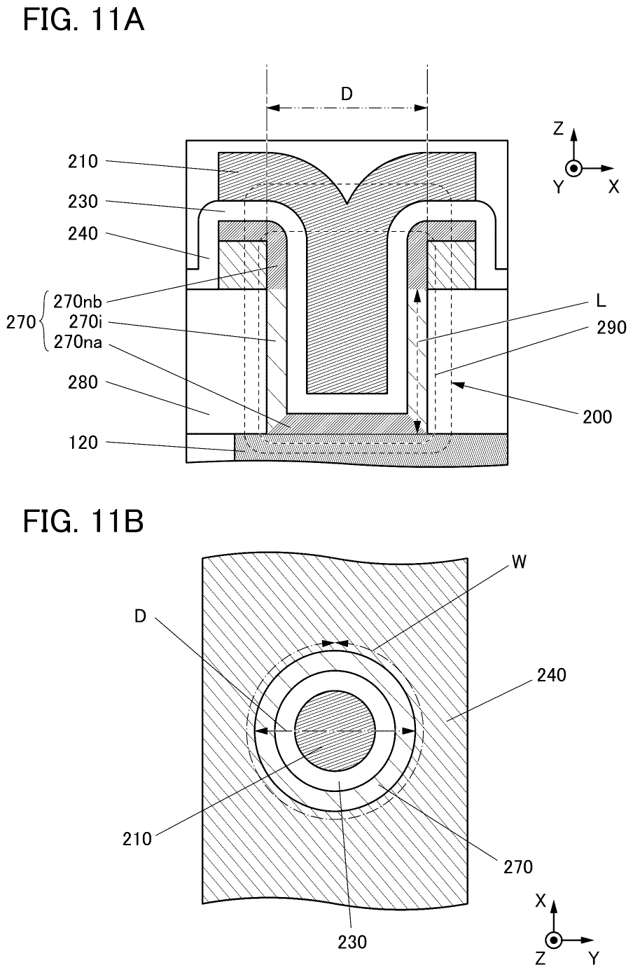

FIG. 11A is an enlarged view of the oxide semiconductor 270 and its vicinity in FIG. 4A. FIG. 11B is a cross-sectional view along the XY plane including the wiring 240.

As illustrated in FIG. 11A, the oxide semiconductor 270 includes a region 270i and a region 270na and a region 270nb provided such that the region 270i is sandwiched therebetween.

The region 270na is a region in contact with the conductor 120 in the oxide semiconductor 270. At least part of the region 270na functions as one of the source region and the drain region of the transistor 200. The region 270nb is a region in contact with the wiring 240 in the oxide semiconductor 270. At least part of the region 270nb functions as the other of the source region and the drain region of the transistor 200. As illustrated in FIG. 11B, the wiring 240 is in contact with all the perimeter of the oxide semiconductor 270. Thus, the other of the source region and the drain region of the transistor 200 can be formed along all the perimeter of a portion formed in the same layer as the wiring 240 in the oxide semiconductor 270.

The region 270i is a region positioned between the region 270na and the region 270nb in the oxide semiconductor 270. At least part of the region 270i functions as the channel formation region of the transistor 200. That is, the channel formation region of the transistor 200 is formed in part of the oxide semiconductor 270 that is positioned in a region between the conductor 120 and the wiring 240. It can be said that the channel formation region of the transistor 200 is positioned in a region in contact with the insulator 280 or a region in the vicinity thereof in the oxide semiconductor 270.

The channel length of the transistor 200 is the distance between the source region and the drain region. In other words, the channel length of the transistor 200 is determined by the thickness of the insulator 280 over the conductor 120. In FIG. 11A, a channel length L of the transistor 200 is indicated by a dashed double-headed arrow. The channel length L is a distance between an end portion of a region where the oxide semiconductor 270 and the conductor 120 are in contact with each other and an end portion of a region where the oxide semiconductor 270 and the wiring 240 are in contact with each other in a cross-sectional view. That is, the channel length L corresponds to the length of the side surface of the insulator 280 on the opening portion 290 side in the cross-sectional view.

In a conventional transistor, the channel length is determined by the light exposure limit of photolithography; meanwhile, in the present invention, the channel length can be determined by the thickness of the insulator 280. Thus, the transistor 200 can have an extremely small channel length smaller than or equal to the light exposure limit of photolithography (e.g., smaller than or equal to 60 nm, smaller than or equal to 50 nm, smaller than or equal to 40 nm, smaller than or equal to 30 nm, smaller than or equal to 20 nm, or smaller than or equal to 10 nm, and larger than or equal to 1 nm, or larger than or equal to 5 nm). Accordingly, the transistor 200 can have a higher on-state current and improved frequency characteristics. Thus, a memory device with high operating speed can be provided.

In addition, as described above, the channel formation region, the source region, and the drain region can be formed in the opening portion 290. Thus, the occupation area of the transistor 200 can be reduced as compared with a conventional transistor in which a channel formation region, a source region, and a drain region are provided separately on the XY plane. This allows high integration of the memory device, thereby increasing the storage capacity per unit area.

Such a transistor including the channel formation region along the side surface of the insulator 280 in the opening portion 290 is also referred to as a vertical transistor.

Furthermore, as illustrated in FIG. 11B, in the XY plane including the channel formation region of the oxide semiconductor 270, as in FIG. 11B, the oxide semiconductor 270, the insulator 230, and the wiring 210 are provided concentrically. Therefore, the side surface of the wiring 210 provided at the center faces the side surface of the oxide semiconductor 270 with the insulator 230 therebetween. That is, in the top view, all the perimeter of the oxide semiconductor 270 serves as the channel formation region. In this case, for example, the channel width of the transistor 200 is determined by the length of the perimeter of the oxide semiconductor 270. In other words, the channel width of the transistor 200 is determined by the maximum width of the opening portion 290 (the maximum diameter in the case where the opening portion 290 is circular in the top view). In FIG. 11A and FIG. 11B, a maximum width D of the opening portion 290 is indicated by a dashed double-dotted double-headed arrow. In FIG. 11B, a channel width W of the transistor 200 is indicated by a dashed-dotted double-headed arrow. By increasing the maximum width D of the opening portion 290, the channel width per unit area can be increased and the on-state current can be increased.

In the case where the opening portion 290 is formed by a photolithography method, the maximum width D of the opening portion 290 is determined by the light exposure limit of photolithography. In addition, the maximum width D of the opening portion 290 is determined by the thicknesses of the oxide semiconductor 270, the insulator 230, and the wiring 210 provided in the opening portion 290. The maximum width D of the opening portion 290 is preferably, for example, larger than or equal to 5 nm, larger than or equal to 10 nm, or larger than or equal to 20 nm and smaller than or equal to 100 nm, smaller than or equal to 60 nm, smaller than or equal to 50 nm, smaller than or equal to 40 nm, or smaller than or equal to 30 nm. In the case where the opening portion 290 is circular in the top view, the maximum width D of the opening portion 290 corresponds to the diameter of the opening portion 290, and the channel width W can be calculated to be “D×π”.

In the memory device of one embodiment of the present invention, the channel length L of the transistor 200 is preferably shorter than at least the channel width W of the transistor 200. The channel length L of the transistor 200 in one embodiment of the present invention is greater than or equal to 0.1 times and less than or equal to 0.99 times, preferably greater than or equal to 0.5 times and less than or equal to 0.8 times the channel width W of the transistor 200. This structure enables a transistor with favorable electrical characteristics and high reliability.

In the case where the opening portion 290 is formed to be substantially circular in the top view, the oxide semiconductor 270, the insulator 230, and the wiring 210 are formed concentrically. This makes the distance between the wiring 210 and the oxide semiconductor 270 substantially uniform, so that a gate electric field can be substantially uniformly applied to the oxide semiconductor 270.

It is preferable that the channel formation region of the transistor including an oxide semiconductor in the semiconductor layer contain fewer oxygen vacancies or have a lower concentration of an impurity such as hydrogen, nitrogen, or a metal element than the source region and the drain region. In some cases, hydrogen in the vicinity of an oxygen vacancy forms a defect that is an oxygen vacancy into which hydrogen has entered (hereinafter sometimes referred to as VoH), which generates an electron serving as a carrier. Thus, it is preferable that VoH be also decreased in the channel formation region. Thus, the channel formation region of the transistor is a high-resistance region having a low carrier concentration. Thus, the channel formation region of the transistor can be regarded as being i-type (intrinsic) or substantially i-type.

The source region and the drain region of the transistor including an oxide semiconductor in the semiconductor layer include more oxygen vacancies, include more VoH, or have a higher concentration of an impurity such as hydrogen, nitrogen, or a metal element than the channel formation region, and thus are low-resistance regions with high carrier concentrations. In other words, the source region and the drain region of the transistor are n-type regions that have a higher carrier concentration and a lower resistance than the channel formation region.

Although the opening portion 290 is provided such that the side surface of the opening portion 290 is perpendicular to the top surface of the conductor 120 in FIG. 11A and the like, the present invention is not limited thereto. The side surface of the opening portion 290 may have a tapered shape, for example.

The band gap of the metal oxide used as the oxide semiconductor 270 is preferably larger than or equal to 2 eV, further preferably larger than or equal to 2.5 eV. With the use of a metal oxide having a wide band gap for the oxide semiconductor 270, the off-state current of the transistor can be reduced. When a transistor with a low off-state current is used in a memory cell, stored content can be retained for a long time. In other words, such a memory device does not require refresh operation or has extremely low frequency of the refresh operation, which leads to a sufficient reduction in power consumption of the memory device. Note that the frequency of refresh operation in a general DRAM needs to be approximately once per 60 msec, whereas the frequency of refresh operation in the memory device of one embodiment of the present invention can be approximately once per 10 sec, which is greater than or equal to 10 times or greater than or equal to 100 times that of the general DRAM. In the memory device of one embodiment of the present invention, the frequency of refresh operation can be once per period of more than or equal to 1 sec and less than or equal to 100 sec, preferably once per period of more than or equal to 5 sec and less than or equal to 50 sec.

As the oxide semiconductor 270, a single layer or stacked layers of any of metal oxides described in the section [Metal oxide] below can be used.

As the oxide semiconductor 270, a metal oxide with a composition of In:M:Zn=1:3:2 [atomic ratio] or in the neighborhood thereof, a composition of In:M:Zn=1:3:4 [atomic ratio] or in the neighborhood thereof, a composition of In:M:Zn=1:1:0.5 [atomic ratio] or in the neighborhood thereof, a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof is specifically used. Note that a composition in the neighborhood includes the range of ±30 % of an intended atomic ratio. Gallium is preferably used as the element M.

When the metal oxide is deposited by a sputtering method, the above atomic ratio is not limited to the atomic ratio of the deposited of the metal oxide and may be the atomic ratio of a sputtering target used for depositing the metal oxide.

Analysis of the composition of a metal oxide used for the oxide semiconductor 270 can be performed by, for example, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES). Alternatively, such kinds of analysis methods may be performed in combination. Note that as for an element whose content percentage is low, the actual content percentage may be different from the content percentage obtained by analysis because of the influence of the analysis accuracy. In the case where the content percentage of the element Mis low, for example, the content percentage of the element M obtained by analysis may be lower than the actual content percentage.

A sputtering method or an atomic layer deposition (ALD) method can be suitably used to form the metal oxide. In the case where the metal oxide is formed by a sputtering method, the composition of the formed metal oxide may be different from the composition of a sputtering target. In particular, the content percentage of zinc in the formed metal oxide may be reduced to approximately 50% of that of the sputtering target.

The oxide semiconductor 270 preferably has crystallinity. Examples of the oxide semiconductor having crystallinity include a CAAC-OS (c-axis aligned crystalline oxide semiconductor), an nc-OS (nanocrystalline oxide semiconductor), a polycrystalline oxide semiconductor, and a single-crystal oxide semiconductor. As the oxide semiconductor 270, the CAAC-OS or the nc-OS is preferably used, and the CAAC-OS is particularly preferably used.

The CAAC-OS preferably includes a plurality of layered crystal regions and the c-axis is preferably aligned in a normal direction of a surface where the CAAC-OS is formed. For example, the oxide semiconductor 270 preferably includes a layered crystal that is substantially parallel to the side surface of the opening portion 290, particularly the side surface of the insulator 280. With this structure, the layered crystals of the oxide semiconductor 270 are formed substantially parallel to the channel length direction of the transistor 200, so that the on-state current of the transistor can be increased.

The CAAC-OS is a metal oxide having a dense structure with high crystallinity and a small amount of impurities and defects (e.g., oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in a CAAC-OS; thus, it can be said that a reduction in electron mobility due to the crystal grain boundary is less likely to occur. Thus, a metal oxide including a CAAC-OS is physically stable. Accordingly, a metal oxide including a CAAC-OS is resistant to heat and has high reliability.

When an oxide having crystallinity, such as CAAC-OS, is used as the oxide semiconductor 270, oxygen extraction from the oxide semiconductor 270 by the source electrode or the drain electrode can be inhibited. This can inhibit oxygen extraction from the oxide semiconductor 270 even when heat treatment is performed; thus, the transistor 200 is stable with respect to high temperatures in a manufacturing process (what is called thermal budget).

The crystallinity of the oxide semiconductor 270 can be analyzed with an X-ray diffraction (XRD) pattern, a transmission electron microscope (TEM) image, or an electron diffraction (ED) pattern, for example. Alternatively, such kinds of analysis methods may be performed in combination.

Although FIG. 4A and the like show that the oxide semiconductor 270 has the single-layer structure, the present invention is not limited thereto. The oxide semiconductor 270 may have a stacked-layer structure of a plurality of oxide layers with different chemical compositions. For example, a structure in which a plurality of kinds of metal oxides selected from the above-described metal oxides are stacked as appropriate may be used.

In the case where the oxide semiconductor 270 has a three-layer structure, the oxide semiconductor 270 may have a structure in which a metal oxide with a composition of In:Ga:Zn=1:1:1 [atomic ratio] or in the neighborhood thereof, a metal oxide with a composition of In:Zn=1:1 [atomic ratio] or in the neighborhood thereof or with a composition of In:Zn=4:1 [atomic ratio] or in the neighborhood thereof, and a metal oxide with a composition of In:Ga:Zn=1:1:1 [atomic ratio] or in the neighborhood thereof are provided in order from the conductor 120 side. With this structure, the on-state current of the transistor 200 can be increased, and the transistor can have high reliability with small variations.

As the insulator 230, a single layer or stacked layers of any of insulators described in the later-described section [Insulator] can be used. For the insulator 230, silicon oxide or silicon oxynitride can be used, for example. Silicon oxide and silicon oxynitride, which are thermally stable, are preferable.

As the insulator 230, any of materials with high relative dielectric constants, that is, high-k materials, described in the later-described section [Insulator] may be used. For example, hafnium oxide, aluminum oxide, or the like may be used.

The thickness of the insulator 230 is preferably larger than or equal to 0.5 nm and smaller than or equal to 15 nm, further preferably larger than or equal to 0.5 nm and smaller than or equal to 12 nm, still further preferably larger than or equal to 0.5 nm and smaller than or equal to 10 nm. At least part of the insulator 230 has a region with the above-described thickness.

The concentration of impurities such as water and hydrogen in the insulator 230 is preferably reduced. This can inhibit entry of impurities such as water and hydrogen into the channel formation region of the oxide semiconductor 270.

As illustrated in FIG. 4A, part of the insulator 230 is positioned outside the opening portion 290, that is, over the wiring 240 and the insulator 280. In this case, the insulator 230 preferably covers the side end portion of the oxide semiconductor 270. This can prevent a short circuit between the wiring 210 and the oxide semiconductor 270. The insulator 230 preferably covers the side end portion of the wiring 240. This can prevent a short circuit between the wiring 210 and the wiring 240.

Although FIG. 4A shows that the insulator 230 has the single-layer structure, the present invention is not limited thereto. The insulator 230 may have a stacked-layer structure.

As the wiring 210, a single layer or stacked layers of any of conductors described in the later-described section [Conductor] can be used. For example, a conductive material with high conductivity such as tungsten can be used for the wiring 210.

In addition, a conductive material that is less likely to be oxidized, a conductive material having a function of inhibiting diffusion of oxygen, or the like is preferably used for the wiring 210. Examples of the conductive material include a conductive material containing nitrogen (e.g., titanium nitride or tantalum nitride) and a conductive material containing oxygen (e.g., ruthenium oxide). This can inhibit a decrease in the conductivity of the wiring 210.

Although FIG. 4A show that the wiring 210 has the single-layer structure, the present invention is not limited thereto. The wiring 210 may have a stacked-layer structure.

As the wiring 240, a single layer or stacked layers of any of conductors described in the later-described section [Conductor] can be used. For example, a conductive material with high conductivity such as tungsten can be used for the wiring 240.

A conductive material that is less likely to be oxidized, a conductive material having a function of inhibiting diffusion of oxygen, or the like is preferably used for the wiring 240 like the wiring 210. For example, titanium nitride, tantalum nitride, or the like can be used. This structure can inhibit excessive oxidation of the wiring 240 due to the oxide semiconductor 270.

A structure in which tungsten is stacked over titanium nitride may be used, for example. When tungsten is stacked in this manner, the conductivity of the wiring 240 can be improved.

In the case where the wiring 240 has a structure where a first conductor and a second conductor are stacked, the first conductor may be formed using a conductive material with high conductivity and the second conductor may be formed using a conductive material containing oxygen, for example. When a conductive material containing oxygen is used for the second conductor of the wiring 240 that is in contact with the insulator 230, oxygen in the insulator 230 can be inhibited from diffusing into the first conductor of the wiring 240. For example, tungsten may be used as the first conductor of the wiring 240, and indium tin oxide to which silicon is added may be used as the second conductor of the wiring 240.

When the oxide semiconductor 270 and the conductor 120 are in contact with each other, a metal compound is formed or oxygen vacancies are formed, so that the resistance of the region 270na in the oxide semiconductor 270 is reduced. The reduction in the resistance of the oxide semiconductor 270 in contact with the conductor 120 can reduce the contact resistance between the oxide semiconductor 270 and the conductor 120. Similarly, when the oxide semiconductor 270 and the wiring 240 are in contact with each other, the resistance of the region 270nb in the oxide semiconductor 270 is reduced. Accordingly, the contact resistance between the oxide semiconductor 270 and the wiring 240 can be reduced.

The insulator 280 functions as an interlayer film and thus preferably has a low relative dielectric constant. When a material with a low relative dielectric constant is used for an interlayer film, the electrostatic capacitance of parasitic capacitance generated between wirings can be reduced. As the insulator 280, a single layer or stacked layers of any of insulators each containing a material with low relative dielectric constant described in the later-described section [Insulator] can be used. Silicon oxide and silicon oxynitride are preferable because they are thermally stable. The concentration of impurities such as water and hydrogen in the insulator 280 is preferably reduced. This can inhibit entry of impurities such as water and hydrogen into the channel formation region of the oxide semiconductor 270.

As the insulator 280, an insulator containing oxygen that is released by heating (hereinafter, sometimes referred to as excess oxygen) is preferably used. By performing heat treatment on the insulator 280 containing excess oxygen, oxygen can be supplied from the insulator 280 to the channel formation region of the oxide semiconductor 270 and oxygen vacancies and VoH can be reduced. Thus, the transistor 200 can have stable electrical characteristics and increased reliability.

As the insulator 280, any of insulators having a function of capturing or fixing hydrogen described in the later-described section [Insulator] may be used. With this structure, hydrogen in the oxide semiconductor 270 can be captured or fixed, so that the concentration of hydrogen in the oxide semiconductor 270 can be reduced. For the insulator 280, magnesium oxide, aluminum oxide, or the like can be used for example.

As the insulator 280, any of the insulators having a barrier property against hydrogen, which are described in the section [Insulator] below, may be used. With such a structure, hydrogen that might enter the oxide semiconductor 270 can be reduced. As the insulator 280, aluminum oxide, magnesium oxide, hafnium oxide, silicon nitride, silicon nitride oxide, or the like can be used. In particular, silicon nitride is suitably used for the insulator 280.

Although FIG. 4A shows that the insulator 280 has the single-layer structure, the present invention is not limited thereto. The insulator 280 may have a stacked-layer structure.

### Component Materials of Memory Device

Component materials that can be used for the memory device are described below.

### Substrate

Examples of a substrate where the transistor 100 and the transistor 200 are formed include an insulator substrate, a semiconductor substrate, and a conductor substrate. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate containing silicon carbide, silicon germanium, gallium arsenide, indium phosphide, zinc oxide, or gallium oxide. Another example is a semiconductor substrate in which an insulator region is included in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate containing a metal nitride and a substrate containing a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor, a resistor, a switching element, a light-emitting element, and a memory element.

### Insulator

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as a leakage current may arise because of a thinner gate insulator. When a high-k material is used for the insulator functioning as a gate insulator, the voltage at the time of the operation of the transistor can be reduced while the physical thickness is maintained. In addition, the equivalent oxide thickness (EOT) of the insulator functioning as the gate insulator can be reduced. In contrast, when a material with a low relative dielectric constant is used for the insulator functioning as an interlayer film, the electrostatic capacitance of parasitic capacitance generated between wirings can be reduced. Thus, a material is preferably selected in accordance with the function of the insulator. Note that the material with a low relative dielectric constant is a material with high dielectric strength.

Examples of the material with high relative dielectric constant (high-k material) include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the material with low relative dielectric constant include inorganic insulating materials such as silicon oxide, silicon oxynitride, and silicon nitride oxide, and resins such as polyester, polyolefin, polyamide (e.g., nylon and aramid), polyimide, polycarbonate, and acrylic. Other examples of the inorganic insulating material with low relative dielectric constant include silicon oxide to which fluorine is added, silicon oxide to which carbon is added, and silicon oxide to which carbon and nitrogen are added. Another example is porous silicon oxide. These silicon oxides may contain nitrogen.

When a transistor including a metal oxide is surrounded by an insulator having a function of inhibiting passage of impurities and oxygen, the transistor can have stable electrical characteristics. As the insulator having a function of inhibiting passage of impurities and oxygen, a single layer or stacked layers of an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used, for example. Specifically, as the insulator having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

An insulator that is in contact with a semiconductor layer or provided in the vicinity of the semiconductor layer, such as a gate insulator, preferably includes a region containing excess oxygen. For example, when an insulator including a region containing excess oxygen is in contact with a semiconductor layer or provided in the vicinity of the semiconductor layer, the number of oxygen vacancies in the semiconductor layer can be reduced. Examples of an insulator in which a region containing excess oxygen is easily formed include silicon oxide, silicon oxynitride, and porous silicon oxide.

Examples of the insulator having a barrier property against oxygen include an oxide containing one or both of aluminum and hafnium, an oxide containing hafnium and silicon (hafnium silicate), magnesium oxide, gallium oxide, silicon nitride, and silicon nitride oxide. Examples of the oxide containing one or both of aluminum and hafnium include aluminum oxide, hafnium oxide, and an oxide containing aluminum and hafnium (hafnium aluminate).

Examples of the insulator having a barrier property against hydrogen include aluminum oxide, magnesium oxide, hafnium oxide, gallium oxide, silicon nitride, and silicon nitride oxide.

The insulator having a barrier property against oxygen and the insulator having a barrier property against hydrogen can each be regarded as an insulator having a barrier property against one or both of oxygen and hydrogen.

Examples of the insulator having a function of capturing or fixing hydrogen include an oxide containing magnesium and an oxide containing one or both of aluminum and hafnium. These oxides preferably have an amorphous structure. In a metal oxide having an amorphous structure, an oxygen atom has a dangling bond and has a property of capturing or fixing hydrogen with the dangling bond in some cases. Note that such a metal oxide preferably has an amorphous structure, but a crystal region may be partly formed.

Note that in this specification and the like, a barrier insulating film refers to an insulating film having a barrier property. In addition, the barrier property refers to a property that does not easily allow diffusion of a target substance (also referred to as a property that does not easily allow passage of a target substance, a property with low permeability to a target substance, or a function of inhibiting diffusion of a target substance). Note that a function of capturing or fixing (also referred to as gettering) a target substance can be rephrased as a barrier property. Note that hydrogen described as a target substance refers to at least one of a hydrogen atom, a hydrogen molecule, and a substance bonded to hydrogen, such as a water molecule or OH⁻, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, and NO₂), and a copper atom. Oxygen described as a target substance refers to, for example, at least one of an oxygen atom and an oxygen molecule. Specifically, a barrier property against oxygen refers to a property that does not easily allow diffusion of at least one of an oxygen atom, an oxygen molecule, and the like.

### Conductor

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As the alloy containing any of the above metal elements, a nitride of the alloy or an oxide of the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Alternatively, a semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. Examples of the conductive material containing oxygen include indium oxide containing tungsten oxide, indium oxide containing titanium oxide, indium tin oxide, indium tin oxide containing titanium oxide, indium tin oxide to which silicon is added, indium zinc oxide, and indium zinc oxide containing tungsten oxide. In this specification and the like, a conductive film formed using the conductive material containing oxygen may be referred to as an oxide conductive film.

In addition, a conductive material containing tungsten, copper, or aluminum as its main component is preferable because it has high conductivity.

A stack of a plurality of conductive layers formed of the above-described materials may be used. For example, a stacked-layer structure combining a material containing the above-described metal element and a conductive material containing oxygen may be employed. In addition, a stacked-layer structure combining a material containing the above-described metal element and a conductive material containing nitrogen may be employed. Furthermore, a stacked-layer structure combining a material containing the above-described metal element, a conductive material containing oxygen, and a conductive material containing nitrogen may be employed.

In the case where a metal oxide is used for the channel formation region of the transistor, the conductor functioning as the gate electrode preferably employs a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### Metal Oxide

A metal oxide sometimes has a lattice defect. Examples of the lattice defect include point defects such as an atomic vacancy and an exotic atom, a line defect such as dislocation, a plane defect such as a crystal grain boundary, and a volume defect such as a void. Examples of a factor in generating the lattice defect include deviation of the proportion of the number of atoms in constituent elements (excess or deficiency of constituent atoms) and an impurity.

When a metal oxide is used for a semiconductor layer of a transistor, a lattice defect in the metal oxide might cause generation, capture, or the like of a carrier. Thus, the use of a metal oxide with many lattice defects for a semiconductor layer of a transistor may cause unstable electrical characteristics of the transistor. Hence, a metal oxide used for a semiconductor layer of a transistor preferably has a small number of lattice defects.

In particular, the electrical characteristics of a transistor including a metal oxide easily vary when oxygen vacancies (Vo) and impurities exist in a channel formation region in the metal oxide, which might degrade the reliability. In some cases, a defect (hereinafter sometimes referred to as VoH) that is an oxygen vacancy into which hydrogen in the vicinity of the oxygen vacancy has entered is formed, which generates an electron serving as a carrier. Thus, when the channel formation region in the metal oxide includes oxygen vacancies, the transistor is likely to have normally-on characteristics. Accordingly, oxygen vacancies and impurities are preferably reduced as much as possible in the channel formation region of the metal oxide. In other words, the channel formation region in the metal oxide is preferably an i-type (intrinsic) or substantially i-type region with a reduced carrier concentration.

The kind of a lattice defect that is likely to be present in a metal oxide and the number of lattice defects that are present vary depending on the structure of the metal oxide, a method for forming a film of the metal oxide, or the like.

The structure of a metal oxide is classified into a single crystal structure and other structures (non-single-crystal structures). Examples of non-single-crystal structures include a CAAC structure, a polycrystalline structure, an nc structure, an amorphous-like (a-like) structure, and an amorphous structure. The a-like structure has a structure between the nc structure and the amorphous structure. Note that the classification of crystal structures will be described later.

A metal oxide having an a-like structure and a metal oxide having an amorphous structure each include a void or a low-density region. That is, the metal oxide having the a-like structure and the metal oxide having the amorphous structure have low crystallinity as compared with a metal oxide having the nc structure and a metal oxide having the CAAC structure. Moreover, the metal oxide having the a-like structure has a higher hydrogen concentration in the metal oxide than the metal oxide having the nc structure and the metal oxide having the CAAC structure. Thus, a lattice defect is easily formed in the metal oxide having the a-like structure and the metal oxide having the amorphous structure.

Accordingly, a metal oxide with high crystallinity is preferably used in a semiconductor layer of a transistor. For example, it is preferable to use the metal oxide having the CAAC structure or the metal oxide having the single crystal structure. The use of such a metal oxide for a transistor enables the transistor to have favorable electrical characteristics. In addition, the transistor can have high reliability.

For the channel formation region of a transistor, a metal oxide that increases the on-state current of the transistor is preferably used. To increase the on-state current of the transistor, the mobility of the metal oxide used for the transistor is preferably increased. To increase the mobility of the metal oxide, the transfer of carriers (electrons in the case of an n-channel transistor) needs to be facilitated or scattering factors that affect the carrier transfer need to be reduced. The carriers flow from the source to the drain through the channel formation region. Hence, the on-state current of the transistor can be increased by providing a channel formation region through which carriers can easily flow in the channel length direction.

Here, it is preferable to use a metal oxide with high crystallinity for a metal oxide including a channel formation region. The crystal preferably has a crystal structure in which a plurality of layers (for example, a first layer, a second layer, and a third layer) are stacked. That is, the crystal has a layered crystal structure (also referred to as a layered crystal or a layered structure). At this time, the direction of the c-axis of the crystal is the direction in which the plurality of layers are stacked. Examples of a metal oxide including the crystal include a single crystal oxide semiconductor, a CAAC-OS (c-axis-aligned crystalline oxide semiconductor), and the like.

The c-axis of the above crystal is preferably aligned in the normal direction with respect to the formation surface or film surface of the metal oxide. This enables the plurality of layers to be placed parallel or substantially parallel to the formation surface or film surface of the metal oxide. In other words, the plurality of layers extend in the channel length direction.

The above layered crystal structure including three layers is as follows, for example. The first layer has a coordination geometry of atoms that has an octahedral structure of oxygen in which a metal included in the first layer is positioned at the center. The second layer has a coordination geometry of atoms that has a trigonal bipyramidal or tetrahedral structure of oxygen in which a metal included in the second layer is positioned at the center. The third layer has a coordination geometry of atoms that has a trigonal bipyramidal or tetrahedral structure of oxygen in which a metal included in the third layer is positioned at the center.

Examples of the crystal structure of the above crystal are a YbFe₂O₄ type structure, a Yb₂Fe₃O₇ type structure, their deformed structures, and the like.

Preferably, each of the first layer to the third layer is composed of one metal element or a plurality of metal elements with the same valence and oxygen. The valence of the one or plurality of metal elements included in the first layer is preferably equal to the valence of the one or plurality of metal elements included in the second layer. The first layer and the second layer may include the same metal element. The valence of the one or plurality of metal elements included in the first layer is preferably different from the valence of the one or plurality of metal elements included in the third layer.

The above structure can increase the crystallinity of the metal oxide, which leads to an increase in the mobility of the metal oxide. Thus, the use of the metal oxide for the channel formation region of a transistor increases the on-state current of the transistor, leading to an improvement in the electrical characteristics of the transistor.

Examples of the metal oxide of one embodiment of the present invention include indium oxide, gallium oxide, and zinc oxide. The metal oxide of one embodiment of the present invention preferably contains at least indium (In) or zinc (Zn). The metal oxide preferably contains two or three selected from indium, an element M, and zinc. Note that the element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably gallium. When the element M contained in the metal oxide is gallium, the metal oxide in one embodiment of the present invention preferably contains one or more selected from indium, gallium, and zinc. In this specification and the like, a metal element and a metalloid element may be collectively referred to as a “metal element”, and a “metal element” in this specification and the like may refer to a metalloid element.

For example, as the metal oxide semiconductor of one embodiment of the present invention, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), or indium gallium aluminum zinc oxide (In—Ga—Al—Zn oxide, also referred to as IGAZO or IAGZO) can be used. Alternatively, indium tin oxide containing silicon, gallium tin oxide (Ga—Sn oxide), aluminum tin oxide (Al—Sn oxide), or the like can be given as an example.

When the proportion of the number of indium atoms in the total number of atoms of all the metal elements contained in the metal oxide is increased, the field-effect mobility of the transistor can be increased.

Note that the metal oxide may contain, instead of indium, one or more kinds of metal elements with large period numbers. Alternatively, the metal oxide may contain, in addition to indium, one or more kinds of metal elements with large period numbers. The larger the overlap between orbits of metal elements is, the more likely it is that the metal oxide will have high carrier conductivity. Thus, a transistor containing a metal element with a large period number can have high field-effect mobility in some cases. Examples of the metal element with a large period number include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, variation in electrical characteristics of the transistor can be inhibited, and the reliability of the transistor can be increased.

By increasing the proportion of the number of the element M atoms in the total number of atoms of all the metal elements contained in the metal oxide, oxygen vacancies can be inhibited from being formed in the metal oxide. Accordingly, generation of carriers due to oxygen vacancies is inhibited, which can make the off-state current of the transistor low. Furthermore, variation in electrical characteristics of the transistor can be inhibited, and the reliability of the transistor can be increased.

By increasing the proportion of the number of In atoms in the total number of atoms of all the metal elements contained in the metal oxide, a high on-state current and high frequency characteristics of the transistor can be achieved.

In the description of this embodiment, In—Ga—Zn oxide is sometimes taken as an example of the metal oxide.

For the formation of a metal oxide having the layered crystal structure, atomic layers are preferably deposited one by one. Since an ALD method is employed as the deposition method of the metal oxide in one embodiment of the present invention, a metal oxide having the layered crystal structure is easily formed.

Examples of the ALD method include a thermal ALD method, in which a precursor and a reactant react with each other only by thermal energy, and a plasma ALD (PEALD: Plasma Enhanced ALD) method, in which a reactant excited by plasma is used.

The ALD method enables atomic layers to be deposited one by one, and has advantages such as deposition of an extremely thin film, deposition on a component with a high aspect ratio, deposition of a film with a small number of defects such as pinholes, deposition with excellent coverage, and low-temperature deposition. The use of plasma in a PEALD method is sometimes preferable because it enables deposition at a lower temperature. Note that a precursor used in the ALD method sometimes contains an element such as carbon or chlorine. Thus, in some cases, a film provided by an ALD method contains a larger amount of an element such as carbon or chlorine than a film provided by another deposition method. Note that these elements can be quantified by XPS or SIMS. The deposition method of a metal oxide of one embodiment of the present invention, which employs an ALD method and one or both of a deposition condition with a high substrate temperature and impurity removal treatment, can sometimes form a film with smaller amounts of carbon and chlorine than a method employing an ALD method without the deposition condition with a high substrate temperature or the impurity removal treatment.

Unlike a deposition method in which particles ejected from a target or the like are deposited, an ALD method is a deposition method in which a film is formed by reaction at a surface of an object to be processed. Thus, an ALD method is a deposition method that enables favorable step coverage almost regardless of the shape of an object. In particular, the ALD method enables excellent step coverage and excellent thickness uniformity and thus is suitable for covering a surface of an opening portion with a high aspect ratio, for example. On the other hand, the ALD method has a relatively low deposition rate, and thus is preferably used in combination with another deposition method with a high deposition rate, such as a sputtering method or a CVD method, in some cases. For example, a method in which a sputtering method is used to deposit a first metal oxide, and an ALD method is used to deposit a second metal oxide over the first metal oxide can be given. For example, in the case where the first metal oxide has a crystal part, crystal growth occurs in the second metal oxide with the use of the crystal part as a nucleus.

In the ALD method, the composition of a film to be formed can be controlled with the amount of introduced source gases. For example, a film with a certain composition can be deposited by adjusting the amount of introduced source gases, the number of times of introduction (also referred to as the number of pulses), and the time required for one pulse (also referred to as the pulse time) in an ALD method. Moreover, for example, when the source gas is changed during the deposition in an ALD method, a film whose composition is continuously changed can be deposited. In the case where the film is deposited while the source gas is changed, as compared to the case where the film is deposited using a plurality of deposition chambers, the time taken for the deposition can be shortened because the time taken for transfer and pressure adjustment is omitted. Thus, the productivity of the memory device can be increased in some cases.

### Transistor Including Metal Oxide

Next, the case where a metal oxide (oxide semiconductor) is used for a transistor will be described. Hereinafter, a transistor including an oxide semiconductor in a semiconductor layer is sometimes referred to as an OS transistor, and a transistor including silicon in a semiconductor layer is sometimes referred to as a Si transistor.

When the metal oxide (oxide semiconductor) of one embodiment of the present invention is used for a transistor, a transistor with high field-effect mobility can be achieved. In addition, the transistor can have high reliability. Furthermore, a miniaturized or highly integrated transistor can be achieved. For example, a transistor with a channel length larger than or equal to 2 nm and smaller than or equal to 30 nm can be manufactured.

An oxide semiconductor having a low carrier concentration is preferably used for a channel formation region of a transistor. For example, the carrier concentration of an oxide semiconductor in the channel formation region is lower than or equal to 1×10¹⁸ cm⁻³, preferably lower than or equal to 1×10¹⁷ cm⁻³, further preferably lower than or equal to 1×10¹⁵ cm⁻³, still further preferably lower than or equal to 1×10¹³ cm⁻³, yet still further preferably lower than or equal to 1×10¹¹ cm⁻³, yet still further preferably lower than 1 x 1010cm- 3 , and higher than or equal to 1×10⁻⁹ cm⁻³. In order to reduce the carrier concentration in an oxide semiconductor, the impurity concentration in the oxide semiconductor is reduced so that the density of defect states is reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and sometimes behaves like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film also be reduced. Examples of impurities include hydrogen, carbon, and nitrogen. Note that an impurity in an oxide semiconductor refers to, for example, an element other than the main components of the oxide semiconductor. For example, an element with a concentration lower than 0.1 atomic % can be regarded as an impurity.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With use of an oxide semiconductor having a larger band gap than silicon, the off-state current (also referred to as Ioff) of the transistor can be reduced.

In a Si transistor, a short-channel effect (also referred to as SCE) appears as miniaturization of the transistor proceeds. For this reason, it is difficult to miniaturize the Si transistor. One factor that causes the short-channel effect is a small band gap of silicon. By contrast, an OS transistor includes an oxide semiconductor that is a semiconductor material having a large band gap, and thus can inhibit the short-channel effect. In other words, the OS transistor is a transistor in which the short-channel effect does not appear or hardly appears.

Note that the short-channel effect refers to degradation of electrical characteristics which becomes apparent along with miniaturization of a transistor (a decrease in channel length). Specific examples of the short-channel effect include a decrease in the threshold voltage, an increase in subthreshold swing value (sometimes also referred to as S value), and an increase in leakage current. Here, the S value means the amount of change in the gate voltage in the subthreshold region by which the drain current is changed by one order of magnitude at a constant drain voltage.

The characteristic length is widely used as an indicator of resistance to the short-channel effect. The characteristic length is an indicator of curving of a potential in a channel formation region. When the characteristic length is shorter, the potential rises more sharply, which means that the resistance to the short-channel effect is high.

The OS transistor is an accumulation-type transistor and the Si transistor is an inversion-type transistor. Accordingly, the OS transistor has a shorter characteristic length between a source region and a channel formation region and a shorter characteristic length between a drain region and the channel formation region than the Si transistor. Thus, the OS transistor has higher resistance to the short-channel effect than the Si transistor. That is, the OS transistor is more suitable than the Si transistor in the case where a short-channel transistor is to be manufactured.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region might decrease to larger than or equal to 0.1 eV and smaller than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source region and the drain region become n⁺-type regions.

The OS transistor with the above structure can have favorable electrical characteristics even when a memory device is miniaturized or highly integrated. For example, favorable electrical characteristics can be obtained even when the OS transistor has a channel length or a gate length smaller than or equal to 20 nm, smaller than or equal to 15 nm, smaller than or equal to 10 nm, smaller than or equal to 7 nm, or smaller than or equal to 6 nm and larger than or equal to 1 nm, larger than or equal to 3 nm, or larger than or equal to 5 nm. By contrast, it is sometimes difficult for the Si transistor to have a gate length less than or equal to 20 nm or less than or equal to 15 nm because of the appearance of the short-channel effect. Thus, the OS transistor can be suitably used as a transistor having a short channel length as compared with the Si transistor. Note that the gate length refers to the length of a gate electrode in a direction in which carriers move inside a channel formation region during an operation of the transistor.

Miniaturization of the OS transistor can improve the high frequency characteristics of the transistor. Specifically, the cutoff frequency of the transistor can be improved. When the gate length of the OS transistor is within the above range, the cutoff frequency of the transistor can be higher than or equal to 50 GHz, preferably higher than or equal to 100 GHz, further preferably higher than or equal to 150 GHz in a room temperature environment, for example.

As described above, the OS transistor has effects superior to those of the Si transistor, such as a low off-state current and capability of having a short channel length.

### Impurity in Metal Oxide

Here, the influence of each impurity in the metal oxide (oxide semiconductor) will be described.

When silicon or carbon, which is one of Group 14 elements, is contained in the oxide semiconductor, defect states are formed in the oxide semiconductor. Thus, the carbon concentration in the channel formation region of the oxide semiconductor that is obtained by SIMS is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet still further preferably lower than or equal to 3×10¹⁸ atoms/cm³, yet still further preferably lower than or equal to 1×10¹⁸ atoms/cm³. The silicon concentration in the channel formation region of the oxide semiconductor that is obtained by SIMS is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet still further preferably lower than or equal to 3×10¹⁸ atoms/cm³, yet still further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor including an oxide semiconductor that contains nitrogen as a semiconductor is likely to have normally-on characteristics. Alternatively, when the oxide semiconductor contains nitrogen, trap states are sometimes formed. This might make the electrical characteristics of the transistor unstable. Thus, the nitrogen concentration in the channel formation region of the oxide semiconductor that is obtained by SIMS is set lower than or equal to 1×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³, yet still further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor including an oxide semiconductor containing hydrogen is likely to have normally-on characteristics. For this reason, hydrogen in the channel formation region of the oxide semiconductor is preferably reduced as much as possible. Specifically, the hydrogen concentration in the channel formation region of the oxide semiconductor that is obtained by SIMS is set lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet still further preferably lower than 1×10¹⁸ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the channel formation region of the oxide semiconductor that is obtained by SIMS is set lower than or equal to 1×10¹⁸ atoms/cm³, preferably lower than or equal to 2×10¹⁶ atoms/cm³.

When an oxide semiconductor with sufficiently reduced impurities is used for the channel formation region of the transistor, the transistor can have stable electrical characteristics.

### Other Semiconductor Materials

The oxide semiconductor 270 can be rephrased as a semiconductor layer including the channel formation region of the transistor. A semiconductor material that can be used for the semiconductor layer is not limited to the above metal oxides. The semiconductor material that has a band gap (a semiconductor material that is not a zero-gap semiconductor) may be used for the semiconductor layer. For example, a single element semiconductor, a compound semiconductor, or a layered substance (also referred to as an atomic layer substance, a two-dimensional material, or the like) is preferably used as the semiconductor material.

Here, in this specification and the like, the layered substance generally refers to a group of materials having a layered crystal structure. In the layered crystal structure, layers formed by covalent bonding or ionic bonding are stacked with bonding such as the Van der Waals force, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the single-element semiconductor that can be used as the semiconductor material include silicon and germanium. As silicon that can be used for the semiconductor layer, single crystal silicon, polycrystalline silicon, microcrystalline silicon, and amorphous silicon can be given. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic structure.

Examples of the layered substance include graphene, silicene, boron carbonitride, and chalcogenide. Boron carbonitride serving as the layered material contains carbon, nitrogen, and boron atoms arranged in a hexagonal lattice structure on a plane. Chalcogenide is a compound containing chalcogen. Chalcogen is a general term for elements belonging to Group 16 and includes oxygen, sulfur, selenium, tellurium, polonium, and livermorium. Examples of chalcogenide include transition metal chalcogenide and chalcogenide of Group 13 elements.

For a semiconductor layer, transition metal chalcogenide functioning as a semiconductor is preferably used, for example. Specific examples of the transition metal chalcogenide that can be used for the semiconductor layer include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the transition metal chalcogenide for the semiconductor layer enables a memory device with a high on-state current to be provided.

The configuration, structure, method, and the like described in this embodiment can be used in combination as appropriate with the configurations, structures, methods, and the like described in the other embodiments and the like.

### Embodiment 2

In this embodiment, a structure example of the memory device of one embodiment of the present invention and a semiconductor device including the memory device will be described with reference to drawings.

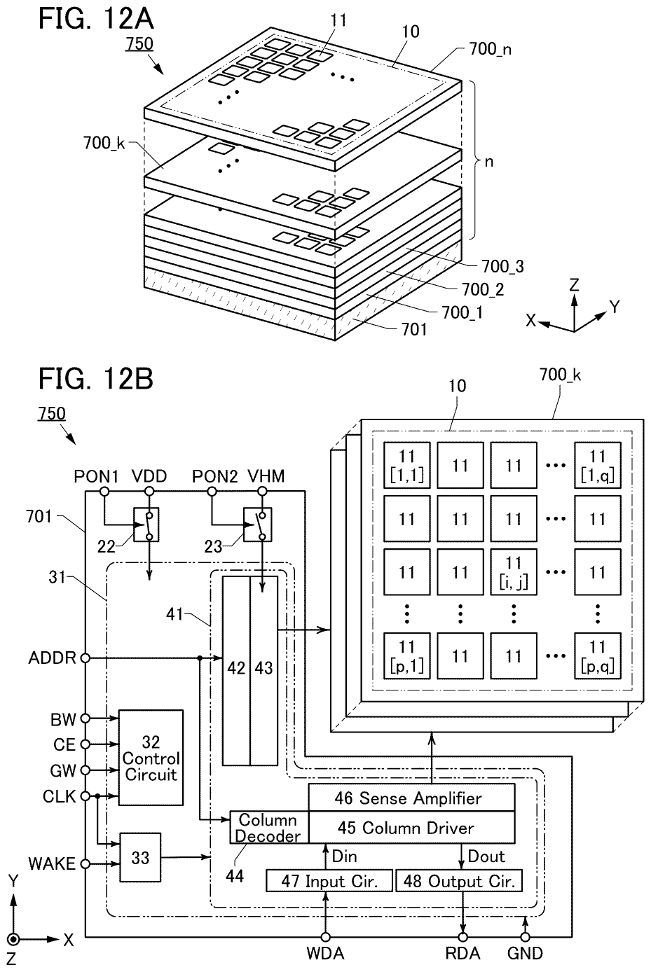

FIG. 12A is a schematic perspective view of the memory device of one embodiment of the present invention. FIG. 12B is a block diagram of the memory device of one embodiment of the present invention.

A memory device 750 illustrated in FIG. 12A and FIG. 12B includes a driver circuit layer 701 and n memory layers 700 (nis an integer greater than or equal to 1). Each of the memory layers 700 includes a memory cell array 10. The memory cell array 10 includes a plurality of memory cells 11.

As a circuit configuration structure example of the memory cells 11, the structure described in the above embodiment (the memory cell 150) can be employed.

The n memory layers 700 are provided over the driver circuit layer 701. Providing the n memory layers 700 over the driver circuit layer 701 can reduce the area occupied by the memory device 750. Furthermore, memory capacity per unit area can be increased.

In this embodiment and the like, the first memory layer 700 is referred to as a memory layer 700_1, the second memory layer 700 is referred to as a memory layer 700_2, and the third memory layer 700 is referred to as a memory layer 700_3. Furthermore, the k-th (k is an integer greater than or equal to 1 and less than or equal to n) memory layer 700 is referred to as a memory layer 700_k, and the n-th memory layer 700 is referred to as a memory layer 700_n. Note that in this embodiment and the like, the simple term “memory layer 700” is sometimes used in the case of describing matters related to all the n memory layers 700 or matters common to the n memory layers 700.

The driver circuit layer 701 includes a PSW 22 (power switch), a PSW 23, and a peripheral circuit 31. The peripheral circuit 31 includes a peripheral circuit 41, a control circuit 32 (Control Circuit), and a voltage generation circuit 33.

In the memory device 750, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside.

The signal CLK is a clock signal. The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. The signal PON1 and the signal PON2 may be generated in the control circuit 32.

The control circuit 32 is a logic circuit having a function of controlling the entire operation of the memory device 750. For example, the control circuit performs a logical operation on the signal CE, the signal GW, and the signal BW to determine an operation mode (e.g., a writing operation or a reading operation) of the memory device 750. Alternatively, the control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a negative voltage.

The peripheral circuit 41 is a circuit for writing and reading data to/from the memory cells 11. The peripheral circuit 41 includes a row decoder 42, a column decoder 44 (Column Decoder), a row driver 43, a column driver 45 (Column Driver), an input circuit 47 (Input Cir.), an output circuit 48 (Output Cir.), and a sense amplifier 46 (Sense Amplifier).

The row decoder 42 and the column decoder 44 have a function of decoding the signal ADDR. The row decoder 42 is a circuit for addressing a row to be accessed, and the column decoder 44 is a circuit for addressing a column to be accessed. The row driver 43 has a function of selecting a wiring WWL (write word line) or a wiring RWL (read word line) specified by the row decoder 42. The column driver 45 has a function of writing data to the memory cells 11, a function of reading data from the memory cells 11, a function of retaining the read data, and the like. The column driver 45 has a function of selecting a wiring WBL (write bit line) and a wiring RBL (read bit line) specified by the column decoder 44.

The input circuit 47 has a function of retaining the signal WDA. Data retained by the input circuit 47 is output to the column driver 45. Data output from the input circuit 47 is data (Din) to be written to the memory cells 11. Data (Dout) read from the memory cells 11 by the column driver 45 is output to the output circuit 48. The output circuit 48 has a function of retaining Dout. In addition, the output circuit 48 has a function of outputting Dout to the outside of the memory device 750. Data output from the output circuit 48 is the signal RDA.

The PSW 22 has a function of controlling supply of VDD to the peripheral circuit 31. The PSW 23 has a function of controlling supply of VHM to the row driver 43. Here, in the memory device 750, a high power supply voltage is VDD and a low power supply voltage is GND (a ground potential). In addition, VHM is a high power supply voltage used to set a word line at the high level and is higher than VDD. The on/off of the PSW 22 is controlled by the signal PON1, and the on/off of the PSW 23 is controlled by the signal PON2. The number of power domains to which VDD is supplied is one in the peripheral circuit 31 in FIG. 12B but can be more than one. In that case, a power switch is provided for each power domain.

A structure example of the n memory layers 700 will be described. Each of the n memory layers 700 includes the memory cell array 10. The memory cell array 10 includes the plurality of memory cells 11. FIG. 12A and FIG. 12B illustrate an example in which the memory cell array 10 includes the plurality of memory cells 11 arranged in a matrix of p rows and q columns (each of p and q is an integer greater than or equal to 2).

Note that the rows and the columns extend in directions orthogonal to each other. In this embodiment, the X direction is referred to as a “row” and the Y direction is referred to as a “column”, but the X direction may be referred to as a “column” and the Y direction may be referred to as a “row”.

In FIG. 12B, the memory cell 11 provided in the first row and the first column is referred to as a memory cell 11[1,1], and the memory cell 11 provided in the p-th row and the q-th column is referred to as a memory cell 11[p, q]. In addition, the memory cell 11 provided in the i-th row and the j-th column (i is an integer greater than or equal to 1 and less than or equal to p, and j is an integer greater than or equal to q) is indicated as a memory cell 11[i, j].

In the case where the memory layers 700 are stacked, it is preferable to arrange the wiring WBL and the wiring RBL in a direction perpendicular to the substrate surface. When the wiring WBL and the wiring RBL are provided in the direction perpendicular to the substrate surface, the signal transmission distance from the sense amplifier connected to the wiring WBL and the wiring RBL can be shortened and the resistance and parasitic capacitance of the wiring WBL and the wiring RBL can be significantly reduced. Thus, power consumption and signal delays can be reduced.

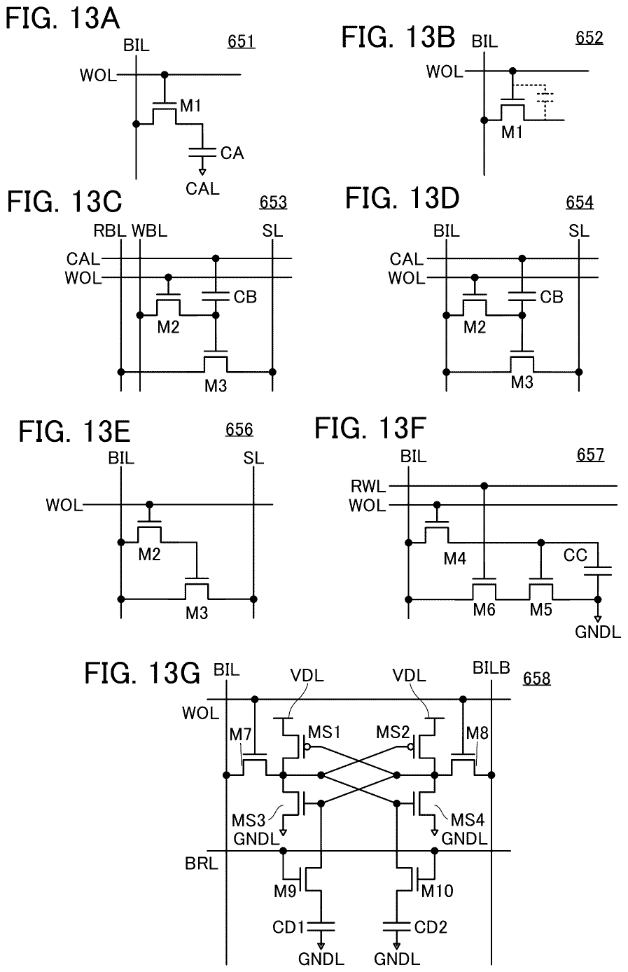

With FIG. 13A to FIG. 13G, structure examples of other memory cells applicable to the memory cell 11 are described.

### DOSRAM

FIG. 13A illustrates a circuit configuration example of a memory cell of DRAM. In this specification and the like, a DRAM using an OS transistor is referred to as a DOSRAM (Dynamic Oxide Semiconductor Random Access Memory). A memory cell 651 includes a transistor M1 and a capacitor CA.

Note that the transistor M1 may include a front gate (simply referred to as a gate in some cases) and a back gate. Here, the back gate may be connected to a wiring supplied with a constant potential or a signal, and the front gate and the back gate may be connected to each other.

A first terminal of the transistor M1 is connected to a first terminal of the capacitor CA. A second terminal of the transistor M1 is connected to a wiring BIL. A gate of the transistor M1 is connected to a wiring WOL. A second terminal of the capacitor CA is connected to a wiring CAL.

The wiring BIL functions as a bit line, and the wiring WOL functions as a word line. The wiring CAL functions as a wiring for applying a predetermined potential to the second terminal of the capacitor CA. At the time of data writing and reading, a low-level potential (also referred to as a reference potential in some cases) is preferably applied to the wiring CAL.

Data writing and data reading are performed as follows: a high-level potential is applied to the wiring WOL to turn on the transistor M1, and thus the wiring BIL is connected to the first terminal of the capacitor CA.

The memory cell that can be used as the memory cell 11 is not limited to the memory cell 651, and the circuit configuration can be changed. For example, the structure of a memory cell 652 illustrated in FIG. 13B may be employed. The memory cell 652 is an example including neither the capacitor CA nor the wiring CAL. The first terminal of the transistor M1 is in an electrically floating state.

In the memory cell 652, a potential written through the transistor MI is retained in a capacitor (also referred to as parasitic capacitance) between the first terminal and the gate, which is shown by a dashed line. Thus, the structure of the memory cell can be greatly simplified.

Note that the transistor M1 is preferably an OS transistor. An OS transistor has a characteristic of an extremely low off-state current. The use of an OS transistor as the transistor M1 enables an extremely low leakage current of the transistor M1. That is, with the use of the transistor M1, written data can be retained for a long time, and thus the frequency of refresh operation for the memory cell can be decreased. Alternatively, refresh operation for the memory cell can be omitted. In addition, owing to an extremely low leakage current, multilevel data or analog data can be retained in the memory cell 651 and the memory cell 652.

### NOSRAM

FIG. 13C illustrates a circuit configuration example of a gain memory cell including two transistors and one capacitor. A memory cell 653 includes a transistor M2, a transistor M3, and a capacitor CB. In this specification and the like, a memory device including a gain memory cell using an OS transistor as the transistor M2 is referred to as a nonvolatile oxide semiconductor RAM (NOSRAM).

A first terminal of the transistor M2 is connected to a first terminal of the capacitor CB. A second terminal of the transistor M2 is connected to a wiring WBL. A gate of the transistor M2 is connected to the wiring WOL. A second terminal of the capacitor CB is connected to the wiring CAL. A first terminal of the transistor M3 is connected to a wiring RBL. A second terminal of the transistor M3 is connected to a wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. At the time of data writing, data retention, and data reading, a low-level potential (sometimes referred to as a reference potential) is preferably applied to the wiring CAL.

Data writing is performed by applying a high-level potential to the wiring WOL to turn on the transistor M2, thereby connecting the wiring WBL to the first terminal of the capacitor CB. Specifically, when the transistor M2 is on, a potential corresponding to data to be stored is applied to the wiring WBL, and the potential is written to the first terminal of the capacitor CB and the gate of the transistor M3. Then, a low-level potential is applied to the wiring WOL to turn off the transistor M2, whereby the potential of the first terminal of the capacitor CB and the potential of the gate of the transistor M3 are retained.

Data reading is performed by applying a predetermined potential to the wiring SL. A current flowing between the source and the drain of the transistor M3 and the potential of the first terminal of the transistor M3 are determined by the potential of the gate of the transistor M3 and the potential of the second terminal of the transistor M3. Accordingly, by reading a potential of the wiring RBL connected to the first terminal of the transistor M3, a potential retained at the first terminal of the capacitor CB (or the gate of the transistor M3) can be read. That is, data written to the memory cell can be read on the basis of the potential retained at the first terminal of the capacitor CB (or the gate of the transistor M3).

As another example, one wiring BIL may be provided instead of the wiring WBL and the wiring RBL. A circuit configuration example of the memory cell is illustrated in FIG. 13D. In a memory cell 654, one wiring BIL is provided instead of the wiring WBL and the wiring RBL in the memory cell 653, and the second terminal of the transistor M2 and the first terminal of the transistor M3 are connected to the wiring BIL. In other words, one wiring BIL operates as the write bit line and the read bit line in the memory cell 654.

A memory cell 656 illustrated in FIG. 13E is an example in which the capacitor CB and the wiring CAL in the memory cell 654 are omitted. Such a structure enables high integration of memory cells.

Note that at least the transistor M2 is preferably the OS transistor. It is particularly preferable that the transistor M2 and the transistor M3 each be the OS transistor.

Since an OS transistor has a characteristic of an extremely low off-state current, the transistor M2 can retain written data for a long time. Thus, the frequency of refresh operation for the memory cell can be decreased. Alternatively, refresh operation for the memory cell can be omitted. In addition, owing to an extremely low leakage current, multilevel data or analog data can be retained in the memory cell 653, the memory cell 654, and the memory cell 656.

The memory cell 653, the memory cell 654, and the memory cell 656 each using the OS transistor as the transistor M2 are embodiments of NOSRAMs.

Note that the transistor M3 may be a Si transistor. The Si transistor can have a high field-effect mobility and can be formed as a p-channel transistor, so that circuit design flexibility can be increased.

When the OS transistor is used as the transistor M3, the memory cell can be configured with the transistors having the same conductivity type.

FIG. 13F illustrates an example of a gain memory cell 657 including three transistors and one capacitor. The memory cell 657 includes transistors M4 to M6 and a capacitor CC.

A first terminal of the transistor M4 is connected to a first terminal of the capacitor CC. A second terminal of the transistor M4 is connected to the wiring BIL. A gate of the transistor M4 is connected to the wiring WOL. A second terminal of the capacitor CC is electrically connected to a first terminal of the transistor M5 and a wiring GNDL. A second terminal of the transistor M5 is connected to a first terminal of the transistor M6. A gate of the transistor M5 is connected to the first terminal of the capacitor CC. A second terminal of the transistor M6 is connected to the wiring BIL. A gate of the transistor M6 is connected to a wiring RWL.

The wiring BIL functions as a bit line. The wiring WOL functions as a write word line. The wiring RWL functions as a read word line. The wiring GNDL is a wiring for supplying a low-level potential.

Data writing is performed by applying a high-level potential to the wiring WOL to turn on the transistor M4, thereby connecting the wiring BIL to the first terminal of the capacitor CC. Specifically, when the transistor M4 is on, a potential corresponding to data to be stored is applied to the wiring BIL, and the potential is written to the first terminal of the capacitor CC and the gate of the transistor M5. Then, a low-level potential is applied to the wiring WOL to turn off the transistor M4, whereby the potential of the first terminal of the capacitor CC and the potential of the gate of the transistor M5 are retained.

Data reading is performed by precharging the wiring BIL with a predetermined potential, and then making the wiring BIL in an electrically floating state and applying a high-level potential to the wiring RWL. Since the wiring RWL has the high-level potential, the transistor M6 is turned on, so that the wiring BIL is electrically connected to the second terminal of the transistor M5. At this time, the potential of the wiring BIL is applied to the second terminal of the transistor M5; the potential of the second terminal of the transistor M5 and the potential of the wiring BIL change depending on the potential retained at the first terminal of the capacitor CC (or the gate of the transistor M5). Here, the potential retained at the first terminal of the capacitor CC (or the gate of the transistor M5) can be read by reading the potential of the wiring BIL. That is, data written to the memory cell can be read on the basis of the potential retained at the first terminal of the capacitor CC (or the gate of the transistor M5).

Note that at least the transistor M4 is preferably the OS transistor.

Note that the transistors M5 and M6 may be Si transistors. As described above, a Si transistor may have a higher field-effect mobility than the OS transistor depending on the crystal state of silicon used in a semiconductor layer, for example.

When OS transistors are used as the transistors M5 and M6, the memory cell can be configured with the transistors having the same conductivity type.

### OS-SRAM

FIG. 13G illustrates an example of a static random access memory (SRAM) using an OS transistor. In this specification and the like, an SRAM using an OS transistor is referred to as an oxide semiconductor SRAM (OS-SRAM). A memory cell 658 illustrated in FIG. 13G is a memory cell of an SRAM capable of backup operation.

The memory cell 658 includes transistors M7 to M10, transistors MS1 to MS4, a capacitor CD1, and a capacitor CD2. The transistors MS1 and MS2 are p-channel transistors, and the transistors MS3 and MS4 are n-channel transistors.

A first terminal of the transistor M7 is connected to the wiring BIL. A second terminal of the transistor M7 is connected to a first terminal of the transistor MS1, a first terminal of the transistor MS3, a gate of the transistor MS2, a gate of the transistor MS4, and a first terminal of the transistor M10. A gate of the transistor M7 is connected to the wiring WOL. A first terminal of the transistor M8 is connected to a wiring BILB. A second terminal of the transistor M8 is connected to a first terminal of the transistor MS2, a first terminal of the transistor MS4, a gate of the transistor MS1, a gate of the transistor MS3, and a first terminal of the transistor M9. A gate of the transistor M8 is connected to the wiring WOL.

A second terminal of the transistor MS1 is electrically connected to a wiring VDL. A second terminal of the transistor MS2 is electrically connected to the wiring VDL. A second terminal of the transistor MS3 is electrically connected to the wiring GNDL. A second terminal of the transistor MS4 is electrically connected to the wiring GNDL.

A second terminal of the transistor M9 is connected to a first terminal of the capacitor CD1. A gate of the transistor M9 is connected to a wiring BRL. A second terminal of the transistor M10 is connected to a first terminal of the capacitor CD2. A gate of the transistor M10 is connected to the wiring BRL.

A second terminal of the capacitor CD1 is connected to the wiring GNDL. A second terminal of the capacitor CD2 is connected to the wiring GNDL.

The wiring BIL and the wiring BILB function as bit lines. The wiring WOL functions as a word line. The wiring BRL controls the on/off states of the transistors M9 and M10.

The wiring VDL supplies a high-level potential. The wiring GNDL supplies a low-level potential.

Data writing is performed by applying a high-level potential to the wiring WOL and the wiring BRL. Specifically, when the transistor M10 is on, a potential corresponding to data to be stored is applied to the wiring BIL, and the potential is written to the second terminal side of the transistor M10.

In the memory cell 658, the transistors MS1 and MS2 form an inverter loop; hence, an inversion signal of a data signal corresponding to the potential is input to the second terminal side of the transistor M8. Since the transistor M8 is on, an inversion signal of the potential applied to the wiring BIL (i.e., the signal input to the wiring BIL) is output to the wiring BILB. Since the transistor M9 and the transistor M10 are on, the potential of the second terminal of the transistor M7 is retained at the first terminal of the capacitor CD2, and the potential of the second terminal of the transistor M8 is retained at the first terminal of the capacitor CD1. After that, a low-level potential is applied to the wiring WOL and the wiring BRL to turn off the transistors M7 to M10, whereby the potential of the first terminal of the capacitor CD1 and the potential of the first terminal of the capacitor CD2 are retained.

Data reading is performed by precharging the wiring BIL and the wiring BILB with a predetermined potential, and then applying a high-level potential to the wiring WOL and the wiring BRL, whereby the potential of the first terminal of the capacitor CD1 is refreshed by the inverter loop in the memory cell 658 and output to the wiring BILB. Furthermore, the potential of the first terminal of the capacitor CD2 is refreshed by the inverter loop in the memory cell 658 and output to the wiring BIL. Since the potentials of the wiring BIL and the wiring BILB are changed from the precharged potentials to the potentials of the first terminal of the capacitor CD2 and the first terminal of the capacitor CD1, the potential retained in the memory cell can be read on the basis of the potentials of the wiring BIL and the wiring BILB.

Note that the transistors M7 to M10 are preferably OS transistors. In this case, the transistors M7 to M10 enable written data to be retained for a long time, and thus the frequency of refresh operation for the memory cell can be decreased. Alternatively, refresh operation for the memory cell can be omitted.

Note that the transistors MS1 to MS4 may be Si transistors.

Next, description is made on an example of an arithmetic processing device that can include the semiconductor device, such as the memory device described above.

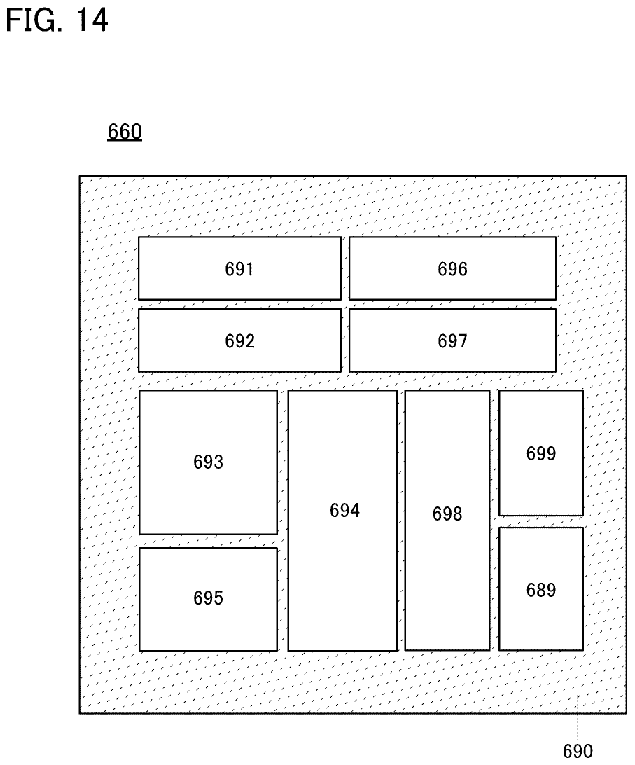

FIG. 14 is a block diagram of an arithmetic processing device 660. The arithmetic processing device 660 illustrated in FIG. 14 can be used for a central processing unit (CPU), for example. The arithmetic processing device 660 can also be used for an arithmetic processing device including a plurality of (several tens to several hundreds of) processor cores capable of parallel processing than a CPU, such as a graphics processing unit (GPU), a tensor processing unit (TPU), or a neural processing unit (NPU).

The arithmetic processing device 660 illustrated in FIG. 14 includes, over a substrate 690, an arithmetic logic unit (ALU) 691, an ALU controller 692, an instruction decoder 693, an interrupt controller 694, a timing controller 695, a register 696, a register controller 697, a bus interface 698, a cache 699, and a cache interface 689. A semiconductor substrate, an SOI substrate, a glass substrate, or the like is used as the substrate 690. The arithmetic device 660 may also include a rewritable ROM and a ROM interface. The cache 699 and the cache interface 689 may be provided in a separate chip.

The cache 699 is connected via the cache interface 689 to a main memory provided in another chip. The cache interface 689 has a function of supplying part of data retained in the main memory to the cache 699. The cache interface 689 also has a function of outputting part of data retained in the cache 699 to the ALU 691, the register 696, or the like through the bus interface 698.

As described later, the memory cell array 10 can be stacked over the arithmetic processing device 660. The memory cell array 10 can be used as a cache. At this time, the cache interface 689 may have a function of supplying data retained in the memory cell array 10 to the cache 699. In that case, part of the cache interface 689 preferably includes a driver circuit (a circuit included in the driver circuit layer 701) of the memory cell array.

Note that it is also possible that the cache 699 is not provided and only the memory cell array 10 is used as a cache.

The arithmetic processing device 660 illustrated in FIG. 14 is only an example with a simplified structure, and the actual arithmetic processing device 660 has a variety of structures depending on the application. For example, what is called a multicore structure is preferably employed in which a plurality of cores each including the arithmetic processing device 660 illustrated in FIG. 14 operate in parallel. The larger number of cores can further enhance the arithmetic performance. The number of cores is preferably larger; for example, the number is preferably 2, further preferably 4, still further preferably 8, yet further preferably 12, yet still further preferably 16 or larger. For application requiring extremely high arithmetic performance, e.g., a server, it is preferable to employ the multicore structure including 16 or more, preferably 32 or more, further preferably 64 or more cores. In addition, the number of bits that the arithmetic processing device 660 can process in an internal arithmetic circuit, a data bus, or the like can be 8 bits, 16 bits, 32 bits, 64 bits, or the like, for example.

An instruction that is input to the arithmetic processing device 660 through the bus interface 698 is input to the instruction decoder 693 and decoded therein, and then, input to the ALU controller 692, the interrupt controller 694, the register controller 697, and the timing controller 695.

The ALU controller 692, the interrupt controller 694, the register controller 697, and the timing controller 695 conduct various controls in accordance with the decoded instruction. Specifically, the ALU controller 692 generates signals for controlling the operation of the ALU 691. While the arithmetic processing device 660 is executing a program, the interrupt controller 694 judges an interrupt request from an external input/output device, a peripheral circuit, or the like on the basis of its priority, a mask state, or the like, and processes the request. The register controller 697 generates an address of the register 696, and reads/writes data from/to the register 696 in accordance with the state of the arithmetic processing device 660.

The timing controller 695 generates signals for controlling operation timings of the ALU 691, the ALU controller 692, the instruction decoder 693, the interrupt controller 694, and the register controller 697. For example, the timing controller 695 includes an internal clock generator for generating an internal clock signal on the basis of a reference clock signal, and supplies the internal clock signal to the above various circuits.

In the arithmetic processing device 660 illustrated in FIG. 14, the register controller 697 selects a retention operation in the register 696 in accordance with an instruction from the ALU 691. That is, the register controller 697 selects whether data is retained by a flip-flop or by a capacitor in the memory cell included in the register 696. In the case where data retention by the flip-flop is selected, a power supply voltage is supplied to the memory cell in the register 696. In the case where data retention by the capacitor is selected, the data is rewritten into the capacitor, and supply of a power supply voltage to the memory cell in the register 696 can be stopped.

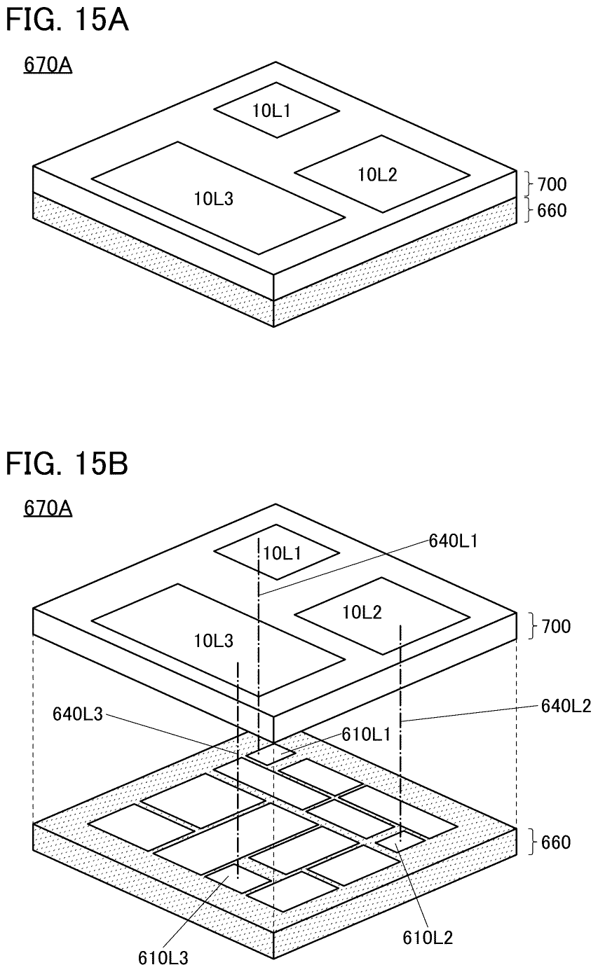

The memory cell array 10 and the arithmetic processing device 660 can be provided to overlap with each other. FIG. 15A and FIG. 15B are perspective views of a semiconductor device 670A. The semiconductor device 670A includes the memory layer 700 provided with memory cell arrays over the arithmetic processing device 660. A memory cell array 10L1, a memory cell array 10L2, and a memory cell array 10L3 are provided in the memory layer 700. The arithmetic processing device 660 and each of the memory cell arrays overlap with each other. For easy understanding of the structure of the semiconductor device 670A, the arithmetic processing device 660 and the memory layer 700 are separately illustrated in FIG. 15B.

Overlapping the arithmetic processing device 660 and the memory layer 700 including the memory cell arrays can shorten the connection distance therebetween. Accordingly, the communication speed therebetween can be increased. Moreover, since the connection distance is short, power consumption can be reduced.

As a method for stacking the memory layer 700 including the memory cell arrays and the arithmetic processing device 660, either of the following methods may be employed: a method in which the memory layer 700 including the memory cell arrays is stacked directly on the arithmetic processing device 660 (which is also referred to as monolithic stacking) and a method in which the arithmetic processing device 660 and the memory layer 700 are formed over two different substrates, the substrates are bonded to each other, and the arithmetic processing device 660 and the memory layer 700 are electrically connected to each other with a through via or by a technique for bonding conductive films (e.g., Cu—Cu bonding). The former method does not require consideration of misalignment in bonding; thus, not only the chip size but also the manufacturing cost can be reduced.

Here, it is possible that the arithmetic processing device 660 does not include the cache 699 and the memory cell arrays 10L1, 10L2, and 10L3 provided in the memory layer 700 are each used as a cache. In this case, for example, the memory cell array 10L1 can be used as an L1 cache (also referred to as a level 1 cache), the memory cell array 10L2 can be used as an an L2 cache (also referred to as a level 2 cache), and the memory cell array 10L3 can be used as an L3 cache (also referred to as a level 3 cache). Among the three memory cell arrays, the memory cell array 10L3 has the highest capacity and the lowest access frequency. The memory array 10L1 has the lowest capacity and the highest access frequency.

Note that in the case where the cache 699 provided in the arithmetic processing device 660 is used as the L1 cache, the memory cell arrays provided in the memory layer 700 can each be used as the lower-level cache or the main memory. The main memory has higher capacity and lower access frequency than the cache.

As illustrated in FIG. 15B, the arithmetic processing device 660 is provided with a driver circuit 610L1, a driver circuit 610L2, and a driver circuit 610L3. The driver circuit 610L1 is connected to the memory cell array 10L1 through a connection electrode 640L1. Similarly, the driver circuit 610L2 is connected to the memory cell array 10L2 through a connection electrode 640L2, and the driver circuit 610L3 is connected to the memory cell array 10L3 through a connection electrode 640L3.

Note that although the case where three memory cell arrays function as caches is described here, the number of memory cell arrays may be one, two, or four or more.

In the case where the memory array 10L1 is used as a cache, the driver circuit 610L1 may function as part of the cache interface 689 or the driver circuit 610L1 may be connected to the cache interface 689. Similarly, the driver circuit 610L2 and the driver circuit 610L3 may also function as part of the cache interface 689 or be connected thereto.

Whether the memory cell array 10 functions as the cache or the main memory is determined by the control circuit 32 included in each of the driver circuits 610. The control circuit 32 can make some of the plurality of memory cells 11 included in the memory device 750 function as a RAM in accordance with a signal supplied from the arithmetic processing device 660.

In the memory device 750, some of the memory cells 11 can function as the cache and other memory cells 11 can function as the main memory. That is, the memory device 750 can have both the function of the cache and the function of the main memory. The memory device 750 of one embodiment of the present invention can function as a universal memory, for example.

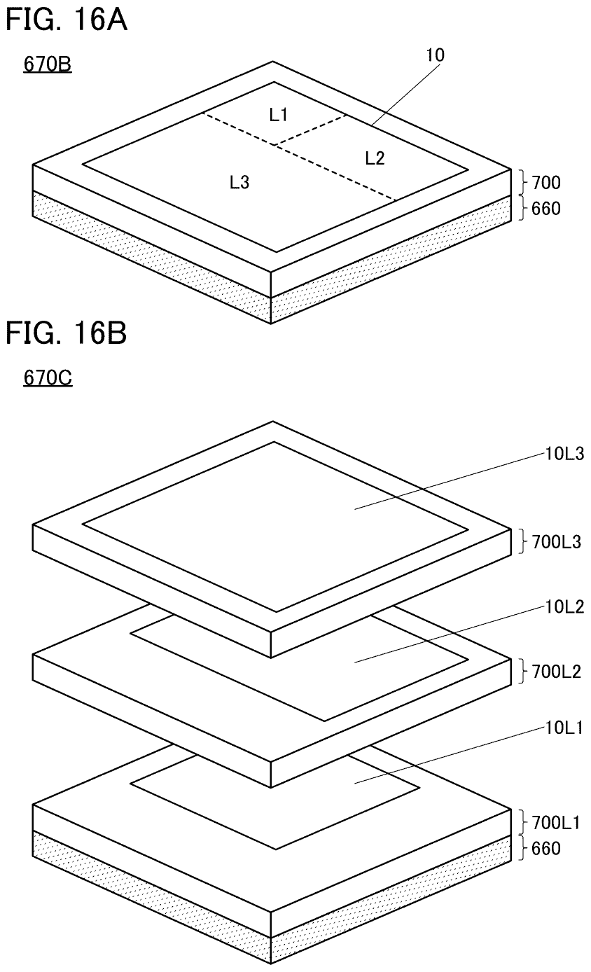

The memory layer 700 including one memory cell array 10 may be provided to overlap with the arithmetic processing device 660. FIG. 16A is a perspective view of a semiconductor device 670B.

In the semiconductor device 670B, one memory cell array 10 can be divided into a plurality of areas having different functions. FIG. 16A illustrates an example in which a region L1, a region L2, and a region L3 are used as the L1 cache, the L2 cache, and the L3 cache, respectively.

In the semiconductor device 670B, the capacity of each of the region L1 to the region L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory cell arrays may be stacked. FIG. 16B is a perspective view of a semiconductor device 670C.

In the semiconductor device 670C, a memory layer 700L1 including the memory cell array 10L1, a memory layer 700L2 including the memory cell array 10L2 over the memory layer 700L1, and a memory layer 700L3 including the memory cell array 10L3 over the memory layer 700L2 are stacked. The memory cell array 10L1 physically closest to the arithmetic processing device 660 can be used as a high-level cache, and the memory cell array 10L3 physically farthest from the arithmetic processing device 660 can be used as a low-level cache or a main memory. Such a structure can increase the capacity of each memory cell array, leading to higher processing capability.

The configuration, structure, method, and the like described in this embodiment can be used in combination as appropriate with the configurations, structures, methods, and the like described in the other embodiments, an example, and the like.

### Embodiment 3

In this embodiment, application examples of the memory device of one embodiment of the present invention will be described.

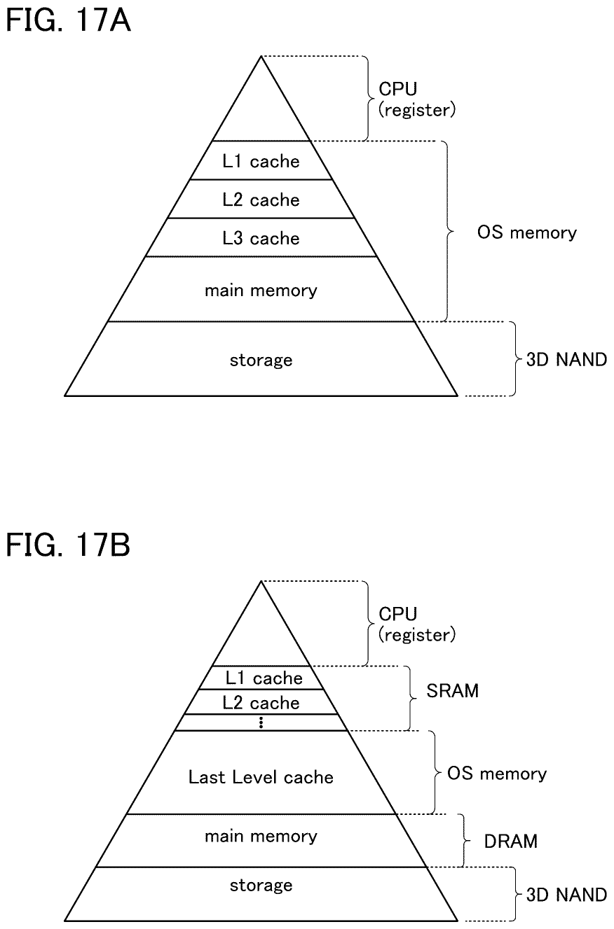

In general, a variety of memory devices are used in semiconductor devices such as computers in accordance with the intended use. FIG. 17A illustrates the hierarchy of various memory devices used in a semiconductor device. The memory devices at the upper levels require a higher operating speed, whereas the memory devices at the lower levels require a larger memory capacity and a higher memory density. FIG. 17A illustrates, for example, a memory included as a register in an arithmetic processing device such as a CPU, an L1 cache, an L2 cache, an L3 cache, a main memory, and a storage in this order from the uppermost layer. Although the caches up to the L3 cache are included in this example, a lower-level cache may be further included.

A memory included as a register in an arithmetic processing device such as a CPU is used for temporary storage of arithmetic operation results, for example, and thus is very frequently accessed by the arithmetic processing device. Accordingly, rapid operation is more important than the memory capacity. The register also has a function of retaining settings of the arithmetic processing device, for example.

The cache has a function of duplicating and retaining part of data retained in the main memory. Duplicating frequently used data and retaining the duplicated data in the cache facilitates rapid data access. The cache requires a smaller memory capacity than the main memory but a higher operating speed than the main memory. Data that is rewritten in the cache is duplicated, and the duplicated data is supplied to the main memory.

The main memory has a function of retaining a program and data that are read from the storage.

The storage has a function of retaining data that needs to be stored for a long time and programs used in an arithmetic processing device, for example. Therefore, the storage needs to have a high memory capacity and a high memory density rather than operating speed. For example, a high-capacity nonvolatile memory device such as a 3D NAND memory device can be used.

The memory device including an oxide semiconductor (the OS memory) of one embodiment of the present invention operates fast and can retain data for a long time. Thus, as illustrated in FIG. 17A, the memory device of one embodiment of the present invention can be favorably used at both the level including the cache and the level including the main memory. The memory device of one embodiment of the present invention can also be used at the level including the storage.

FIG. 17B illustrates an example in which an SRAM is used as at least one of the caches and the OS memory of one embodiment of the present invention is used as the other cache.

The lowest-level cache can be referred to as a last level cache (LLC). The LLC does not require a higher operation speed than a higher-level cache, but desirably has large storage capacity. The OS memory of one embodiment of the present invention operates at high speed and can retain data for a long time, and thus can be suitably used as the LLC. Note that the OS memory of one embodiment of the present invention can also be used as a final level cache (FLC).

For example, as illustrated in FIG. 17B, an SRAM can be used as the higher-level caches (the L1 cache, the L2 cache, and the like), and the OS memory of one embodiment of the present invention can be used as the LLC. Moreover, instead of the OS memory, a DRAM can be used as the main memory as illustrated in FIG. 17B.

The configuration, structure, method, and the like described in this embodiment can be used in combination as appropriate with the configurations, structures, methods, and the like described in the other embodiments, an example, and the like.

### Embodiment 4

In this embodiment, a semiconductor device such as an electronic computer (also referred to as a computer in some cases) of one embodiment of the present invention will be described with reference to drawings. The electronic computer includes the memory device of one embodiment of the present invention. At least part of the electronic computer of one embodiment of the present invention can be used for, for example, a microcomputer, a personal computer, a workstation, a mainframe, or a supercomputer.

### Structure Example of Electronic Computer

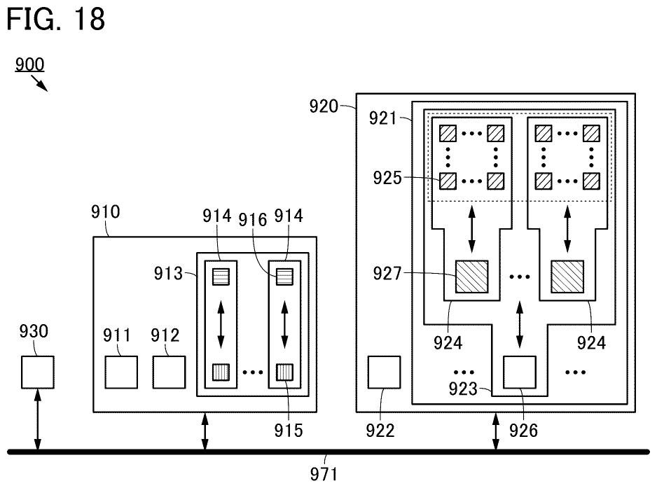

FIG. 18 is a block diagram illustrating a structure example of an electronic computer 900 of one embodiment of the present invention.

As illustrated in FIG. 18, the electronic computer 900 includes a processing unit 910 (also referred to as an arithmetic processing device), a memory unit 920 (also referred to as a memory in some cases), and a control unit 930. The processing unit 910, the memory unit 920, and the control unit 930 are electrically connected to each other through a bus line 971.

Although not illustrated, the electronic computer 900 may include an input/output unit (also referred to as an interface in some cases), for example. The input/output unit has a function of transmitting data and the like with a functional device (e.g., an input device, an output device, or a memory device) provided outside the electronic computer 900, for example.

The processing unit 910 has a function of executing a series of steps (tasks) by, for example, successively executing processing corresponding to a program. For example, the processing unit 910 has a function of executing a plurality of tasks. At least part of the processing unit 910 can be used for a CPU (Central Processing Unit), an MPU (Micro Processing Unit), a GPU (Graphics Processing Unit), or the like, for example.

The processing unit 910 includes an arithmetic unit 911 (sometimes referred to as a core), a control unit 912, and a register unit 913. The register unit 913 includes one or a plurality of register units 914.

The register unit 914 includes a scan flip-flop 915 and a backup memory 916. At least part of the register unit 914 can be used for, for example, a general-purpose register and a dedicated register (e.g., a program counter (PC), an instruction register (IR), or a status register (SR).

The arithmetic unit 911 can include, for example, an arithmetic logic unit (ALU), a floating point unit (FPU), and the like.

The control unit 912 has a function of controlling the operation of the processing unit 910. For example, the control unit 912 has a function of controlling processing while switching a plurality of tasks. For example, an instruction decoder (ID) or the like can be included.

Specific structure examples of the register unit 914 will be described later.

The memory unit 920 has a function of storing a program and data, for example. At least part of the memory unit 920 can be used for a main memory, a cache memory, or the like, for example.

The memory unit 920 includes a memory array unit 921 and a control unit 922.

The memory array unit 921 includes one or a plurality of memory blocks 923. The memory block 923 includes one or a plurality of memory units 924 and a sense amplifier 926. The memory unit 924 includes one or a plurality of memory cells 925 and a subsense amplifier 927. Note that the memory unit 924 does not necessarily include the subsense amplifier 927 depending on the structure of the memory cell 925.

Here, a group of the plurality of memory cells 925 surrounded by dotted lines in FIG. 18 is referred to as a memory cell array in some cases. As the memory cell 925, the memory cell 150 described in Embodiment 1 can be used.

The control unit 922 has a function of controlling the operation of the memory unit 920. For example, the control unit 922 has a function of controlling writing and reading of data with respect to the memory array unit 921.

The control unit 930 has a function of controlling the operation of the electronic computer 900. For example, a power management unit (PMU) or the like can be included. The PMU has a function of controlling the operation of power gating, for example. For example, the control unit 930 has a function of controlling power supply to components included in the electronic computer 900 by bringing a power switch (not illustrated) into a conduction state or a non-conduction state.

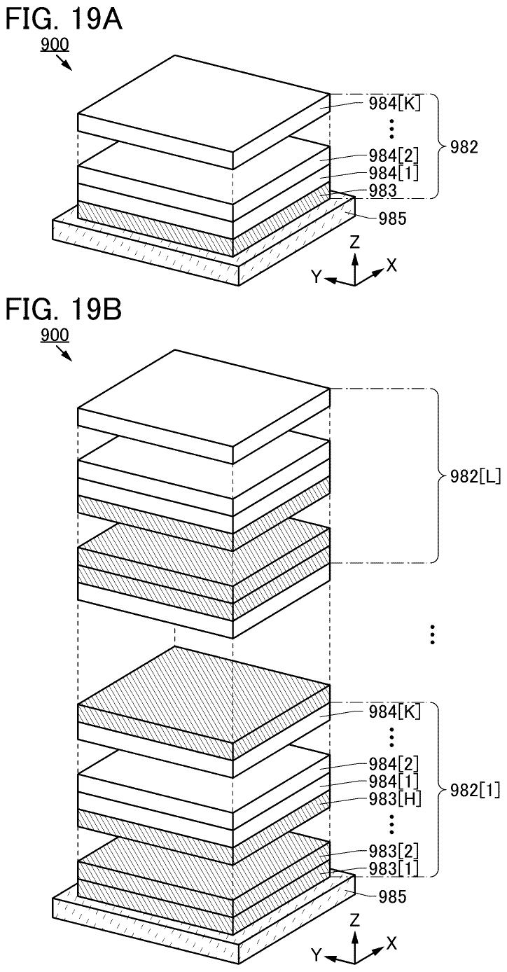

FIG. 19A and FIG. 19B are schematic views each illustrating an example of a layer structure of the electronic computer 900.

As illustrated in FIG. 19A, the electronic computer 900 includes a layer 985 and a layer 982. The layer 982 includes a layer 983 and a plurality of layers 984 (a layer 984[1] to a layer 984[K] (K is an integer greater than or equal to 2)). Note that the layer 982 may include one layer 984.

The layer 983 is stacked over the layer 985. The layer 984[1] to the layer 984[K] are stacked over the layer 983.

Note that in the following description, the X direction, the Y direction, and the Z direction are defined for easy understanding of the positional relation of components. The X direction, the Y direction, and the Z direction are perpendicular or substantially perpendicular to each other. Note that “substantially perpendicular” indicates a state where the angle formed by two targeted elements is greater than or equal to 85° and less than or equal to 95°. The Z direction refers to a direction in which the layer 983 and the layer 984[1] to the layer 984[K] are stacked over the layer 985. Thus, the X direction and the Y direction are directions along the respective surfaces of the layer 985, the layer 983, and the layer 984[1] to the layer 984[K].

The layer 985 can be provided in an insulating substrate or a semiconductor substrate containing a variety of materials.

In one embodiment of the present invention, for example, the layer 985 can be provided over a substrate containing silicon. That is, a Si transistor (a transistor including silicon in a channel formation region) can be provided in the layer 985. Thus, for example, in the layer 985 in one embodiment of the present invention, by electrically connecting a gate of an n-channel Si transistor and a gate of a p-channel Si transistor, a CMOS circuit (e.g., a circuit that operates complementarily, a CMOS logic gate, a CMOS logic circuit, or the like) can be formed.

Each of the layer 983 and the layer 984[1] to the layer 984[K] can contain any of a variety of materials such as a conductor, a semiconductor, and an insulator, for example. Each of the layer 983 and the layer 984[1] to the layer 984[K] can be provided with a variety of elements such as a capacitor and a transistor, for example.

Note that a semiconductor layer including a channel formation region of a transistor provided in the layer 983 and a semiconductor layer including a channel formation region of a transistor provided in each of the layer 984[1] to the layer 984[K] may contain the same material or different materials. The transistor provided in the layer 983 and the transistors provided in the layer 984[1] to the layer 984[K] may have the same structure or different structures.

In one embodiment of the present invention, for example, OS transistors (transistors each including an oxide semiconductor in a channel formation region) can be provided in the layer 983 and the layer 984[1] to the layer 984[K].

The OS transistor has a feature of extremely low off-state current. In addition, the OS transistor has a feature in that the off-state current hardly increases and the on-state current is unlikely to decrease even in a high-temperature environment. Thus, for example, in the case where a wiring electrically connected to one of a source and a drain of the OS transistor is in a floating state (also referred to as floating in some cases), charge accumulated in the wiring can be retained for a long period. Accordingly, in one embodiment of the present invention, for example, a memory cell formed using the OS transistor can retain data written to the memory cell for a long period.

In one embodiment of the present invention, as the OS transistor, for example, a planar transistor can be provided in the layer 983, and vertical transistors (transistors in which at least part of a semiconductor layer including a channel formation region is provided in an opening formed in an insulating layer) can be provided in the layer 984[1] to the layer 984[K].

A vertical transistor has a structure in which the occupied area (a footprint) can be easily smaller than that of a planar transistor. Furthermore, a vertical transistor has a structure in which the channel width is easily increased while the channel length is small; thus, a reduction in on-state resistance (an increase in on-state current) can be easily achieved. Thus, in one embodiment of the present invention, when a memory cell is formed using vertical transistors, for example, the cell area (cell size) of the memory cell can be reduced.

A planar transistor has a structure in which the channel length can be easily larger than that of a vertical transistor; thus, for example, a short-channel effect such as drain-induced barrier lowering (DIBL) can be easily reduced. That is, a transistor with the structure can easily have favorable saturation (the change in drain current with respect to drain voltage is small in a saturation region of the transistor). Thus, in one embodiment of the present invention, for example, a sense amplifier is formed using planar transistors, whereby the characteristics of the sense amplifier can be improved.

Note that a structure in which a vertical transistor is provided in the layer 983 may be employed, for example. A structure in which planar transistors are provided in the layer 984[1] to the layer 984[K] may be employed, for example.

Although not illustrated, the electronic computer 900 may have a structure in which a wiring layer is provided as appropriate between each of the layer 985, the layer 983, and the layer 984[1] to the layer 984[K]. In the wiring layer, for example, a wiring for electrically connecting various elements can be provided.

As illustrated in FIG. 19B, the electronic computer 900 may have a structure in which a plurality of layers 983 (a layer 983[1] to a layer 983[H] (H is an integer greater than or equal to 2)) are included and the layer 983[1] to the layer 983[H] are stacked. A structure may be employed in which the plurality of layers 982 (a layer 982[1] to a layer 982[L] (L is an integer greater than or equal to 2)) are included and the layer 982[1] to the layer 982[L] are stacked.

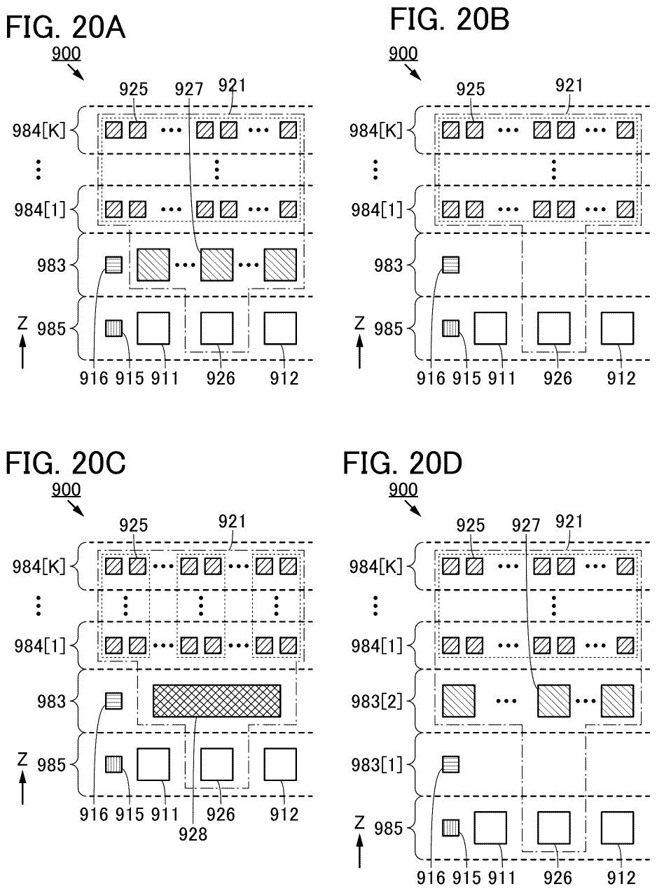

FIG. 20A to FIG. 20D are schematic diagrams each illustrating an example of arrangement of components included in the electronic computer 900. In the electronic computer 900, the components illustrated in FIG. 18 can be placed as appropriate in the layers illustrated in FIG. 19A, for example. Note that FIG. 20A to FIG. 20D each illustrate the arithmetic unit 911, the control unit 912, the scan flip-flop 915, and the backup memory 916 included in the processing unit 910, as some components included in the electronic computer 900. In addition, the memory cell 925, the sense amplifier 926, and the subsense amplifier 927 included in the memory unit 920 are illustrated.

The electronic computer 900 illustrated in FIG. 20A includes the layer 985, the layer 983, and the layer 984[1] to the layer 984[K]. As illustrated in FIG. 20A, the arithmetic unit 911, the control unit 912, the scan flip-flop 915, and the sense amplifier 926 are placed in the layer 985. Although not illustrated, the control unit 930 and the control unit 922 included in the memory unit 920 are also placed in the layer 985. Note that the sense amplifier 926 can be placed between the arithmetic unit 911 and the control unit 912, for example. The backup memory 916 is placed in the layer 983 to be over and overlap with the scan flip-flop 915. The subsense amplifier 927 is placed in the layer 983 to be over and overlap with the sense amplifier 926. Note that the subsense amplifier 927 can be placed to be over and overlap with the arithmetic unit 911 and the control unit 912, for example. The memory cells 925 are arranged in the layer 984[1] to the layer 984[K] to be over and overlap with the subsense amplifier 927. Note that the memory cells 925 can be placed to be, for example, over and overlap with the arithmetic unit 911 and the control unit 912. For another example, the memory cell 925 can be placed to be over and overlap with the backup memory 916.

That is, the electronic computer 900 illustrated in FIG. 20A has a structure in which the memory array unit 921 included in the memory unit 920 is placed in the processing unit 910. Note that the control unit 922 may also be placed in the processing unit 910.

Such arrangement can reduce the dead space of the layer 983 and the layer 984[1] to the layer 984[K] and improve the area efficiency, for example. Thus, the memory array unit 921 can have a higher surface density (a higher memory density). Accordingly, the memory capacity of the memory unit 920 included in the electronic computer 900 can be improved and the size of the electronic computer 900 can be reduced. For example, the bus line 971 between the processing unit 910 and the memory unit 920 can be shortened. Thus, the access time (time needed for data writing and data reading) and the access energy (energy consumed by data writing and data reading) can be reduced. Therefore, the operation speed of the electronic computer 900 can be improved and power consumption thereof can be reduced.

The electronic computer 900 illustrated in FIG. 20B is a modification example of the electronic computer 900 illustrated in FIG. 20A and differs from the electronic computer 900 in FIG. 20A in not including the subsense amplifier 927. As described above, the electronic computer 900 does not necessarily include the subsense amplifier 927 depending on the structure of the memory cell 925.

The electronic computer 900 illustrated in FIG. 20C is a modification example of the electronic computer 900 illustrated in FIG. 20B and differs from the electronic computer 900 in FIG. 20B in including a functional circuit 928. The functional circuit 928 is placed in the layer 983 to be over and overlap with the sense amplifier 926. Note that the functional circuit 928 can be placed to be over and overlap with the arithmetic unit 911 and the control unit 912, for example.

For example, when the memory array unit 921 illustrated in FIG. 20C is divided into a plurality of memory cell arrays as shown in the area surrounded by dotted lines, the functional circuit 928 can have a function of selecting one of the plurality of memory cell arrays. Thus, the sense amplifier 926 can write and read data to/from the memory cells 925 included in the selected memory cell array. Accordingly, for example, when the sense amplifier 926 and the control unit 922 are used in common for a plurality of memory cell arrays, the layout area of the layer 985 can be reduced. Therefore, the electronic computer 900 can be downsized.

The electronic computer 900 illustrated in FIG. 20D is a modification example of the electronic computer 900 illustrated in FIG. 20A and differs from the electronic computer 900 in FIG. 20A in including the layer 983[1] and a layer 983[2] instead of the layer 983. The backup memory 916 is placed in the layer 983[1] to be over and overlap with the scan flip-flop 915. The subsense amplifier 927 is placed in the layer 983[2] to be over and overlap with the sense amplifier 926. Note that the subsense amplifier 927 can be placed to be over and overlap with the arithmetic unit 911, the control unit 912, and the backup memory 916, for example.

In the electronic computer 900 illustrated in FIG. 20D, the parasitic capacitance between the subsense amplifier 927 and each of the arithmetic unit 911 and the control unit 912 can be reduced, for example. Thus, for example, one of the operations can be less likely to cause noise and affect the other operation. Consequently, the reliability of the electronic computer 900 can be improved.

A semiconductor device that can be used for the register unit 914 is described below.

Note that in the following description on the potential corresponding to binary data, a potential corresponding to “1” of binary data is a high power supply potential VDD, and a potential corresponding to “0” of binary data is a low power supply potential VSS. The potential VDD is a potential higher than the potential VSS by at least the threshold voltage of the transistor. Note that the potential VSS may be a ground potential, for example. The potential of the signal is the potential H or the potential L. The potential H is a potential which, when being supplied to a gate of an n-channel transistor, makes the transistor in the conduction state and, when being supplied to a gate of a p-channel transistor, makes the transistor in the non-conduction state. The potential L is a potential which, when being supplied to a gate of an n-channel transistor, makes the transistor in the non-conduction state and, when being supplied to a gate of a p-channel transistor, makes the transistor in the conduction state. The potential H can be, for example, a potential equal to or higher than the potential VDD. The potential L can be, for example, a potential equal to or lower than the potential VSS.

Note that the potentials H are not necessarily the same among a plurality of signals and the potentials L are not necessarily the same among a plurality of signals. The potentials H may be different and the potentials L may be different among the plurality of signals in accordance with a threshold voltage of a transistor supplied with the signal. For example, the potential H may be different in value and the potential L may be different in value between a signal supplied to a gate of a Si transistor provided in the layer 985 and a signal supplied to a gate of an OS transistor provided in each of the layer 983 and the layer 984[1] to the layer 984[K].

### Semiconductor Device Capable of Being Used for Processing Unit 910

A semiconductor device 810 of one embodiment of the present invention is described. At least part of the semiconductor device 810 can be used for, for example, the electronic computer 900 illustrated in FIG. 18 or the like. For example, the semiconductor device 810 can be used for the register unit 914 included in the processing unit 910.

### Structure Example

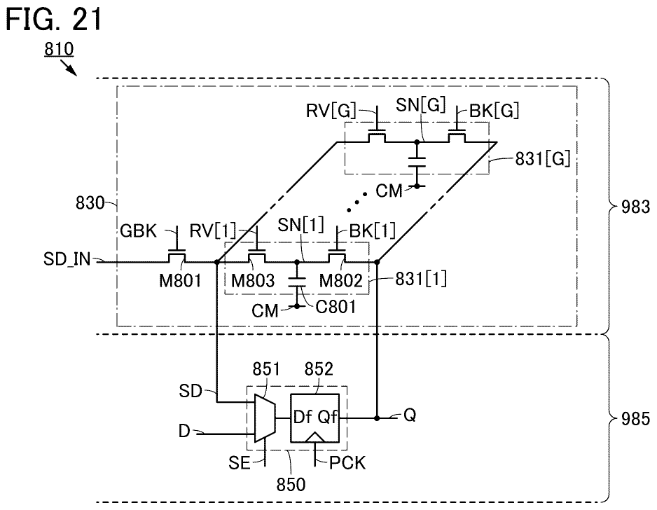

FIG. 21 is a circuit diagram illustrating a structure example of the semiconductor device 810.

The semiconductor device 810 illustrated in FIG. 21 includes a scan flip-flop circuit 850 and a backup circuit 830.

In one embodiment of the present invention, in the case where the semiconductor device 810 is used in the register unit 914 included in the electronic computer 900, for example, the scan flip-flop circuit 850 corresponds to the scan flip-flop 915 and the backup circuit 830 corresponds to the backup memory 916. That is, for example, the scan flip-flop circuit 850 is placed in the layer 985, and the backup circuit 830 is placed in the layer 983. Thus, a Si transistor can be used for the scan flip-flop circuit 850, and an OS transistor can be used for the backup circuit 830, for example.

The scan flip-flop circuit 850 includes a selector circuit 851 and a flip-flop circuit 852. The backup circuit 830 includes a retention circuit 831[1] to a retention circuit 831[G] (G is an integer greater than or equal to 2) and a transistor M801. Each of the retention circuit 831[1] to the retention circuit 831[G] includes a transistor M802, a transistor M803, and a capacitor C801.

A variety of signals for controlling the operation of the semiconductor device 810 are supplied to a wiring BK[1] to a wiring BK[G], a wiring RV[1] to a wiring RV[G], a wiring SE, a wiring PCK, and a wiring GBK.

The semiconductor device 810 can store and retain data input from the wiring D or data input from the wiring SD in the flip-flop circuit 852 in the scan flip-flop circuit 850 in synchronization with a clock signal supplied to the wiring PCK and output the data to the wiring Q. The data retained in the flip-flop circuit 852 is retained after being written to any one of the retention circuit 831[1] to the retention circuit 831[G] in the backup circuit 830 through the wiring Q by a signal supplied to the wiring BK[1] to the wiring BK[G]. Such an operation is referred to as saving, storing, backup, or the like in some cases. The data retained in any one of the retention circuit 831[1] to the retention circuit 831[G] is retained after being written back to the flip-flop circuit 852 through the wiring SD by a signal supplied to the wiring RV[1] to the wiring RV[G]. Such an operation is referred to as loading, restoration, recovery, or the like in some cases.

The flip-flop circuit 852 has a function of storing and retaining data supplied to an input terminal Df in synchronization with a clock signal supplied to the wiring PCK and outputting the data from the output terminal Qf. As the flip-flop circuit 852, a flip-flop circuit prepared in a standard circuit library can be employed. For example, a positive edge-triggered D flip-flop can be used.

The selector circuit 851 has a function of transmitting data supplied to the wiring D or the wiring SD to the flip-flop circuit 852 by a signal supplied to the wiring SE. Data input from the outside of the semiconductor device 810 is supplied to the wiring D. Data retained in any one of the retention circuit 831[1] to the retention circuit 831[G] in the backup circuit 830 or data input from the wiring SD_IN is supplied to the wiring SD. Data for a scan test is supplied to the terminal SD_IN.

The backup circuit 830 can retain the state of the scan flip-flop circuit 850 in any one of the retention circuit 831[1] to the retention circuit 831[G] when performing power gating. The backup circuit 830 can retain the state of the scan flip-flop circuit 850 for each task in a one-to-one correspondence with each of the retention circuit 831[1] to the retention circuit 831[G] when processing a plurality of tasks by switching them.

When the backup circuit 830 saves data, any one of the retention circuit 831[1] to the retention circuit 831[G] is selected by a signal supplied to the wiring BK[1] to the wiring BK[G]. When the backup circuit 830 performs loading of data, any one of the retention circuit 831[1] to the retention circuit 831[G] is selected by a signal supplied to the wiring RV[1] to the wiring RV[G]. The wiring BK[1] to the wiring BK[G] and the wiring RV[1] to the wiring RV[G] are supplied with the respective signals corresponding one-to-one to the retention circuit 831[1] to the retention circuit 831[G].

Note that contents common to the retention circuit 831[1] to the retention circuit 831[G] are described as the retention circuit 831 in some cases. In that case, each of the wiring BK[1] to the wiring BK[G] is described as the wiring BK, and each of the wiring RV[1] to the wiring RV[G] is described as the wiring RV in some cases.

As illustrated in FIG. 21, the retention circuit 831 is electrically connected to each of the wiring Q and the wiring SD. In the retention circuit 831, a terminal (wiring) electrically connected to the wiring Q serves as an input terminal and a terminal (wiring) electrically connected to the wiring SD serves as an output terminal. That is, in the semiconductor device 810, the output terminal Qf of the flip-flop circuit 852 is electrically connected to the input terminal of the retention circuit 831, and the input terminal Df of the flip-flop circuit 852 is electrically connected to the output terminal of the retention circuit 831 through the selector circuit 851.

In the retention circuit 831, one of a source and a drain of the transistor M802 is electrically connected to the one terminal of the capacitor C801. One of the source and the drain of the transistor M803 is electrically connected to the one terminal of the capacitor C801. The other terminal of the capacitor C801 is electrically connected to a wiring CM. The other of the source and the drain of the transistor M802 is electrically connected to the input terminal (i.e., the wiring Q) of the retention circuit 831. The other of the source and the drain of the transistor M803 is electrically connected to the output terminal (i.e., the wiring SD) of the retention circuit 831. A gate of the transistor M802 is electrically connected to the wiring BK. A gate of the transistor M803 is electrically connected to the wiring RV.

Note that in the retention circuit 831[1] to the retention circuit 831[G], wirings that are electrically connected to the one of the source and the drain of the transistor M802, the one of the source and the drain of the transistor M803, and the one terminal of the capacitor C801 are sometimes described as a wiring SN[1] to a wiring SN[G], respectively. In the case where a matter common to each of the retention circuit 831[1] to the retention circuit 831[G] is described, each of the wiring SN[1] to the wiring SN[G] is sometimes referred to as the wiring SN.

In the backup circuit 830, one of a source and a drain of the transistor M801 is electrically connected to the wiring SD. The other of the source and the drain of the transistor M801 is electrically connected to the wiring SD_IN.

A gate of the transistor M801 is electrically connected to the wiring GBK. A signal for controlling whether a scan test is performed is supplied to the wiring GBK.

In one embodiment of the present invention, OS transistors can be used as the transistor M801, the transistor M802, and the transistor M803, for example. The OS transistor has a feature of extremely low off-state current. In addition, the OS transistor has a feature in that the off-state current hardly increases and the on-state current is unlikely to decrease even in a high-temperature environment.

Accordingly, the retention circuit 831 can retain data written to the wiring SN for a long time by bringing the transistor M802 and the transistor M803 into a non-conduction state. For example, data can be continuously retained due to power gating operation even in a state where power is not supplied to the scan flip-flop circuit 850. That is, the retention circuit 831 can be used as a nonvolatile memory.

Here, in the semiconductor device 810, when data retained in the wiring SN is written back to the flip-flop circuit 852, the potential of the data sometimes might change due to the parasitic capacitance of the wiring SD. Thus, the electrostatic capacitance of the capacitor C801 is preferably higher than the parasitic capacitance of the wiring SD so that the amount of change in potential of the data is smaller than the logic threshold value of the flip-flop circuit 852 or the like, for example.

Note that as another structure example of the semiconductor device 810, a structure in which the transistor M801 is provided per some retention circuits 831 may be employed. For example, a Si transistor may be used as the transistor M801.

In order to increase the number of retention circuits 831 in the semiconductor device 810 without increasing the area overhead, a structure in which the plurality of layers 983 are stacked and the backup circuit 830 is provided in each of the layers 983 may be employed.

In one embodiment of the present invention, the backup circuit 830 can be provided in the semiconductor device 810 without changing the circuit configuration and layout of the scan flip-flop circuit 850. That is, the backup circuit 830 is a circuit that has very broad utility.

In the semiconductor device 810, the backup circuit 830 is provided to be stacked over the scan flip-flop circuit 850; thus, the distance of a wiring for electrically connecting the circuits can be shortened. For this reason, energy (access energy) necessary for data saving and data loading can be reduced. Thus, power consumption of the semiconductor device 810 can be reduced.

### Operation Example 1

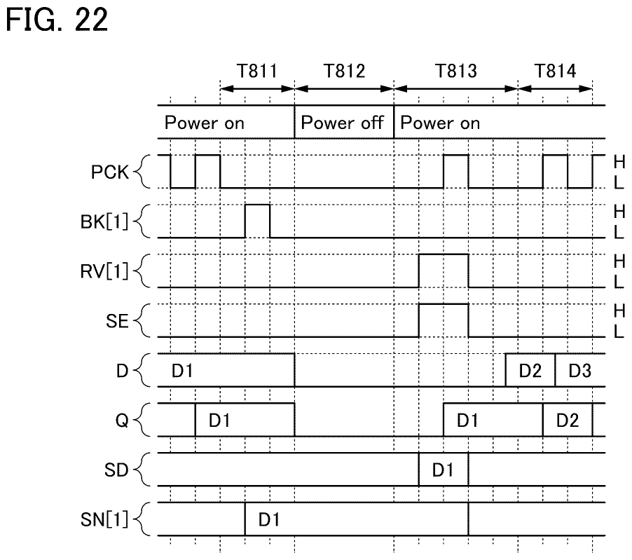

FIG. 22 is a timing chart showing an operation example of the semiconductor device 810 illustrated in FIG. 21.

In this operation example 1, an operation example of the semiconductor device 810 in the case where power gating operation is performed in the above-described electronic computer 900 is described, for example.

Here, as an example for describing the operation of the semiconductor device 810, the case in which the number of the retention circuits 831 included in the backup circuit 830 is four (G=4) is described.

In the following description of the operation, the flip-flop circuit 852 stores data supplied to the input terminal Df in synchronization with the timing (a rising edge) at which the clock signal supplied to the wiring PCK switches from the potential L to the potential H, and outputs the data from the output terminal Qf. In addition, the potential L is supplied to the wiring GBK. A constant potential (e.g., the potential VSS) is supplied to the wiring CM.

The timing chart in FIG. 22 shows the states (the potential H or the potential L) of signals supplied to the wiring PCK, the wiring BK[1], the wiring RV[1], and the wiring SE in each operation period (Period T811 to Period T814). Note that a wiring BK[2] to a wiring BK[4] and a wiring RV[2] to a wiring RV[4] are not illustrated. In addition, the states (any one of data DI to data D3) of data supplied to the wiring D, the wiring Q, the wiring SD, and the wiring SN[1] are illustrated. Note that a wiring SN[2] to a wiring SN[4] are not illustrated. In addition, a state (Power on) where power is supplied to the scan flip-flop circuit 850 or a state (Power off) where power is not supplied is illustrated.

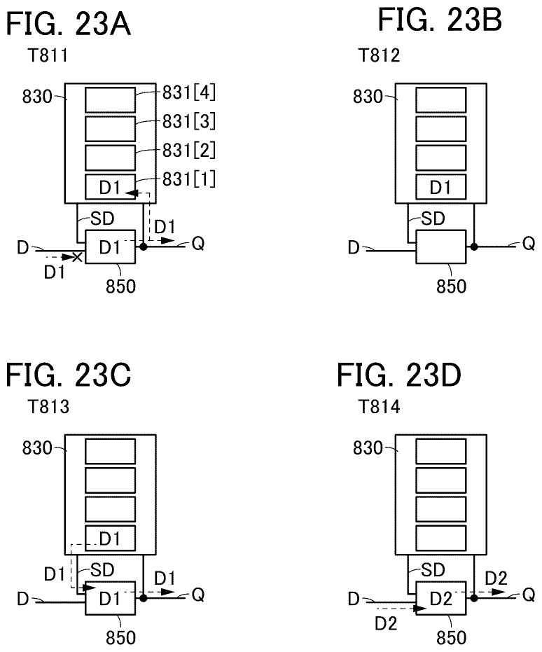

FIG. 23A to FIG. 23D are schematic diagrams illustrating the states where data is stored in the scan flip-flop circuit 850 and the retention circuit 831[1] to a retention circuit 831[4] included in the backup circuit 830 in the periods shown in the timing chart of FIG. 22. In the schematic diagrams, states where data is input and output (data flow) are indicated by dashed arrows.

Immediately before Period T811, the potential L is supplied to each of the wiring BK[1] to the wiring BK[4], the wiring RV[1] to the wiring RV[4], and the wiring SE. Furthermore, the states of the data supplied to the wiring SN[1] and the wiring SN[2] are undetermined (the data D1 to the data D3 are not illustrated). A clock signal is supplied to the wiring PCK. Power is supplied to the scan flip-flop circuit 850. The data DI is stored in the scan flip-flop circuit 850. Note that in the following description, in the case where the signals are not particularly specified, the state immediately before is maintained.

In Period T811, first, the clock signal supplied to the wiring PCK is stopped.

Next, the potential H is supplied to the wiring BK[1], whereby the data D1 output to the wiring Q is stored in the wiring SN[1] of the retention circuit 831[1]. After that, the potential L is supplied to the wiring BK[1], whereby the data D1 stored in the wiring SN[1] is retained.

In Period T812, power supply to the scan flip-flop circuit 850 is stopped. Then, the data D1 stored in the scan flip-flop circuit 850 is lost. At this time, the data D1 retained in the wiring SN[1] of the retention circuit 831[1] is retained.

In Period T813, first, power supply to the scan flip-flop circuit 850 is restarted.

Next, the potential H is supplied to the wiring RV[1] so that the data DI stored in the wiring SN[1] of the retention circuit 831[1] is supplied to the wiring SD, and the potential H is supplied to the wiring SE, whereby the wiring SD is selected.

Next, a pulse signal is supplied to the wiring PCK, whereby the data D1 supplied to the wiring SD is stored in the scan flip-flop circuit 850 and output to the wiring Q in synchronization with the rising edge. After that, the potential L is supplied to the wiring RV[1] and the wiring SE.

In Period T814, the clock signal supplied to the wiring PCK is restarted. Furthermore, the data D2 is supplied to the wiring D. Then, the data D2 supplied to the wiring D is stored in the scan flip-flop circuit 850 and output to the wiring Q in synchronization with the rising edge of the clock signal.

In the above manner, the semiconductor device 810 can be operated as in the timing chart shown in FIG. 22. Thus, in the case where power gating operation is performed in the electronic computer 900, for example, the scan flip-flop circuit 850 can be quickly returned to the state immediately before being turned off when the scan flip-flop circuit 850 is turned on, so that the time taken for the processing to restart can be shortened.

### Operation Example 2

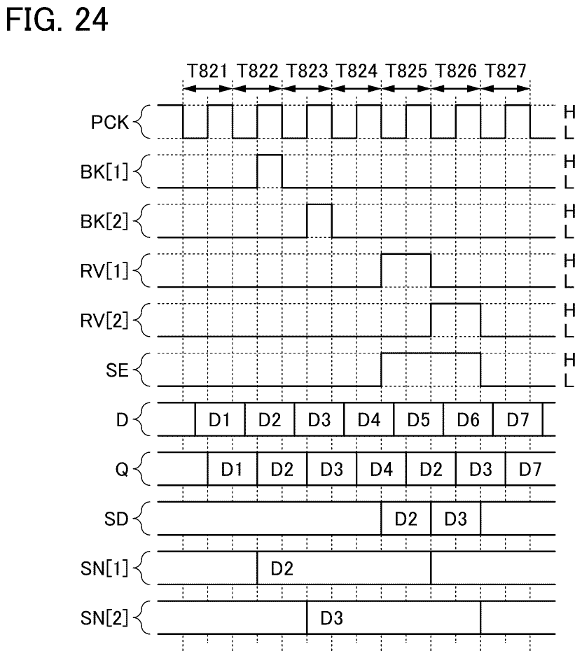

FIG. 24 is a timing chart showing an operation example of the semiconductor device 810 illustrated in FIG. 21.

In this operation example 2, an operation example of the semiconductor device 810 in the case where processing is performed while a plurality of tasks are switched in the above-described electronic computer 900 is described, for example.

Here, as an example for describing the operation of the semiconductor device 810, the case in which the number of the retention circuits 831 included in the backup circuit 830 is four (G=4) is described.

In the following description of the operation, the flip-flop circuit 852 stores data supplied to the input terminal Df in synchronization with the timing (a rising edge) at which the clock signal supplied to the wiring PCK switches from the potential L to the potential H, and outputs the data from the output terminal Qf. In addition, the potential L is supplied to the wiring GBK. A constant potential (e.g., the potential VSS) is supplied to the wiring CM.

The timing chart in FIG. 24 shows the states (the potential H or the potential L) of signals supplied to the wiring PCK, the wiring BK[1], the wiring BK[2], the wiring RV[1], the wiring RV[2], and the wiring SE in each operation period (Period T821 to Period T827). Note that a wiring BK[3], the wiring BK[4], a wiring RV[3], and the wiring RV[4] are not illustrated. In addition, the states (any one of data D1 to data D7) of data supplied to the wiring D, the wiring Q, the wiring SD, the wiring SN[1], and the wiring SN[2] are illustrated. Note that a wiring SN[3] and a wiring SN[4] are not illustrated.

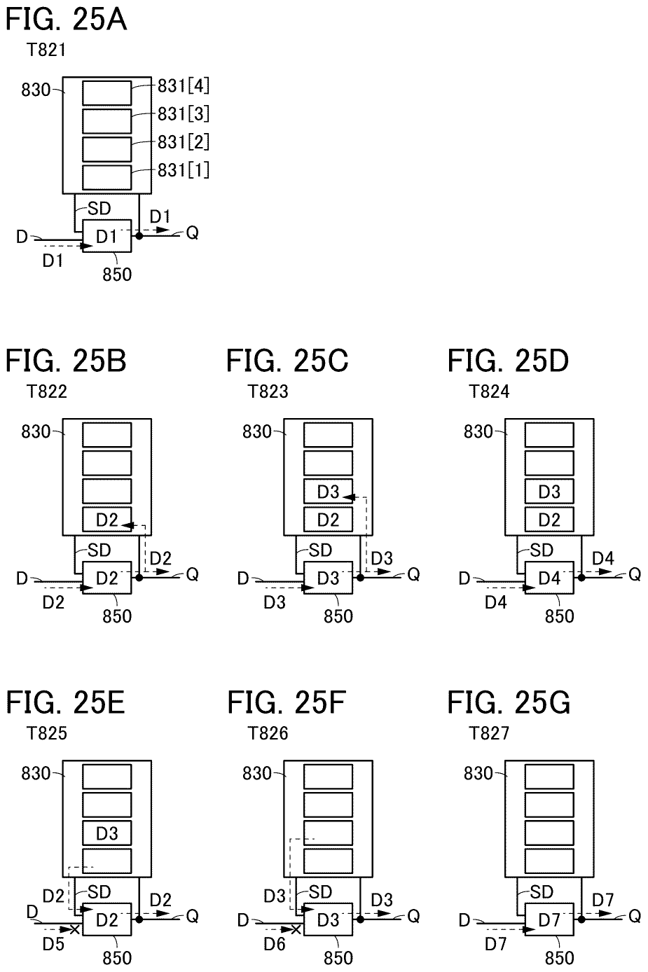

FIG. 25A to FIG. 25G are schematic diagrams illustrating the states where data is stored in the scan flip-flop circuit 850 and the retention circuit 831[1] to the retention circuit 831[4] included in the backup circuit 830 in the periods shown in the timing chart of FIG. 24. In the schematic diagrams, states where data is input and output (data flow) are indicated by dashed arrows.

Immediately before Period T821, the potential L is supplied to each of the wiring BK[1] to the wiring BK[4], the wiring RV[1] to the wiring RV[4], and the wiring SE. Furthermore, the states of the data supplied to the wiring SN[1] and the wiring SN[2] are undetermined (the data D1 to the data D7 are not illustrated). Note that in the following description, in the case where the signals are not particularly specified, the state immediately before is maintained.

In Period T821, the data DI supplied to the wiring D is stored in the scan flip-flop circuit 850 and output to the wiring Q in synchronization with the rising edge of the signal supplied to the wiring PCK.

In Period T822, the data D2 supplied to the wiring D is stored in the scan flip-flop circuit 850 and output to the wiring Q in synchronization with the rising edge of the signal supplied to the wiring PCK.

At this time, the potential H is supplied to the wiring BK[1], whereby the data D2 output to the wiring Q is stored in the wiring SN[1] of the retention circuit 831[1]. After that, the potential L is supplied to the wiring BK[1], whereby the data D2 stored in the wiring SN[1] is retained.

In Period T823, the data D3 supplied to the wiring D is stored in the scan flip-flop circuit 850 and output to the wiring Q in synchronization with the rising edge of the signal supplied to the wiring PCK.

At this time, the potential H is supplied to the wiring BK[2], whereby the data D3 output to the wiring Q is stored in the wiring SN[2] of a retention circuit 831[2]. After that, the potential L is supplied to the wiring BK[2], whereby the data D3 stored in the wiring SN[2] is retained.

In Period T824, the data D4 supplied to the wiring D is stored in the scan flip-flop circuit 850 and output to the wiring Q in synchronization with the rising edge of the signal supplied to the wiring PCK.

In Period T825, first, the potential H is supplied to the wiring RV[1], whereby the data D2 stored in the wiring SN[1] of the retention circuit 831[1] is supplied to the wiring SD. Although the data D5 is supplied to the wiring D, the wiring SD is selected when the potential H is supplied to the wiring SE.

Next, the data D2 supplied to the wiring SD is stored in the scan flip-flop circuit 850 and output to the wiring Q in synchronization with the rising edge of the wiring PCK. After that, the potential L is supplied to the wiring RV[1].

In Period T826, first, the potential H is supplied to the wiring RV[2], whereby the data D3 stored in the wiring SN[2] of the retention circuit 831[2] is supplied to the wiring SD. Although the data D6 is supplied to the wiring D, the wiring SD is selected when the potential H is supplied to the wiring SE.

Next, the data D3 supplied to the wiring SD is stored in the scan flip-flop circuit 850 and output to the wiring Q in synchronization with the rising edge of the wiring PCK. After that, the potential L is supplied to the wiring RV[2] and the potential L is supplied to the wiring SE.

In Period T827, the data D7 supplied to the wiring D is stored in the scan flip-flop circuit 850 and output to the wiring Q in synchronization with the rising edge of the signal supplied to the wiring PCK.

In the above manner, the semiconductor device 810 can be operated as in the timing chart shown in FIG. 24. Thus, in the case where processing is performed while a plurality of tasks are switched in the electronic computer 900, for example, data of a suspended task can be saved and data of a restarting task can be loaded.

Such power gating operation can reduce the power consumption of the electronic computer 900.

In the semiconductor device of one embodiment of the present invention, the OS transistor is a three-terminal semiconductor element having a gate, a source, and a drain in the above description; however, the OS transistor may be a four-terminal semiconductor element having a back gate. In the case where the OS transistor includes a back gate, on-state resistance can be reduced (on-state current can be increased), for example, by supplying the same potential as the gate to the back gate. When the same potential as the source is supplied to the back gate, for example, an electric field generated outside the transistor is unlikely to affect the channel formation region, and consequently the electrical characteristics of the transistor can be stabilized and the reliability thereof can be increased. Furthermore, for example, a given potential is supplied to the back gate, the threshold voltage of the transistor can be changed. For example, a current flowing between a source and a drain can be controlled independently in accordance with a potential supplied to each of the gate and the back gate.

In the description of the operation example of the semiconductor device described above, loads on a wiring (parasitic capacitance and parasitic resistance), for example, sometimes generate a rise time and a fall time at the time of potential change. Such a time is, for example, longer than 0 second and is shorter than 1000 nanoseconds, shorter than 100 nanoseconds, shorter than 10 nanoseconds, or shorter than 1 nanosecond. Furthermore, for example, two different operations that appear to occur at the same timing do not necessarily occur at exactly the same timing. The operations can be sometimes considered to occur at the same timing even though a signal delay of a wiring or the like causes a slight time lag between the operations, for example. The time lag is, for example, longer than 0 second and is shorter than 1000 nanoseconds, shorter than 100 nanoseconds, shorter than 10 nanoseconds, or shorter than 1 nanosecond.

The plurality of wirings are not necessarily supplied with the same potential H or the same potential L. The potentials supplied to the wirings may be different from each other in consideration of the threshold voltage of the transistor supplied with the potential, for example. Note that the potential H or the potential L supplied to each wiring may include a potential decrease due to the threshold voltage of the transistor, for example.

The lengths of the periods in the timing chart may be different from each other even when the lengths of the periods appear the same. That is, in the case where the semiconductor device is actually operated, the length of each period is set as appropriate.

The electronic computer, the semiconductor device, and the memory device of one embodiment of the present invention are not limited to the above description. At least part of the structure examples, the operation examples, the drawings corresponding thereto, and the like described in this embodiment as an example can be combined with the other structure examples, the other operation examples, the other drawings, and the other embodiments described in this specification and the like as appropriate.

### Embodiment 5

In this embodiment, electronic components, electronic devices, a large computer, space equipment, and a data center (also referred to as DC) in which the memory device described in the above embodiments can be used will be described. Electronic components, electronic devices, a large computer, space equipment, and a data center in which the memory device of one embodiment of the present invention is used are effective in improving performance, e.g., reducing power consumption.

### Electronic Component

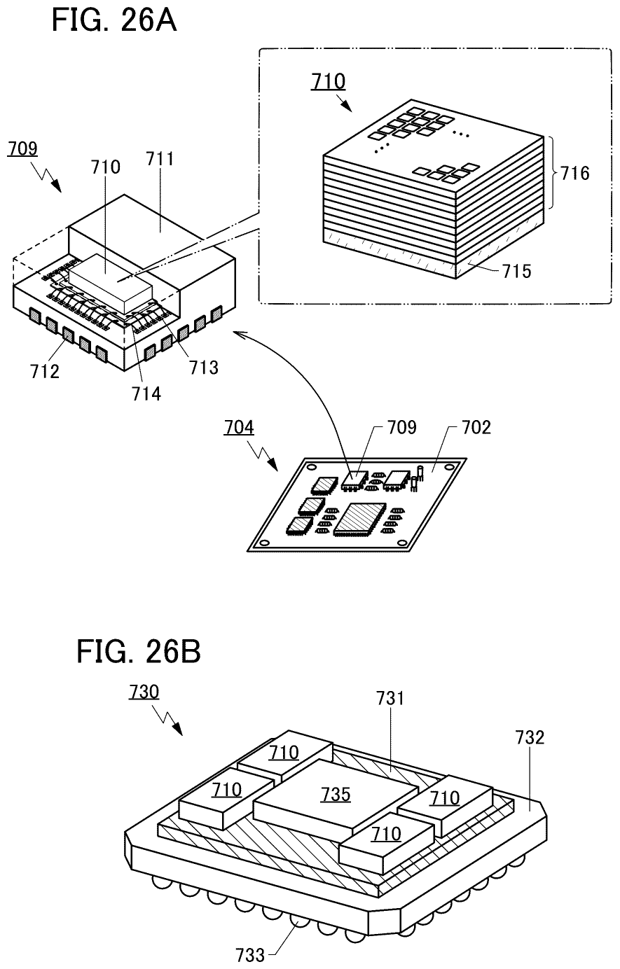

FIG. 26A is a perspective view of a substrate (a mounting board 704) mounted with an electronic component 709. The electronic component 709 illustrated in FIG. 26A includes a memory device 710 in a mold 711. FIG. 26A omits illustrations of some parts to show the inside of the electronic component 709. The electronic component 709 includes a land 712 outside the mold 711. The land 712 is electrically connected to an electrode pad 713, and the electrode pad 713 is electrically connected to the memory device 710 through a wire 714. The electronic component 709 is mounted on a printed circuit board 702, for example. A plurality of such electronic components are combined and electrically connected to each other on the printed circuit board 702, which forms the mounting board 704.

The memory device 710 includes a driver circuit layer 715 and a memory layer 716. Note that the memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected without using a through electrode technique such as a TSV (Through Silicon Via) and a bonding technique such as Cu-Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

In addition, with the on-chip memory structure, the size of a connection wiring and the like can be made smaller than that when the technique using through electrodes such as TSVs is employed; thus, the number of connection pins can be increased. The increase in the number of connection pins enables parallel operation, which can improve the bandwidth of the memory (also referred to as memory bandwidth).

It is preferable that the plurality of memory cell arrays included in the memory layer 716 be formed using OS transistors and be monolithically stacked. The monolithic stacked-layer structure of the plurality of memory cell arrays can improve the bandwidth of the memory and/or the access latency of the memory. Note that the bandwidth refers to the data transfer amount per unit time, and the access latency refers to time between data access and start of data transmission. In the case where the memory layer 716 is formed using Si transistors, it is difficult to obtain the monolithic stacked-layer structure as compared with the case where the memory layer 716 is formed using OS transistors. Thus, the OS transistors are superior to the Si transistors in the monolithic stacked-layer structure.

The memory device 710 may be called a die. Note that in this specification and the like, a die refers to a chip piece obtained by, for example, forming a circuit pattern on a disc-like substrate (also referred to as a wafer) or the like and cutting the substrate into dies in a process of manufacturing a semiconductor chip. Note that examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

Next, FIG. 26B is a perspective view of an electronic component 730. The electronic component 730 is an example of a SiP (System in Package) or an MCM (Multi Chip Module). In the electronic component 730, an interposer 731 is provided on a package substrate 732 (a printed circuit board), and a semiconductor device 735 and a plurality of memory devices 710 are provided on the interposer 731.

The electronic component 730 using the memory devices 710 as a high bandwidth memory (HBM) is shown as an example. As the memory device 735, an integrated circuit such as a CPU (Central Processing Unit), a GPU (Graphics Processing Unit), or an FPGA (Field Programmable Gate Array) can be used.

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. Moreover, in a silicon interposer, a TSV can also be used as the through electrode.

In an HBM, many wirings need to be connected to achieve wide memory bandwidth. Thus, an interposer on which an HBM is mounted requires minute and densely formed wirings. For this reason, a silicon interposer is preferably used as the interposer on which an HBM is mounted.

In addition, in a SiP, an MCM, and the like each using a silicon interposer, a decrease in reliability due to a difference in an expansion coefficient between an integrated circuit and the interposer does not easily occur. Furthermore, a surface of a silicon interposer has high planarity, and a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected using a silicon interposer, a TSV, and the like, a space for the width of the terminal pitch and the like is needed. Accordingly, in the case where the size of the electronic component 730 is to be reduced, the width of the terminal pitch becomes an issue, which sometimes makes it difficult to provide a large number of wirings for achieving a wide memory bandwidth. For this reason, the monolithic stacked-layer structure using the OS transistors is suitable, as described above. A composite structure where memory cell arrays stacked using a TSV and monolithically stacked memory cell arrays are combined may be employed.

A heat sink (radiator plate) may be provided to overlap with the electronic component 730. In the case of providing a heat sink, the levels of integrated circuits provided on the interposer 731 are preferably equal to each other. In the electronic component 730 of this embodiment, the levels of the memory device 710 and the semiconductor device 735 are preferably equal to each other, for example.

An electrode 733 may be provided on the bottom portion of the package substrate 732 to mount the electronic component 730 on another substrate. FIG. 26B illustrates an example in which the electrode 733 is formed of a solder ball. Solder balls are provided in a matrix on the bottom portion of the package substrate 732, whereby BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by various mounting methods not limited to BGA and PGA. Examples of mounting methods include SPGA (Staggered Pin Grid Array), LGA (Land Grid Array), QFP (Quad Flat Package), QFJ (Quad Flat J-leaded package), and QFN (Quad Flat Non-leaded package).

### Electronic Device

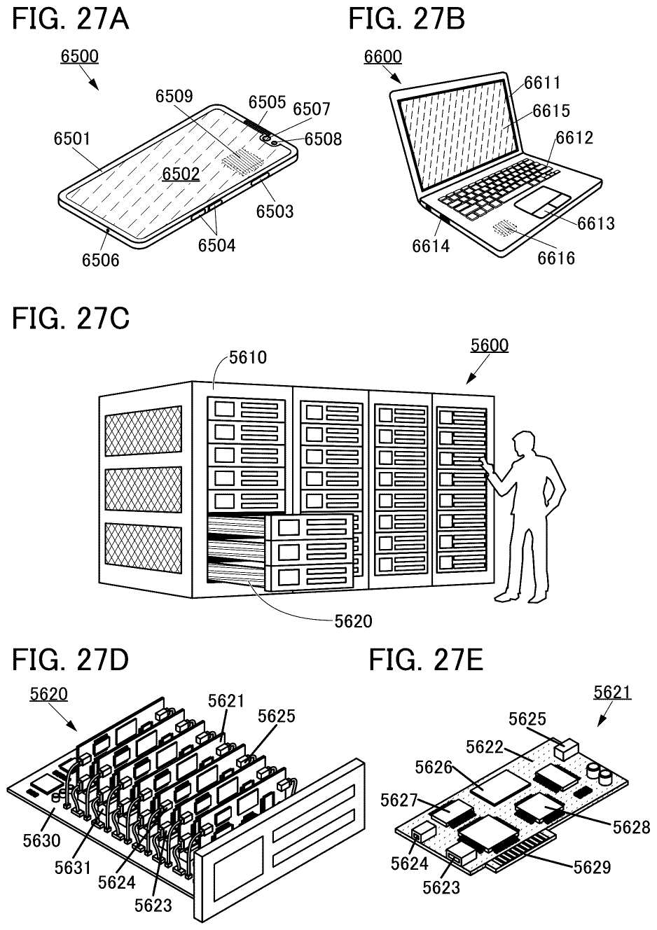

Next, a perspective view of an electronic device 6500 is illustrated in FIG. 27A. The electronic device 6500 illustrated in FIG. 27A is a portable information terminal that can be used for a smartphone. The electronic device 6500 includes a housing 6501, a display portion 6502, a power button 6503, buttons 6504, a speaker 6505, a microphone 6506, a camera 6507, a light source 6508, a control device 6509, and the like. Note that the control device 6509 includes one or more selected from a CPU, a GPU, and a memory device, for example. The memory device of one embodiment of the present invention can be employed for the display portion 6502, the control device 6509, or the like.

An electronic device 6600 illustrated in FIG. 27B is an information terminal that can be used as a laptop personal computer. The electronic device 6600 includes a housing 6611, a keyboard 6612, a pointing device 6613, an external connection port 6614, a display portion 6615, a control device 6616, and the like. Note that the control device 6616 includes one or more selected from a CPU, a GPU, and a memory device, for example. The memory device of one embodiment of the present invention can be employed for the display portion 6615, the control device 6616, or the like. Note that the memory device of one embodiment of the present invention is preferably used for the control device 6509 and the control device 6616, in which case power consumption can be reduced.

### Large Computer

Next, FIG. 27C is a perspective view of a large computer 5600. In the large computer 5600 illustrated in FIG. 27C, a plurality of rack mount computers 5620 are stored in a rack 5610. Note that the large computer 5600 may also be referred to as a supercomputer.

The computer 5620 can have a structure in the perspective view illustrated in FIG. 27D, for example. In FIG. 27D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 27E is an example of a processing board provided with a CPU, a GPU, a memory device, and the like. The PC card 5621 includes a board 5622. In addition, the board 5622 includes the connection terminal 5623, the connection terminal 5624, the connection terminal 5625, a semiconductor device 5626, a semiconductor device 5627, a semiconductor device 5628, and a connection terminal 5629. Note that FIG. 27E illustrates semiconductor devices other than the semiconductor device 5626, the semiconductor device 5627, and the semiconductor device 5628; the following description of the semiconductor device 5626, the semiconductor device 5627, and the semiconductor device 5628 is referred to for these semiconductor devices.

The connection terminal 5629 has a shape that can be inserted in the slot 5631 of the motherboard 5630, and the connection terminal 5629 functions as an interface for connecting the PC card 5621 and the motherboard 5630. An example of the standard for the connection terminal 5629 is PCIe or the like.

The connection terminal 5623, the connection terminal 5624, and the connection terminal 5625 can each serve as, for example, an interface for performing power supply, signal input, or the like to the PC card 5621. As another example, the connection terminal 5623, the connection terminal 5624, and the connection terminal 5625 can each serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In addition, in the case where video signals are output from the connection terminal 5623, the connection terminal 5624, and the connection terminal 5625, an example of the standard for each of the connection terminal 5623, the connection terminal 5624, and the connection terminal 5625 is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected.

The semiconductor device 5627 includes a plurality of terminals, and when the terminals are reflow-soldered, for example, to wirings of the board 5622, the semiconductor device 5627 and the board 5622 can be electrically connected. Examples of the semiconductor device 5627 include an FPGA, a GPU, and a CPU. The electronic component 730 can be used for the semiconductor device 5627, for example.

The semiconductor device 5628 includes a plurality of terminals, and when the terminals are reflow-soldered, for example, to wirings of the board 5622, the semiconductor device 5628 and the board 5622 can be electrically connected. An example of the semiconductor device 5628 is a memory device. The electronic component 709 can be used for the semiconductor device 5628, for example.

The large computer 5600 can also function as a parallel computer. When the large computer 5600 is used as a parallel computer, large-scale computation necessary for artificial intelligence learning and inference can be performed, for example.

### Space Equipment

The memory device of one embodiment of the present invention can be suitably used as space equipment such as equipment that processes and stores information.

The memory device of one embodiment of the present invention can include an OS transistor. Variation in electrical characteristics of the OS transistor due to exposure to radiation is small. That is, the OS transistor is highly resistant to radiation, and thus can be suitably used in an environment where radiation can enter. For example, the OS transistor can be suitably used in outer space.

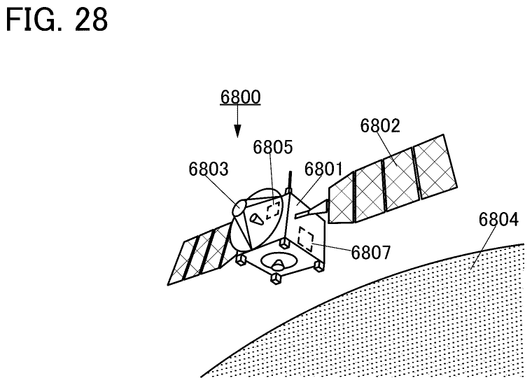

FIG. 28 illustrates an artificial satellite 6800 as an example of space equipment. The artificial satellite 6800 includes a body 6801, a solar panel 6802, an antenna 6803, a secondary battery 6805, and a control device 6807. In FIG. 28, a planet 6804 in outer space is illustrated. Note that outer space refers to, for example, space at an altitude greater than or equal to 100 km, and outer space described in this specification may include thermosphere, mesosphere, and stratosphere.

Although not illustrated in FIG. 28, a battery management system (also referred to as BMS) or a battery control circuit may be provided in the secondary battery 6805. The battery management system or the battery control circuit preferably includes an OS transistor, in which case low power consumption and high reliability are achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the memory device of one embodiment of the present invention is suitably used for the control device 6807. Variation in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited thereto. The memory device of one embodiment of the present invention can be suitably used for space equipment, such as a spacecraft, a space capsule, or a space probe, for example.

As described above, the OS transistor has excellent effects of achieving a wide memory bandwidth and being highly resistant to radiation as compared with the Si transistor.

### Data Center

The memory device of one embodiment of the present invention can be suitably used for a storage system in a data center, for example. Long-term data management, such as a guarantee for data immutability, is required for the data center. The long-term management of data needs an increase in building size owing to installation of storages and servers for storing an enormous amount of data, stable electric power for data retention, cooling equipment necessary for data retention, and the like.

With use of the memory device of one embodiment of the present invention for the storage system used in the data center, electric power required for data retention can be reduced and the size of a memory device retaining data can be downsized. Accordingly, downsizing of the storage system, downsizing of a power source for data retention, downscaling of cooling equipment, and the like can be achieved. This can reduce the space of the data center.

Since the memory device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the memory device of one embodiment of the present invention enables a data center that operates stably even in a high-temperature environment. Thus, the reliability of the data center can be increased.

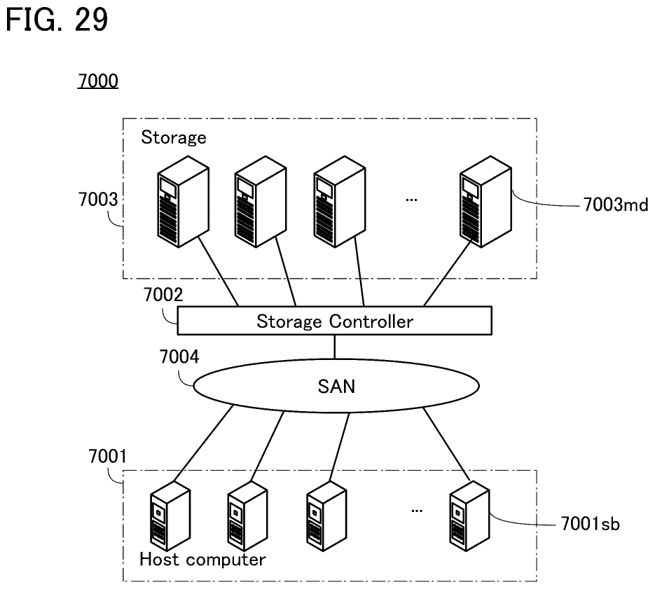

FIG. 29 illustrates a storage system that can be used in a data center. A storage system 7000 illustrated in FIG. 29 includes a plurality of servers 7001sb as a host 7001 (indicated as “Host Computer” in the diagram). In addition, the storage system 7000 includes a plurality of memory devices 7003md as a storage 7003 (indicated as “Storage” in the diagram). In the illustrated example, the host 7001 and the storage 7003 are connected through a storage area network 7004 (indicated as “SAN” in the diagram) and a storage control circuit 7002 (indicated as “Storage Controller” in the diagram).

The host 7001 corresponds to a computer that accesses data stored in the storage 7003. The hosts 7001 may be connected to each other through a network.

The data access speed, i.e., the time taken for storing and outputting data, of the storage 7003 is shortened by using a flash memory, but is considerably longer than the data access speed of a DRAM that can be used as a cache memory in a storage. In the storage system, in order to solve the problem of low access speed of the storage 7003, a cache memory is usually provided in a storage to shorten the time taken for storing and outputting data.

The cache memories are used in the storage control circuit 7002 and the storage 7003. Data transmitted between the host 7001 and the storage 7003 are stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing is possible by stacking memory cell arrays.

The use of the memory device of one embodiment of the present invention for one or more selected from an electronic component, an electronic device, a large computer, space equipment, and a data center will produce an effect of reducing power consumption. Although demand for energy will increase with increasing performance and integration degree of memory devices, the use of the memory device of one embodiment of the present invention can thus reduce the emission amount of greenhouse gas typified by carbon dioxide (CO₂). The memory device of one embodiment of the present invention can be effectively used as one of the global warming countermeasures because of its low power consumption.

The configuration, structure, method, and the like described in this embodiment can be used in combination as appropriate with the configurations, structures, methods, and the like described in the other embodiments and the like.

### REFERENCE NUMERALS

10: memory cell array, 11: memory cell, 22: PSW, 23: PSW, 31: peripheral circuit, 32: control circuit, 33: voltage generation circuit, 41: peripheral circuit, 42: row decoder, 43: row driver, 44: column decoder, 45: column driver, 46: sense amplifier, 47: input circuit, 48: output circuit, 100: transistor, 110: wiring, 120: conductor, 130: insulator, 140: wiring, 150: memory cell, 160: insulator, 170: oxide semiconductor, 180: insulator, 190: opening portion, 200: transistor, 210: wiring, 230: insulator, 240: wiring, 270i: region, 270na: region, 270nb: region, 270: oxide semiconductor, 280 r: etching residue, 280: insulator, 285: insulator, 290: opening portion, 610: driver circuit, 651: memory cell, 652: memory cell, 653: memory cell, 654: memory cell, 656: memory cell, 657: memory cell, 658: memory cell, 660: arithmetic processing device, 670A: semiconductor device, 670B: semiconductor device, 670C: semiconductor device, 689: cache interface, 690: substrate, 691: ALU, 692: ALU controller, 693: instruction decoder, 694: interrupt controller, 695: timing controller, 696: register, 697: register controller, 698: bus interface, 699: cache, 700_1: memory layer, 700_2: memory layer, 700_3: memory layer, 700_k: memory layer, 700_n: memory layer, 700: memory layer, 701: driver circuit layer, 702: printed circuit board, 704: mounting board, 709: electronic component, 710: memory device, 711: mold, 712: land, 713: electrode pad, 714: wire, 715: driver circuit layer, 716: memory layer, 730: electronic component, 731: interposer, 732: package substrate, 733: electrode, 735: semiconductor device, 750: memory device, 810: semiconductor device, 830: backup circuit, 831[1]: retention circuit, 831[2]: retention circuit, 831[4]: retention circuit, 831[G]: retention circuit, 831: retention circuit, 850: scan flip-flop circuit, 851: selector circuit, 852: flip-flop circuit, 900: electronic computer, 910: processing unit, 911: arithmetic unit, 912: control unit, 913: register unit, 914: register unit, 915: scan flip flop, 916: backup memory, 920: memory unit, 921: memory array unit, 922: control unit, 923: memory block, 924: memory unit, 925: memory cell, 926: sense amplifier, 927: subsense amplifier, 928: functional circuit, 930: control unit, 971: bus line, 982[1]: layer, 982[L]: layer, 982: layer, 983[1]: layer, 983[2]: layer, 983[H]: layer, 983: layer, 984[1]: layer, 984[K]: layer, 985: layer, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6500: electronic device, 6501: housing, 6502: display portion, 6503: power supply button, 6504: button, 6505: speaker, 6506: microphone, 6507: camera, 6508: light source, 6509: control device, 6600: electronic device, 6611: housing, 6612: keyboard, 6613: pointing device, 6614: external connection port, 6615: display portion, 6616: control device, 6800: artificial satellite, 6801: body, 6802: solar panel, 6803: antenna, 6804: planet, 6805: secondary battery, 6807: control device, 7000: storage system, 7001sb: server, 7001: host, 7002: storage control circuit, 7003md: memory device, 7003: storage

1. A semiconductor device comprising:
a first layer comprising an arithmetic processing device and a sense amplifier; and
wherein a second layer comprising a memory device,
wherein the second layer is positioned over the first layer,
wherein the sense amplifier is configured to read data from the memory device,
wherein the memory device comprises a plurality of memory cells,
wherein the memory cell comprises a first transistor and a second transistor,
wherein the first transistor and the second transistor are electrically connected to each other through a conductor,
wherein the first transistor comprises a channel formation region in a first semiconductor positioned along a side surface of a first opening portion included in a first insulator,
wherein the second transistor comprises a channel formation region in a second semiconductor positioned along a side surface of a second opening portion included in a second insulator,
wherein the second insulator is positioned over the first insulator, and
wherein the second opening portion is positioned obliquely above the first opening portion.

2. The semiconductor device according to claim 1,
wherein the conductor comprises a region configured to be a gate electrode of the first transistor and a region configured to be a source electrode or a drain electrode of the second transistor.

3. The semiconductor device according to claim 1,
wherein the second opening portion does not overlap with the first opening portion in a top view.

4. A semiconductor device comprising:
a first layer comprising an arithmetic processing device and a sense amplifier; and
wherein a second layer comprising a memory device,
wherein the second layer is provided positioned over the first layer,
wherein the sense amplifier has is configured to read data from the memory device,
wherein the memory device comprises a plurality of memory cells,
wherein the memory cell comprises a first transistor and a second transistor,
wherein the first transistor comprises a first conductor, a first semiconductor, a first insulator, a second conductor, and a third conductor,
wherein the first semiconductor comprises a first region positioned on a side surface of a first opening portion,
wherein the first opening portion penetrates a second insulator and the second conductor,
wherein the second insulator and the second conductor are positioned over the first conductor,
wherein the first insulator comprises a second region,
wherein the second region is in contact with the first semiconductor and covers the first opening portion,
wherein the third conductor comprises a third region,
wherein the third region is in contact with the first insulator and covers the first opening portion,
wherein the second transistor comprises the third conductor, a second semiconductor, a third insulator, a fourth conductor, and a fifth conductor,
wherein the second semiconductor comprises a fourth region positioned on a side surface of a second opening portion portion,
wherein the second opening portion penetrates a fourth insulator and the fourth conductor,
wherein the fourth insulator and the fourth conductor are positioned over the third conductor,
wherein the third insulator comprises fifth region,
wherein the fifth region is in contact with the second semiconductor and covers the second opening portion,
wherein the fifth conductor comprises sixth region,
wherein the sixth region is in contact with the third insulator and covers the second opening portion, and
wherein the second opening portion is positioned obliquely above the first opening portion.

5. The semiconductor device according to claim 4,
wherein the first conductor comprises a region configured to be one of a source electrode and a drain electrode of the first transistor,
wherein the second conductor comprises a region configured to be the other of the source electrode and the drain electrode of the first transistor,
wherein the third conductor comprises a region configured to be a gate electrode of the first transistor and a region configured to be one of a source electrode and a drain electrode of the second transistor,
wherein the fourth conductor comprises a region configured to be the other of the source electrode and the drain electrode of the second transistor, and
wherein the fifth conductor comprises a region configured to be a gate electrode of the second transistor.

6. The semiconductor device according to claim 4,
wherein the second opening portion does not overlap with the first opening portion in a top view.

7. The semiconductor device according to claim 4,
wherein a whole of the third conductor overlaps with the second conductor in a top view.

8. The semiconductor device according to claim 4,
wherein the third conductor in a top view has an elliptical shape or an oval shape,
wherein the first conductor, the second conductor, the fourth conductor, and the fifth conductor each have a belt-like shape in a top view, and
wherein a direction of a major axis of the third conductor in a top view is not the same as and is not orthogonal to a longitudinal direction of each of the first conductor, the second conductor, the fourth conductor, and the fifth conductor in a top view.

9. The semiconductor device according to claim 1,
wherein each of the first semiconductor and the second semiconductor is an oxide semiconductor, and
wherein the oxide semiconductor comprises any one or more selected from In, Ga, and Zn.

10. The semiconductor device according to claim 4,
wherein each of the first semiconductor and the second semiconductor is an oxide semiconductor, and
wherein the oxide semiconductor comprises any one or more selected from In, Ga, and Zn.

11. A semiconductor device,
a first layer comprising a sense amplifier; and
a second layer comprising a memory device electrically connected to the sense amplifier,
wherein the second layer is positioned over the first layer,
wherein the memory device comprises a plurality of memory cells,
wherein the memory cell comprises a first transistor and a second transistor,
wherein the first transistor and the second transistor are electrically connected to each other through a conductor,
wherein the first transistor comprises a channel formation region in a first semiconductor positioned along a side surface of a first opening portion included in a first insulator,
wherein the second transistor comprises a channel formation region in a second semiconductor positioned along a side surface of a second opening portion included in a second insulator,
wherein the second insulator is positioned over the first insulator, and
wherein the second opening portion comprises a region not overlapping with the first opening portion.

12. The semiconductor device according to claim 11,
wherein the conductor comprises a region configured to be a gate electrode of the first transistor and a region configured to be a source electrode or a drain electrode of the second transistor.

13. The semiconductor device according to claim 11,
wherein each of the first semiconductor and the second semiconductor is an oxide semiconductor, and
wherein the oxide semiconductor comprises any one or more selected from In, Ga, and Zn.
